(19) United States
(12) Patent Application Publication
(10) Pub. No.: US 2025/0151538 A1
(43) Pub. Date: May 8, 2025

(54) SEMICONDUCTOR DEVICE AND METHOD FOR MANUFACTURING THE SEMICONDUCTOR DEVICE

(71) Applicant: Semiconductor Energy Laboratory Co., Ltd., Atsugi-shi, Kanagawa-ken (JP)

(72) Inventors: Yasuharu HOSAKA, Tochigi (JP); Yukinori SHIMA, Tatebayashi (JP); Masami JINTYOU, Shimotsuga (JP); Masataka NAKADA, Tochigi (JP); Junichi KOEZUKA, Tochigi (JP); Kenichi OKAZAKI, Atsugi (JP)

(21) Appl. No.: 18/833,581

(22) PCT Filed: Feb. 6, 2023
(86) PCT No.: PCT/IB2023/051026

§ 371 Date: Jul. 26, 2024

(30) Foreign Application Priority Data
Feb. 17, 2022 (JP) 2022-022886

(51) Int. Cl. H10K 59/124; H10K 59/12; H10K 59/121

(52) U.S. Cl. CPC H10K 59/124; H10K 59/1201; H10K 59/1213

(57) ABSTRACT

A semiconductor device including a miniaturized transistor is provided. The semiconductor device includes a semiconductor layer, a first conductive layer, a second conductive layer, a third conductive layer, a first insulating layer, and a second insulating layer. The first insulating layer is provided over the first conductive layer. The first insulating layer has a first opening reaching the first conductive layer. The semiconductor layer is in contact with a top surface and a side surface of the first insulating layer and a top surface of the first conductive layer. The second conductive layer is provided over the semiconductor layer. The second conductive layer includes a second opening in a region overlapping with the first opening. The second insulating layer is provided over the semiconductor layer and the second conductive layer. The third conductive layer is provided over the second insulating layer. The first insulating layer has a stacked-layer structure of a third insulating layer and a fourth insulating layer over the third insulating layer. The fourth insulating layer includes a region having a film density higher than that of the third insulating layer.

### TECHNICAL FIELD

One embodiment of the present invention relates to a semiconductor device, a display apparatus, a display module, and an electronic device. One embodiment of the present invention relates to a method for manufacturing a semiconductor device and a method for manufacturing a display apparatus.

Note that one embodiment of the present invention is not limited to the above technical field. Examples of the technical field of one embodiment of the present invention include a semiconductor device, a display apparatus, a light-emitting apparatus, a power storage device, a memory device, an electronic device, a lighting device, an input device (e.g., a touch sensor), an input/output device (e.g., a touch panel), a method for driving any of them, and a method for manufacturing any of them.

### BACKGROUND ART

Semiconductor devices including transistors have been widely used in display apparatuses and electronic devices, and required to achieve high integration and high-speed operation. In the case where semiconductor devices are used for high-definition display apparatuses, for example, highly integrated semiconductor devices are desired. As one way of increasing the degree of integration of transistors, miniaturized transistors have been developed.

In recent years, display apparatuses applicable to virtual reality (VR), augmented reality (AR), substitutional reality (SR), or mixed reality (MR) have been desired. VR, AR, SR, and MR are collectively referred to as XR (Extended Reality). Display apparatuses for XR have been expected to have higher definition and higher color reproducibility so that realistic feeling and the sense of immersion can be enhanced. Examples of apparatuses applicable to such display apparatuses include a liquid crystal display apparatus and a light-emitting apparatus including a light-emitting device such as organic EL (Electro Luminescence) element or a light-emitting diode (LED).

Patent Document 1 discloses a display apparatus using an organic EL device (also referred to as organic EL element) for VR.

### REFERENCE

### Patent Document

[Patent Document 1] PCT International Publication No. 2018/087625

### SUMMARY OF THE INVENTION

### Problems to be Solved by the Invention

An object of one embodiment of the present invention is to provide a semiconductor device including a miniaturized transistor and a manufacturing method thereof. Another object of one embodiment of the present invention is to provide a semiconductor device including a transistor with high on-state current and a manufacturing method thereof. Another object of one embodiment of the present invention is to provide a semiconductor device having favorable electrical characteristics and a manufacturing method thereof. Another object of one embodiment of the present invention is to provide a highly reliable semiconductor device and a method for manufacturing the highly reliable semiconductor device. Another object of one embodiment of the present invention is to provide a method for manufacturing a semiconductor device with high productivity. Another object of one embodiment of the present invention is to provide a novel semiconductor device and a manufacturing method thereof.

Note that the description of these objects does not preclude the presence of other objects. In one embodiment of the present invention, there is no need to achieve all these objects. Note that objects other than these can be derived from the description of the specification, the drawings, the claims, and the like.

### Means for Solving the Problems

One embodiment of the present invention is a semiconductor device including a semiconductor layer, a first conductive layer, a second conductive layer, a third conductive layer, a first insulating layer, and a second insulating layer. The first insulating layer is provided over the first conductive layer. The first insulating layer has a first opening reaching the first conductive layer. The semiconductor layer is in contact with a top surface and a side surface of the first insulating layer and a top surface of the first conductive layer. The second conductive layer is provided over the semiconductor layer. The second conductive layer includes a second opening in a region overlapping with the first opening. The second insulating layer is provided over the semiconductor layer and the second conductive layer. The third conductive layer is provided over the second insulating layer. The first insulating layer has a stacked-layer structure of a third insulating layer and a fourth insulating layer over the third insulating layer. The fourth insulating layer includes a region having a film density higher than a film density of the third insulating layer.

One embodiment of the present invention is a semiconductor device including a semiconductor layer, a first conductive layer, a second conductive layer, a third conductive layer, a first insulating layer, and a second insulating layer. The first insulating layer is provided over the first conductive layer. The first insulating layer has a first opening reaching the first conductive layer. The semiconductor layer is in contact with a top surface and a side surface of the first insulating layer and a top surface of the first conductive layer. The second conductive layer is provided over the semiconductor layer. The second conductive layer includes a second opening in a region overlapping with the first opening. The second insulating layer is provided over the semiconductor layer and the second conductive layer. The third conductive layer is provided over the second insulating layer. The first insulating layer has a stacked-layer structure of a third insulating layer and a fourth insulating layer over the third insulating layer. The fourth insulating layer includes a region having a content of nitrogen higher than a content of nitrogen of the third insulating layer.

In the above-described semiconductor device, the first insulating layer preferably includes a fifth insulating layer. The fifth insulating layer is preferably positioned between the third insulating layer and the first conductive layer. The fifth insulating layer preferably includes a region having a film density higher than a film density of the third insulating layer.

In the above-described semiconductor device, the first insulating layer preferably includes a fifth insulating layer. The fifth insulating layer is preferably positioned between the third insulating layer and the first conductive layer. The fifth insulating layer preferably includes a region having a content of nitrogen higher than a content of nitrogen of the third insulating layer.

In the above-described semiconductor device, the thickness of the first insulating layer is preferably greater than or equal to 0.01 μm and less than 3 μm.

In the above-described semiconductor device, the first conductive layer preferably includes an oxide conductor.

In the above-described semiconductor device, the second conductive layer preferably includes an oxide conductor.

One embodiment of the present invention is a method for manufacturing a semiconductor device, including: forming a first conductive film; processing the first conductive film to form a first conductive layer; forming a first insulating film over the first conductive layer; processing the first insulating film to form a first insulating layer having a first opening reaching the first conductive layer; forming a semiconductor layer in contact with a top surface of the first conductive layer and a top surface and a side surface of the first insulating layer; forming a second conductive film over the semiconductor layer; processing the second conductive film to form a second conductive layer having a second opening in a region overlapping with the first opening; forming a second insulating layer over the semiconductor layer and the second conductive layer; and forming a third conductive layer over the second insulating layer. The first insulating layer has a stacked-layer structure of a third insulating layer and a fourth insulating layer over the third insulating layer. The fourth insulating layer includes a region having a film density higher than a film density of the third insulating layer.

One embodiment of the present invention is a method for manufacturing a semiconductor device, including: forming a first conductive film; processing the first conductive film to form a first conductive layer; forming a first insulating film over the first conductive layer; processing the first insulating film to form a first insulating layer having a first opening reaching the first conductive layer; forming a semiconductor layer in contact with a top surface of the first conductive layer and a top surface and a side surface of the first insulating layer; forming a second conductive film over the semiconductor layer; processing the second conductive film to form a second conductive layer having a second opening in a region overlapping with the first opening; forming a second insulating layer over the semiconductor layer and the second conductive layer; and forming a third conductive layer over the second insulating layer. The first insulating layer has a stacked-layer structure of a third insulating layer and a fourth insulating layer over the third insulating layer. The fourth insulating layer includes a region having a content of nitrogen higher than a content of nitrogen of the third insulating layer.

### Effect of the Invention

One embodiment of the present invention can provide a semiconductor device including a miniaturized transistor and a manufacturing method thereof. One embodiment of the present invention can provide a semiconductor device including a transistor with high on-state current and a manufacturing method thereof. One embodiment of the present invention can provide a semiconductor device having favorable electrical characteristics and a manufacturing method thereof. One embodiment of the present invention can provide a highly reliable semiconductor device and a manufacturing method thereof. One embodiment of the present invention can provide a method for manufacturing a semiconductor device with high productivity. One embodiment of the present invention can provide a novel semiconductor device and a manufacturing method thereof.

Note that the description of these effects does not preclude the presence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a top view illustrating an example of a semiconductor device. FIG. 1B and FIG. 1C are cross-sectional views each illustrating the example of the semiconductor device.

FIG. 2 is a perspective view illustrating an example of a semiconductor device.

FIG. 3A to FIG. 3C are perspective views illustrating examples of a semiconductor device.

FIG. 4A is a top view illustrating an example of a semiconductor device. FIG. 4B is a cross-sectional view illustrating the example of the semiconductor device.

FIG. 5A is a top view illustrating an example of a semiconductor device. FIG. 5B is a cross-sectional view illustrating the example of the semiconductor device.

FIG. 6A and FIG. 6B are cross-sectional views each illustrating an example of a semiconductor device.

FIG. 7A and FIG. 7B are cross-sectional views each illustrating an example of a semiconductor device.

FIG. 8A is a top view illustrating an example of a semiconductor device. FIG. 8B and FIG. 8C are cross-sectional views each illustrating the example of the semiconductor device.

FIG. 9A is a top view illustrating an example of a semiconductor device. FIG. 9B is a cross-sectional view illustrating the example of the semiconductor device.

FIG. 10A is a top view illustrating an example of a semiconductor device. FIG. 10B and FIG. 10C are cross-sectional views each illustrating the example of the semiconductor device.

FIG. 11A1 and FIG. 11B1 are perspective views illustrating an example of a method for manufacturing a semiconductor device. FIG. 11A2 and FIG. 11B2 are cross-sectional views illustrating the example of the method for manufacturing the semiconductor device.

FIG. 12A1 and FIG. 12B1 are perspective views illustrating an example of a method for manufacturing a semiconductor device. FIG. 12A2 and FIG. 12B2 are cross-sectional views illustrating the example of the method for manufacturing the semiconductor device.

FIG. 13A1 and FIG. 13B1 are perspective views illustrating an example of a method for manufacturing a semiconductor device. FIG. 13A2 and FIG. 13B2 are cross-sectional views illustrating the example of the method for manufacturing the semiconductor device.

FIG. 14A1 and FIG. 14B1 are perspective views illustrating an example of a method for manufacturing a semiconductor device. FIG. 14A2 and FIG. 14B2 are cross-sectional views illustrating the example of the method for manufacturing the semiconductor device.

FIG. 15A1 and FIG. 15B1 are perspective views illustrating an example of a method for manufacturing a semiconductor device. FIG. 15A2 and FIG. 15B2 are cross-sectional views illustrating the example of the method for manufacturing the semiconductor device.

FIG. 16 is a perspective view illustrating an example of a display apparatus.

FIG. 17 is a cross-sectional view illustrating an example of a display apparatus.

FIG. 18A and FIG. 18B are cross-sectional views each illustrating an example of a display apparatus.

FIG. 19 is a cross-sectional view illustrating an example of a display apparatus.

FIG. 20 is a cross-sectional view illustrating an example of a display apparatus.

FIG. 21A to FIG. 21C are cross-sectional views illustrating examples of a display apparatus.

FIG. 22A and FIG. 22B are cross-sectional views each illustrating an example of a display apparatus.

FIG. 23 is a cross-sectional view illustrating an example of a display apparatus.

FIG. 24 is a cross-sectional view illustrating an example of a display apparatus.

FIG. 25 is a cross-sectional view illustrating an example of a display apparatus.

FIG. 26A to FIG. 26H are diagrams illustrating examples of pixels.

FIG. 27A to FIG. 27K are diagrams illustrating examples of pixels.

FIG. 28A to FIG. 28F are diagrams illustrating structure examples of light-emitting devices.

FIG. 29A to FIG. 29C are diagrams illustrating structure examples of light-emitting devices.

FIG. 30A and FIG. 30B are diagrams each illustrating structure examples of a light-receiving device. FIG. 30C to FIG. 30E are diagrams illustrating structure examples of a display device.

FIG. 31A to FIG. 31D are diagrams illustrating examples of electronic devices.

FIG. 32A to FIG. 32F are diagrams illustrating examples of electronic devices.

FIG. 33A to FIG. 33G are diagrams illustrating examples of electronic devices.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in drawings.

Note that the term “film” and the term “layer” can be interchanged with each other depending on the case or the circumstances. For example, the term “conductive layer” can be replaced with the term “conductive film”. As another example, the term “insulating film” can be replaced with the term “insulating layer”.

In this specification and the like, a device manufactured using a metal mask or an FMM (fine metal mask, high-definition metal mask) may be referred to as a device having an MM (metal mask) structure. In addition, in this specification and the like, a device manufactured without using a metal mask or an FMM may be referred to as a device having an MML (metal maskless) structure.

In this specification and the like, a structure where at least light-emitting layers of light-emitting devices having different emission wavelengths are separately formed is sometimes referred to as an SBS (Side By Side) structure. The SBS structure can optimize materials and structures of light-emitting devices and thus can extend the freedom of choice of materials and structures, whereby the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from one another on the basis of the cross-sectional shape, properties, or the like in some cases. One layer may have two or three functions of the carrier-injection layer, the carrier-transport layer, and the carrier-blocking layer in some cases.

In this specification and the like, a light-emitting device (also referred to as a light-emitting element) includes an EL layer between a pair of electrodes. The EL layer includes at least a light-emitting layer. Here, examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

In this specification and the like, a light-receiving device (also referred to as a light-receiving element) includes at least an active layer functioning as a photoelectric conversion layer between a pair of electrodes.

In this specification and the like, the term “island shape” refers to a state where two or more layers formed using the same material in the same step are physically separated from each other. For example, “island-shaped light-emitting layer” means a state where the light-emitting layer and its adjacent light-emitting layer are physically separated from each other.

In this specification and the like, a tapered shape refers to a shape such that at least part of a side surface of a component is inclined with respect to a substrate surface or a formation surface. For example, a tapered shape preferably includes a region where the angle between the inclined side surface and the substrate surface or the formation surface (such an angle is also referred to as a taper angle) is less than 90°. Note that the side surface, the substrate surface, and the formation surface of the component are not necessarily completely flat, and may have a substantially planar shape with a small curvature or a substantially planar shape with slight unevenness.

Note that in this specification and the like, a mask layer (also referred to as a sacrificial layer) is positioned above at least a light-emitting layer (specifically, a layer processed into an island shape among layers included in an EL layer) and has a function of protecting the light-emitting layer in the manufacturing process.

Note that in this specification and the like, step disconnection refers to a phenomenon in which a layer, a film, or an electrode is disconnected because of the shape of the formation surface (e.g., a step).

In this specification and the like, the expression “top surface shapes substantially match” means that at least outlines of stacked layers partly overlap with each other. For example, the case of processing the upper layer and the lower layer with the use of the same mask pattern or mask patterns that are partly the same is included. However, in some cases, the outlines do not completely overlap with each other and the upper layer is positioned inward from the lower layer or the upper layer is positioned outward from the lower layer; such cases are also represented by the expression “top surface shapes substantially match”.

### Embodiment 1

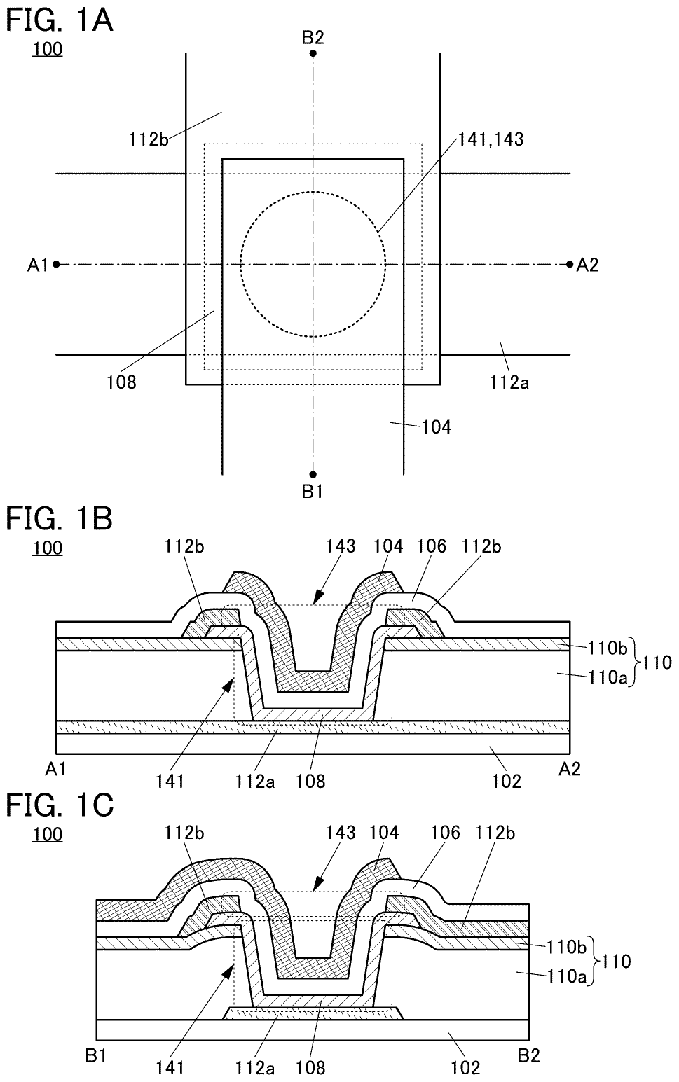

In this embodiment, a semiconductor device of one embodiment of the present invention, a manufacturing method thereof, and the like will be described with reference to FIG. 1 to FIG. 15.

### Structure Example 1

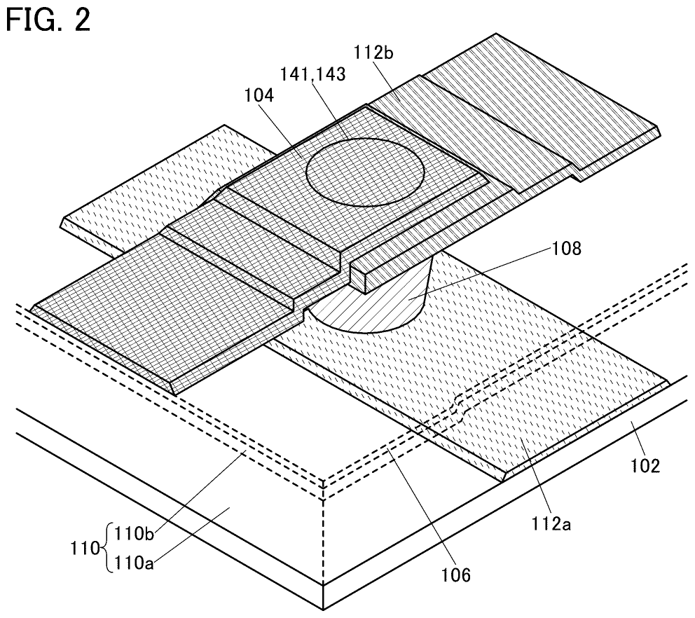

Transistors that can be used in the semiconductor device of one embodiment of the present invention are described. FIG. 1A illustrates a top view (also referred to as a plan view) of a transistor 100. FIG. 1B is a cross-sectional view of a cut plane along the dashed-dotted line A1-A2 in FIG. 1A and FIG. 1C is a cross-sectional view of a cut plane along the dashed-dotted line B1-B2. FIG. 2 illustrates a perspective view of the transistor 100. Note that in FIG. 1A, some components (e.g., a gate insulating layer) of the transistor 100 are not illustrated. Some components are not illustrated in top views of transistors in the following drawings, as in FIG. 1A. For easy understanding, FIG. 2 illustrates an insulating layer so as to be seen through and its outline is indicated by a dashed line.

The transistor 100 is provided over a substrate 102. The transistor 100 includes a conductive layer 104, an insulating layer 106, a semiconductor layer 108, a conductive layer 112a, a conductive layer 112b, and an insulating layer 110. The conductive layer 104 functions as a gate electrode. Part of the insulating layer 106 functions as a gate insulating layer. The conductive layer 112a functions as one of a source electrode and a drain electrode, and the conductive layer 112b functions as the other. In the semiconductor layer 108, the whole region that is between the source electrode and the drain electrode and overlaps with the gate electrode with the gate insulating layer therebetween functions as a channel formation region. In the semiconductor layer 108, a region in contact with the source electrode functions as a source region and a region in contact with the drain electrode functions as a drain region.

The conductive layer 112a is provided over the substrate 102, and the insulating layer 110 is provided over the conductive layer 112a. The conductive layer 110 has an opening 141 in a region overlapping with the conductive layer 112a. The conductive layer 112a is exposed in the opening 141. The semiconductor layer 108 is provided to cover the opening 141. In the opening 141, the semiconductor layer 108 includes a region in contact with the conductive layer 112a. The insulating layer 110 includes a region interposed between the conductive layer 112a and the semiconductor layer 108. The conductive layer 112b is provided over the semiconductor layer 108. The conductive layer 112b has an opening 143 in a region overlapping with the conductive layer 112a. The opening 143 is provided in a region overlapping with the opening 141. The conductive layer 112b includes a region overlapping with the conductive layer 112a with the insulating layer 110 and the semiconductor layer 108 therebetween.

The semiconductor layer 108 includes a region in contact with the bottom surface of the conductive layer 112b, the top surface and the side surface of the insulating layer 110, and the top surface of the conductive layer 112a. That is, the bottom surface of the semiconductor layer 108 is in contact with one of the source electrode and the drain electrode, and the top surface of the semiconductor layer 108 is in contact with the other of the source electrode and the drain electrode. The semiconductor layer 108 has a shape along the shapes of the top surface and the side surface of the insulating layer 110 and the top surface of the conductive layer 112a.

Note that in this specification and the like, a surface of a layer on a formation surface side is referred to as a bottom surface, and a surface opposite to the bottom surface is referred to as a top surface. For example, a surface of the semiconductor layer 108 on the side of the insulating layer 110 and the conductive layer 112a, which are the formation surface for the semiconductor layer 108, is referred to as a bottom surface of the semiconductor layer 108, and a surface of the semiconductor layer 108 opposite to the bottom surface is referred to as a top surface.

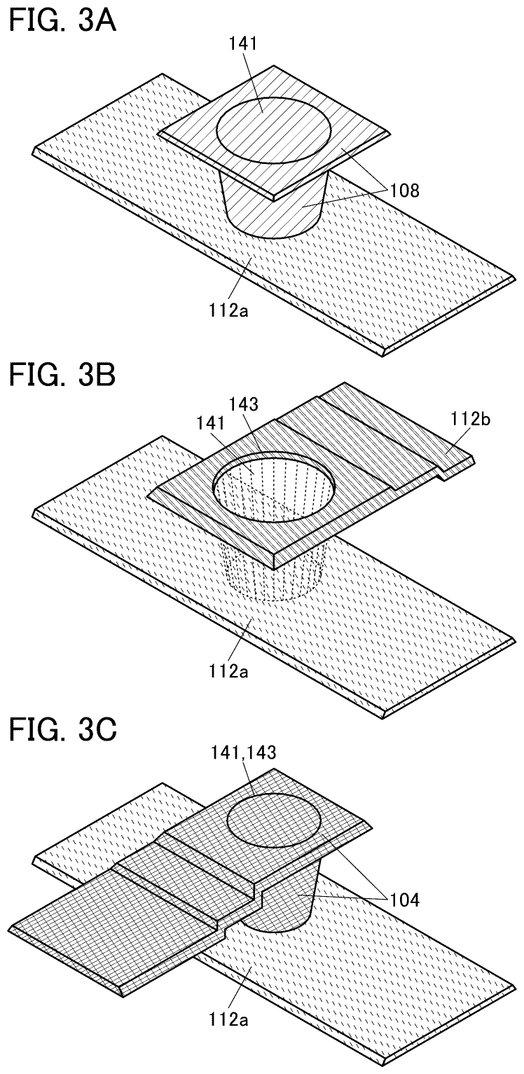

FIG. 3A is a perspective view selectively illustrating the conductive layer 112a and the semiconductor layer 108. The semiconductor layer 108 is provided to cover the opening 141 provided in the insulating layer 110 (not illustrated in FIG. 3A). In the opening 141, the semiconductor layer 108 includes a region in contact with the top surface of the conductive layer 112a.

Although the semiconductor layer 108 has a single-layer structure in FIG. 1B and the like, one embodiment of the present invention is not limited thereto. The semiconductor layer 108 may have a stacked-layer structure of two or more layers.

FIG. 3B is a perspective view selectively illustrating the conductive layer 112a and the conductive layer 112b. Note that the opening 141 provided in the insulating layer 110 (not illustrated in FIG. 3B) is indicated by dashed lines. The conductive layer 112b has the opening 143 in a region overlapping with the conductive layer 112a.

The top surface shapes of the opening 141 and the opening 143 can each be a circle or an ellipse, for example. The top surface shapes of the opening 141 and the opening 143 may each be a polygon such as a triangle, a tetragon (including a rectangle, a rhombus, and a square), and a pentagon; or a polygon with rounded corners. The top surface shapes of the opening 141 and the opening 143 are each preferably a circle as illustrated in FIG. 1A and the like. When the top surface shapes of the opening 141 and the opening 143 are each a circle, the processing accuracy in forming the opening 141 and the opening 143 can be enhanced, whereby the opening 141 and the opening 143 with a minute size can be formed. Note that in this specification and the like, the circle is not limited to a perfect circle.

As illustrated in FIG. 1B and the like, it is preferable that the conductive layer 112b not be provided inside the opening 141. Specifically, it is preferable that the conductive layer 112b not include a region that is in contact with a side surface of the insulating layer 110 on the opening 141 side. FIG. 1B and the like illustrate a structure in which the end portion of the conductive layer 112b on the opening 143 side matches with or substantially matches with the end portion of the insulating layer 110 on the opening 141 side. It can be said that the top surface shape of the opening 143 matches or substantially matches with the top surface shape of the opening 141. Note that in this specification and the like, the end portion of the conductive layer 112b on the opening 143 side refers to the end portion of the bottom surface of the conductive layer 112b on the opening 143 side. The bottom surface of the conductive layer 112b refers to a surface thereof on the insulating layer 110 side. The end portion of the insulating layer 110 on the opening 141 side refers to the end portion of the top surface of the insulating layer 110 on the opening 141 side. The top surface of the insulating layer 110 refers to a surface thereof on the conductive layer 112b side. The top surface shape of the opening 143 refers to the shape of the end portion of the bottom surface of the conductive layer 112b on the opening 143 side. The top surface shape of the opening 141 refers to the shape of the end portion of the top surface of the insulating layer 110 on the opening 141 side.

In the case where end portions match or substantially match, the end portions can also be said to be aligned or substantially aligned. In the case where end portions are aligned or substantially aligned with each other and the case where top surface shapes match or substantially match, it can be said that outlines of stacked layers at least partly overlap with each other in a top view. For example, a case of processing the upper layer and the lower layer with the use of the same mask pattern or mask patterns that are partly the same is included. Note that, in some cases, the outlines do not completely overlap with each other and the upper layer is positioned inward from the lower layer or the upper layer is positioned outward from the lower layer; such cases are also represented by the expression “end portions are substantially aligned” or the expression “top surface shapes substantially match”.

The insulating layer 106 functioning as the gate insulating layer is provided to cover the opening 141 and the opening 143. The insulating layer 106 is provided over the semiconductor layer 108, the conductive layer 112b, and the insulating layer 110. The insulating layer 106 includes are region that is in contact with the top surface and the side surface of the semiconductor layer 108, the top surface and the side surface of the conductive layer 112b, and the top surface of the insulating layer 110. The insulating layer 106 has a shape along the shapes of the top surface and the side surface of the semiconductor layer 108, the top surface and the side surface of the conductive layer 112b, and the top surface of the insulating layer 110.

The conductive layer 104 functioning as the gate electrode is provided over the insulating layer 106 and includes a region in contact with the top surface of the insulating layer 106. The conductive layer 104 includes a region overlapping with the semiconductor layer 108 with the insulating layer 106 therebetween. The conductive layer 104 has a shape along the shape of the top surface of the insulating layer 106.

FIG. 3C is a perspective view selectively illustrating the conductive layer 112a and the conductive layer 104. The conductive layer 104 is provided to cover the opening 141 and the opening 143.

As illustrated in FIG. 1B and the like, the conductive layer 104 includes a region overlapping with the semiconductor layer 108 with the insulating layer 106 therebetween in the opening 141. The conductive layer 104 includes a region overlapping with the conductive layer 112a with the insulating layer 106 and the semiconductor layer 108 therebetween and a region overlapping with the conductive layer 112b with the insulating layer 106 therebetween. The conductive layer 104 preferably covers the end portion of the conductive layer 112b on the opening 143 side. With such a structure, in the semiconductor layer 108, the whole region that is between the source electrode and the drain electrode and overlaps with the gate electrode with the gate insulating layer therebetween can function as the channel formation region.

The transistor 100 is what is called a top-gate transistor including a gate electrode above the semiconductor layer 108.

The conductive layer 112a, the conductive layer 112b, and the conductive layer 104 can each function as a wiring. The transistor 100 can be provided in a region where these wirings overlap with each other. That is, the areas occupied by the transistor 100 and the wirings can be reduced in the circuit including the transistor 100 and the wirings. Furthermore, the area occupied by a circuit can be reduced. Therefore, a semiconductor device with a small size can be obtained. When the semiconductor device of one embodiment of the present invention is used for a pixel circuit of a display apparatus, the area occupied by the pixel circuit can be reduced and the display apparatus can have high definition, for example. When the semiconductor device of one embodiment of the present invention is used for a driver circuit (e.g., a gate line driver circuit and a source line driver circuit) of a display apparatus, the area occupied by the driver circuit can be reduced and the display apparatus can have a narrow bezel.

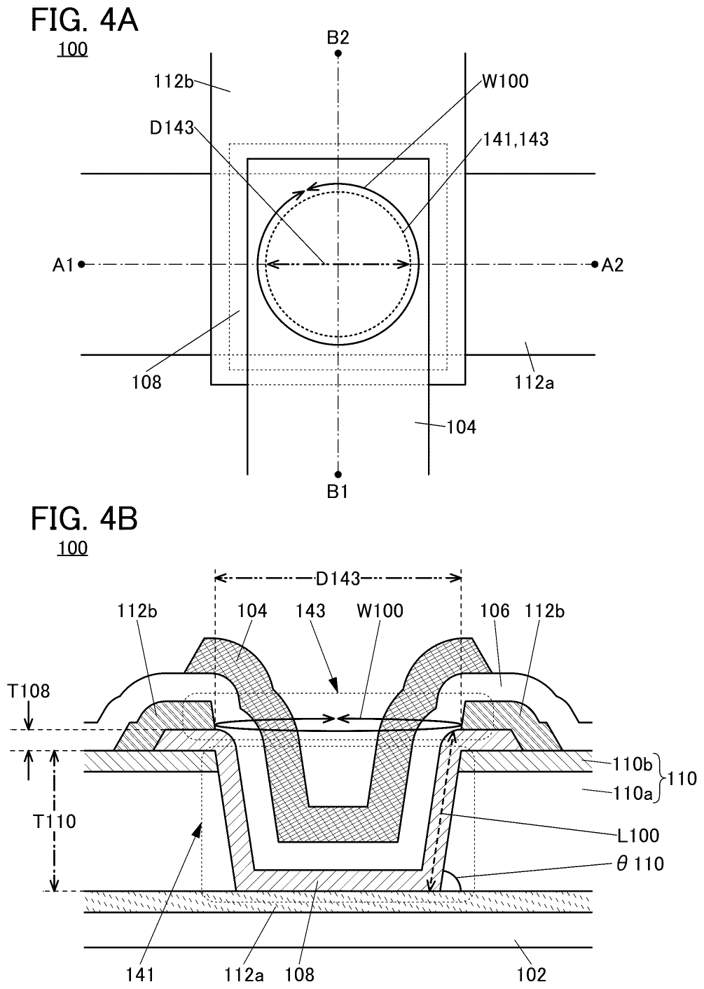

Here, the channel length and channel width of the transistor 100 are described with reference to FIG. 4A and FIG. 4B. FIG. 4A is a top view of the transistor 100. FIG. 4B is an enlarged view of FIG. 1B.

In the semiconductor layer 108, a region in contact with the conductive layer 112a functions as one of the source region and the drain region, a region in contact with the conductive layer 112b functions as the other of the source region and the drain region, and a region between the source region and the drain region functions as the channel formation region.

The channel length of the transistor 100 is a distance between the source region and the drain region. In FIG. 4B, a channel length L100 of the transistor 100 is indicated by a dashed double-headed arrow. In a cross-sectional view, the channel length L100 is a distance between an end portion of the region where the semiconductor layer 108 is in contact with the conductive layer 112a and an end portion of the region where the semiconductor layer 108 is in contact with the conductive layer 112b.

Here, the channel length L100 of the transistor 100 corresponds to the sum of the length of the side surface of the insulating layer 110 on the opening 141 side and the thickness of the semiconductor layer 108 in a cross-sectional view. That is, the channel length L100 is determined by a thickness T110 of the insulating layer 110, an angle θ1 10 formed between the side surface of the insulating layer 110 on the opening 141 side and a formation surface of the insulating layer 110 (here, the top surface of the conductive layer 112a), and the thickness of the semiconductor layer 108, and is not affected by the performance of a light-exposure apparatus used for manufacturing the transistor. Thus, the channel length L100 can be a value smaller than that of the resolution limit of a light-exposure apparatus, which enables the transistor to have a minute size. For example, the channel length L100 is preferably larger than or equal to 0.01 μm and smaller than 3 μm, further preferably larger than or equal to 0.05 μm and smaller than 3 μm, still further preferably larger than or equal to 0.1 μm and smaller than 3 μm, yet still further preferably larger than or equal to 0.15 μm and smaller than 3 μm, yet still further preferably larger than or equal to 0.2 μm and smaller than 3 μm, yet still further preferably larger than or equal to 0.2 μm and smaller than 2.5 μm, yet still further preferably larger than or equal to 0.2 μm and smaller than 2 μm, yet still further preferably larger than or equal to 0.2 μm and smaller than 1.5 μm, yet still further preferably larger than or equal to 0.3 μm and smaller than or equal to 1.5 μm, yet still further preferably larger than or equal to 0.3 μm and smaller than or equal to 1.2 μm, yet still further preferably larger than or equal to 0.4 μm and smaller than or equal to 1.2 μm, yet still further preferably larger than or equal to 0.4 μm and smaller than or equal to 1 μm, yet still further preferably larger than or equal to 0.5 μm and smaller than or equal to 1 μm. In FIG. 4B, the thickness T110 of the insulating layer 110 is indicated by a dashed-dotted double-headed arrow, and the thickness T108 of the semiconductor layer 108 is indicated by solid-line arrows.

The reduction in the channel length L100 can increase the on-state current of the transistor 100. With the use of the transistor 100, a circuit capable of high-speed operation can be manufactured. Furthermore, the area occupied by a circuit portion can be reduced. Therefore, a semiconductor device with a small size can be obtained. The application of the semiconductor device of one embodiment of the present invention to a large-sized display apparatus or a high-definition display apparatus can reduce signal delay in wirings and reduce display unevenness if the number of wirings is increased, for example. Thus, a display apparatus with high display quality can be provided. In addition, since the area occupied by the circuit can be reduced, the bezel of the display apparatus can be narrowed.

By adjusting the thickness T110 and the angle θ1 10 of the insulating layer 110, the channel length L100 can be controlled.

The thickness T110 of the insulating layer 110 is preferably larger than or equal to 0.01 μm and smaller than 3 μm, further preferably larger than or equal to 0.05 μm and smaller than 3 μm, still further preferably larger than or equal to 0.1 μm and smaller than 3 μm, yet still further preferably larger than or equal to 0.15 μm and smaller than 3 μm, yet still further preferably larger than or equal to 0.2 μm and smaller than 3 μm, yet still further preferably larger than or equal to 0.2 μm and smaller than 2.5 μm, yet still further preferably larger than or equal to 0.2 μm and smaller than 2 μm, yet still further preferably larger than or equal to 0.2 μm and smaller than 1.5 μm, yet still further preferably larger than or equal to 0.3 μm and smaller than or equal to 1.5 μm, yet still further preferably larger than or equal to 0.3 μm and smaller than or equal to 1.2 μm, yet still further preferably larger than or equal to 0.4 μm and smaller than or equal to 1.2 μm, yet still further preferably larger than or equal to 0.4 μm and smaller than or equal to 1 μm, yet still further preferably larger than or equal to 0.5 μm and smaller than or equal to 1 μm.

The side surface of the insulating layer 110 on the opening 141 side is preferably tapered. The angle θ1 10 of the insulating layer 110 is preferably less than 90°. By reducing the angle θ1 10, coverage with the layer (e.g., the semiconductor layer 108) provided over the insulating layer 110 can be improved. However, reducing the angle θ1 10 may reduce the contact area between the semiconductor layer 108 and the conductive layer 112a and increase the contact resistance between the semiconductor layer 108 and the conductive layer 112a in some cases. The angle θ1 10 is preferably greater than or equal to 45° and less than 90°, further preferably greater than or equal to 50° and less than 90°, still further preferably greater than or equal to 55° and less than 90°, yet still further preferably greater than or equal to 60° and less than 90°, yet still further preferably greater than or equal to 60° and less than or equal to 85°, yet still further preferably greater than or equal to 65° and less than or equal to 85°, yet still further preferably greater than or equal to 65° and less than or equal to 80°, yet still further preferably greater than or equal to 70° and less than or equal to 80°. When the angle θ1 10 is in the above range, the coverage with the layer (e.g., the semiconductor layer 108) formed over the conductive layer 112a and the insulating layer 110 can be improved and a defect such as step disconnection or a void can be inhibited from occurring in the layer. In addition, the contact resistance between the semiconductor layer 108 and the conductive layer 112a can be reduced.

Although FIG. 4B and the like illustrate a structure in which the side surface of the insulating layer 110 on the opening 141 side is linear in a cross-sectional view, one embodiment of the present invention is not limited thereto. In a cross-sectional view, the side surface of the insulating layer 110 on the opening 141 side may be curved or include both a region where the side surface is curved and a region where the side surface is linear.

The thickness of the semiconductor layer 108 is preferably larger than or equal to 3 nm and smaller than or equal to 100 nm, further preferably larger than or equal to 5 nm and smaller than or equal to 100 nm, still further preferably larger than or equal to 10 nm and smaller than or equal to 100 nm, yet still further preferably larger than or equal to 10 nm and smaller than or equal to 70 nm, yet still further preferably larger than or equal to 15 nm and smaller than or equal to 70 nm, yet still further preferably larger than or equal to 15 nm and smaller than or equal to 50 nm, yet still further preferably larger than or equal to 20 nm and smaller than or equal to 50 nm, yet still further preferably larger than or equal to 20 nm and smaller than or equal to 40 nm, yet still further preferably larger than or equal to 25 nm and smaller than or equal to 40 nm.

The channel width of the transistor 100 is the width of the source region or the width of the drain region in a direction perpendicular to the channel length direction. In other words, the channel width is the width of the region where the semiconductor layer 108 is in contact with the conductive layer 112a or the width of the region where the semiconductor layer 108 is in contact with the conductive layer 112b in the direction perpendicular to the channel length direction. Here, the channel width of the transistor 100 is described as the width of the region where the semiconductor layer 108 is in contact with the conductive layer 112b in the direction perpendicular to the channel length direction. In FIG. 4A and FIG. 4B, a channel width W100 of the transistor 100 is indicated by a solid double-headed arrow. In a top view (also referred to as a plan view), the channel width W100 is the length of the end portion of the bottom surface of the conductive layer 112b on the opening 143 side.

The channel width W100 is determined by the top surface shape of the opening 143. In FIG. 4A and FIG. 4B, a width D143 of the opening 143 is indicated by a dashed double-dotted double-headed arrow. The width D143 refers to the shorter side of the smallest rectangle circumscribing the opening 143 in a top view. In the case where the opening 143 is formed by a photolithography method, the width D143 of the opening 143 is larger than or equal to the resolution limit of a light-exposure apparatus. For example, the width D143 is preferably larger than or equal to 0.2 μm and smaller than 5 μm, further preferably larger than or equal to 0.2 μm and smaller than 4.5 μm, still further preferably larger than or equal to 0.2 μm and smaller than 4 μm, yet still further preferably larger than or equal to 0.2 μm and smaller than 3.5 μm, yet still further preferably larger than or equal to 0.2 μm and smaller than 3 μm, yet still further preferably larger than or equal to 0.2 μm and smaller than 2.5 μm, yet still further preferably larger than or equal to 0.2 μm and smaller than 2 μm, yet still further preferably larger than or equal to 0.2 μm and smaller than 1.5 μm, yet still further preferably larger than or equal to 0.3 μm and smaller than or equal to 1.5 μm, yet still further preferably larger than or equal to 0.3 μm and smaller than or equal to 1.2 μm, yet still further preferably larger than or equal to 0.4 μm and smaller than or equal to 1.2 μm, yet still further preferably larger than or equal to 0.4 μm and smaller than or equal to 1 μm, yet still further preferably larger than or equal to 0.5 μm and smaller than or equal to 1 μm. Note that in the case where the top surface shape of the opening 143 is a circle, the width D143 corresponds to the diameter of the opening 143, and the channel width W100 can be calculated to be “D143×π”.

Components included in the semiconductor device of this embodiment will be described below.

### <Component of Semiconductor Device>

### [Semiconductor Layer 108]

The semiconductor material that can be used for the semiconductor layer 108 is not particularly limited. For example, a single-element semiconductor or a compound semiconductor can be used. As the single-element semiconductor material, silicon or germanium can be used, for example. Examples of the compound semiconductor include gallium arsenide and silicon germanium. As the compound semiconductor, an organic substance having semiconductor characteristics or a metal oxide having semiconductor characteristics (also referred to as an oxide semiconductor) can be used. These semiconductor materials may contain an impurity as a dopant.

There is no particular limitation on the crystallinity of a semiconductor material used for the semiconductor layer 108, and any of an amorphous semiconductor and a semiconductor having crystallinity (a single crystal semiconductor, a polycrystalline semiconductor, a microcrystalline semiconductor, or a semiconductor partly including crystal regions) may be used. A semiconductor having crystallinity is preferably used, in which case degradation of the transistor characteristics can be inhibited.

Silicon can be used for the semiconductor layer 108. Examples of silicon include single crystal silicon, polycrystalline silicon, microcrystalline silicon, and amorphous silicon. An example of the polycrystalline silicon is low-temperature polysilicon (LTPS).

The transistor using amorphous silicon for the semiconductor layer 108 can be formed over a large-sized glass substrate, thereby reducing the manufacturing cost. The transistor using polycrystalline silicon for the semiconductor layer 108 has high field-effect mobility and is capable of high-speed operation. The transistor using microcrystalline silicon for the semiconductor layer 108 has higher field-effect mobility and is capable of higher-speed operation than the transistor using amorphous silicon.

The semiconductor layer 108 preferably contains a metal oxide having semiconductor characteristics (oxide semiconductor). Examples of the metal oxide that can be used for the semiconductor layer 108 include indium oxide, gallium oxide, and zinc oxide. The metal oxide preferably contains at least indium (In) or zinc (Zn). The metal oxide preferably contains two or three selected from indium, an element M, and zinc. Note that the element M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium. In particular, the element M is preferably one or more selected from aluminum, gallium, yttrium, and tin.

For the semiconductor layer 108, indium oxide, indium zinc oxide (In—Zn oxide), indium tin oxide (In—Sn oxide), indium titanium oxide (In—Ti oxide), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide), and indium gallium aluminum zinc oxide (In—Ga—Al—Zn oxide, also referred to as IGAZO or IAGZO) can be used, for example. Alternatively, indium tin oxide containing silicon, or the like can also be used.

In particular, the element M is preferably one or more selected from gallium, aluminum, yttrium, and tin. In particular, gallium is preferable as the element M.

Here, the composition of the metal oxide contained in the semiconductor layer 108 has a great impact on the electrical characteristics and reliability of the transistor 100.

For example, higher content of indium in the metal oxide enables the transistor to have high on-state current.

In the case where an In—Zn oxide is used for the semiconductor layer 108, a metal oxide in which the atomic ratio of indium is higher than or equal to that of zinc is preferably used. For example, a metal oxide in which the atomic ratio of metal elements is In:Zn=1:1, In:Zn=2:1, In:Zn=3:1, In:Zn=4:1, In:Zn=5:1, In:Zn=7:1, or In:Zn=10:1, or a neighborhood thereof can be used.

In the case where an In—Sn oxide is used for the semiconductor layer 108, a metal oxide in which the atomic ratio of indium is higher than or equal to that of tin is preferably used. For example, a metal oxide in which the atomic ratio of metal elements is In:Sn=1:1, In:Sn=2:1, In:Sn=3:1, In:Sn=4:1, In:Sn=5:1, In:Sn=7:1, or In:Sn=10:1, or a neighborhood thereof can be used.

In the case where an In—Sn—Zn oxide is used for the semiconductor layer 108, a metal oxide in which the atomic ratio of indium is higher than that of tin can be used. Furthermore, it is preferable to use a metal oxide in which the atomic ratio of zinc is higher than that of tin. For example, a metal oxide in which the atomic ratio of metal elements is In:Sn:Zn=2:1:3, In:Sn:Zn=3:1:2, In:Sn:Zn=4:2:3, In:Sn:Zn=4:2:4.1, In:Sn:Zn=5:1:3, In:Sn:Zn=5:1:6, In:Sn:Zn=5:1:7, In:Sn:Zn=5:1:8, In:Sn:Zn=6:1:6, In:Sn:Zn=10:1:3, In:Sn:Zn=10:1:6, In:Sn:Zn=10:1:7, In:Sn:Zn=10:1:8, In:Sn:Zn=5:2:5, In:Sn:Zn=10:1:10, In:Sn:Zn=20:1:10, or In:Sn:Zn=40:1:10, or a neighborhood thereof can be used.

In the case where an In—Al—Zn oxide is used for the semiconductor layer 108, a metal oxide in which the atomic ratio of indium is higher than that of aluminum can be used. Furthermore, it is preferable to use a metal oxide in which the atomic ratio of zinc is higher than that of aluminum. For example, a metal oxide in which the atomic ratio of metal elements is In:Al:Zn=2:1:3, In:Al:Zn=3:1:2, In:Al:Zn=4:2:3, In:Al:Zn=4:2:4.1, In:Al:Zn=5:1:3, In:Al:Zn=5:1:6, In:Al:Zn=5:1:7, In:Al:Zn=5:1:8, In:Al:Zn=6:1:6, In:Al:Zn=10:1:3, In:Al:Zn=10:1:6, In:Al:Zn=10:1:7, In:Al:Zn=10:1:8, In:Al:Zn=5:2:5, In:Al:Zn=10:1:10, In:Al:Zn=20:1:10, or In:Al:Zn=40:1:10, or a neighborhood thereof can be used.

In the case where an In—Ga—Zn oxide is used for the semiconductor layer 108, a metal oxide in which the atomic ratio of indium to the metal elements is higher than that of gallium can be used. It is further preferable to use a metal oxide in which the atomic ratio of zinc is higher than that of gallium. For example, a metal oxide in which the atomic ratio of metal elements is In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, or a neighborhood thereof can be used for the semiconductor layer 108.

In the case where an In-M-Zn oxide is used for the semiconductor layer 108, a metal oxide in which the atomic ratio of indium to the metal elements is higher than that of the element M can be used. It is further preferable to use a metal oxide in which the atomic ratio of zinc is higher than that of the element M. For example, a metal oxide in which the atomic ratio of metal elements is In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:3, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, or a neighborhood thereof can be used for the semiconductor layer 108.

Note that in the case where a plurality of metal elements are contained as the element M, the atomic ratio of the sum of the metal elements can be the atomic ratio of the element M. In an In—Ga—Al—Zn oxide where gallium and aluminum are contained as the element M, for example, the atomic ratio of the sum of gallium and aluminum can be the atomic ratio of the element M. The atomic ratio of indium to the element M to zinc is preferably within the ranges given above.

It is preferable to use a metal oxide in which the atomic ratio of indium to the metal elements contained in the metal oxide is higher than or equal to 30 atomic % and lower than or equal to 100 atomic %, preferably higher than or equal to 30 atomic % and lower than or equal to 95 atomic %, further preferably higher than or equal to 35 atomic % and lower than or equal to 95 atomic %, still further preferably higher than or equal to 35 atomic % and lower than or equal to 90 atomic %, yet still further preferably higher than or equal to 40 atomic % and lower than or equal to 90 atomic %, yet still further preferably higher than or equal to 45 atomic % and lower than or equal to 90 atomic %, yet still further preferably higher than or equal to 50 atomic % and lower than or equal to 80 atomic %, yet still further preferably higher than or equal to 60 atomic % and lower than or equal to 80 atomic %, yet still further preferably higher than or equal to 70 atomic % and lower than or equal to 80 atomic %. For example, when an In—Ga—Zn oxide is used for the semiconductor layer 108, the ratio of the number of indium atoms to the total number of the atoms of indium, the element M, and zinc is preferably within the ranges given above.

In this specification and the like, the atomic ratio of indium to the metal elements contained is sometimes referred to as indium content. The same applies to other metal elements.

Higher indium content in the metal oxide enables the transistor to have high on-state current. By using such a transistor as a transistor required to have high on-state current, a semiconductor device having excellent electrical characteristics can be provided.

As an analysis method of the composition of a metal oxide, for example, energy dispersive X-ray spectroscopy (EDX), X-ray photoelectron spectroscopy (XPS), inductively coupled plasma-mass spectroscopy (ICP-MS), or inductively coupled plasma-atomic emission spectrometry (ICP-AES) can be used. In addition, some of the analysis methods may be combined to perform an analysis. Note that as for an element whose content is low, the actual content may be different from the content obtained by analysis because of the influence of the analysis accuracy. In the case where the content of the element M is low, for example, the content of the element M obtained by analysis may be lower than the actual content.

Note that a composition in the neighborhood in this specification and the like includes the range of +30% of an intended atomic ratio. For example, when the atomic ratio is described as In:M:Zn=4:2:3 or a composition in the neighborhood thereof, the case is included where the atomic ratio of the element M is greater than or equal to 1 and less than or equal to 3 and the atomic ratio of zinc is greater than or equal to 2 and less than or equal to 4 with the atomic ratio of indium being 4. When the atomic ratio is described as In:M:Zn=5:1:6 or a composition in the neighborhood thereof, the case is included where the atomic ratio of the element M is greater than 0.1 and less than or equal to 2 and the atomic ratio of zinc is greater than or equal to 5 and less than or equal to 7 with the atomic ratio of indium being 5. When the atomic ratio is described as In:M:Zn=1:1:1 or a composition in the neighborhood thereof, the case is included where the atomic ratio of the element M is greater than 0.1 and less than or equal to 2 and the atomic ratio of zinc is greater than 0.1 and less than or equal to 2 with the atomic ratio of indium being 1. A sputtering method or an atomic layer deposition (ALD) method can be suitably used for forming a metal oxide. Note that in the case where the metal oxide is formed by a sputtering method, the atomic ratio of a target may be different from the atomic ratio of the metal oxide. In particular, the atomic ratio of zinc in the metal oxide is lower than the atomic ratio of zinc in the target in some cases. Specifically, the atomic ratio of zinc contained in the metal oxide may be approximately 40% to 90% of the atomic ratio of zinc contained in the target.

Here, the reliability of a transistor is described. One of indicators of evaluating the reliability of a transistor is a GBT (Gate Bias Temperature) stress test in which a state of applying an electric field to a gate is maintained. Among GBTs, a test in which a state where a positive potential (positive bias) relative to a source potential and a drain potential is supplied to a gate is maintained at high temperatures is referred to as a PBTS (Positive Bias Temperature Stress) test, and a test in which a state where a negative potential (negative bias) is supplied to a gate is maintained at high temperatures is referred to as an NBTS (Negative Bias Temperature Stress) test. The PBTS test and the NBTS test conducted under light irradiation are respectively referred to as a PBTIS (Positive Bias Temperature Illumination Stress) test and an NBTIS (Negative Bias Temperature Illumination Stress) test.

In particular, in an n-channel transistor, a positive potential is applied to a gate in putting the transistor in an on state (a state where current flows); thus, the amount of change in threshold voltage in the PBTS test is one important item to be focused on as an indicator of the reliability of the transistor.

With use of a metal oxide that does not contain gallium or has low gallium content for the semiconductor layer 108, the transistor can be highly reliable against positive bias application. In other words, the amount of change in the threshold voltage of the transistor in the PBTS test can be small. Meanwhile, with use of a metal oxide that contains gallium, the gallium content is preferably lower than the indium content. Thus, a highly reliable transistor can be achieved.

One of the factors in change in the threshold voltage in the PBTS test is a defect state at the interface between a semiconductor layer and a gate insulating layer or in the vicinity of the interface. As the density of defect states increases, degradation in the PBTS test becomes noticeable. Generation of the defect states can be inhibited by reducing the gallium content in a region of the semiconductor layer that is in contact with the gate insulating layer.

The following can be given as the reason why the amount of change in the threshold voltage in the PBTS test can be reduced when a metal oxide that does not contain gallium or has low gallium content is used for the semiconductor layer. Gallium contained in a metal oxide has a property of attracting oxygen more easily than another metal element (e.g., indium or zinc) does. Thus, when, at the interface between a metal oxide containing a large amount of gallium and the gate insulating layer, gallium is bonded to excess oxygen in the gate insulating layer, trap sites of carriers (here, electrons) are probably generated easily. This probably causes the change in the threshold voltage when a positive potential is applied to a gate and carriers are trapped at the interface between the semiconductor layer and the gate insulating layer.

Specifically, in the case where an In—Ga—Zn oxide is used for the semiconductor layer 108, a metal oxide in which the atomic ratio of indium is higher than that of gallium can be used as the semiconductor layer 108. It is further preferable to use a metal oxide in which the atomic ratio of zinc is higher than that of gallium. In other words, a metal oxide in which the atomic ratio of metal elements satisfy In >Ga and Zn>Ga is preferably used as the semiconductor layer 108.

The semiconductor layer 108 is preferably formed using a metal oxide having the following compositions; the atomic ratio of gallium to the metal elements contained in the metal oxide is higher than 0 atomic % and lower than or equal to 50 atomic %, preferably higher than or equal to 0.1 atomic % and lower than or equal to 40 atomic %, further preferably higher than or equal to 0.1 atomic % and lower than or equal to 35 atomic %, still further preferably higher than or equal to 0.1 atomic % and lower than or equal to 30 atomic %, yet still further preferably higher than or equal to 0.1 atomic % and lower than or equal to 25 atomic %, yet still further preferably higher than or equal to 0.1 atomic % and lower than or equal to 20 atomic %, yet still further preferably higher than or equal to 0.1 atomic % and lower than or equal to 15 atomic %, yet still further preferably higher than or equal to 0.1 atomic % and lower than or equal to 10 atomic %. The reduction in the gallium content in the semiconductor layer enables the transistor to be highly resistant to the PBTS test. Note that oxygen vacancies (V_{O}) are less likely to be generated in the metal oxide when the metal oxide contains gallium.

A metal oxide not containing gallium may be used as the semiconductor layer 108. For example, an In—Zn oxide can be used for the semiconductor layer 108. In this case, when the atomic ratio of indium to metal elements contained in the metal oxide is increased, the field-effect mobility of the transistor can be increased. By contrast, when the atomic ratio of zinc to metal elements contained in the metal oxide is increased, the metal oxide has high crystallinity; thus, a change in the electrical characteristics of the transistor can be inhibited and the reliability can be increased. Alternatively, a metal oxide that contains neither gallium nor zinc, such as indium oxide, can be used as the semiconductor layer 108. The use of a metal oxide not containing gallium can make a change in the threshold voltage particularly in the PBTS test extremely small.

For example, an oxide containing indium and zinc can be used for the semiconductor layer 108. In that case, for example, a metal oxide where the atomic ratio of metal elements of In:Zn=2:3, In:Zn=4:1, or a neighborhood thereof can be used.

Although the case of using gallium is described as an example, the same applies to the case where the element M is used instead of gallium. In particular, a metal oxide in which the atomic ratio of indium is higher than the atomic ratio of the element M is preferably used as the semiconductor layer 108. Furthermore, a metal oxide in which the atomic ratio of zinc is higher than the atomic ratio of the element M is preferably used.

With the use of a metal oxide with a low content of the element M for the semiconductor layer 108, the transistor can be highly reliable against positive bias application. With use of the transistor as a transistor that is required to have high reliability against positive bias application, a highly reliable semiconductor device can be provided.

Next, the reliability of a transistor against light is described.

Light irradiation on a transistor may change electrical characteristics of the transistor. In particular, a transistor provided in a region on which light can be incident preferably exhibits a small variation in electrical characteristics under light irradiation and has high reliability against light. The reliability against light can be evaluated with the amount of change in threshold voltage in a NBTIS test, for example.

The high content of the element M in the metal oxide enables the transistor to be highly reliable against light. In other words, the amount of change in the threshold voltage of the transistor in the NBTIS test can be small. Specifically, in a metal oxide in which the atomic ratio of the element M is higher than or equal to that of indium, the band gap is increased and accordingly the amount of change in the threshold voltage of the transistor in the NBTIS test can be reduced. The band gap of the metal oxide in the semiconductor layer 108 is preferably greater than or equal to 2.0 eV, further preferably greater than or equal to 2.5 eV, still further preferably greater than or equal to 3.0 eV, yet still further preferably greater than or equal to 3.2 eV, yet still further preferably greater than or equal to 3.3 eV, yet still further preferably greater than or equal to 3.4 eV, yet still further preferably greater than or equal to 3.5 eV.

For example, a metal oxide with the atomic ratio of metal elements of In:M:Zn=1:1:1, In:M:Zn=1:1:1.2, In:M:Zn=1:3:2, In:M:Zn=1:3:3, or In:M:Zn=1:3:4, or a neighborhood thereof can be used for the semiconductor layer 108.

For the semiconductor layer 108, in particular, it is preferable to use a metal oxide in which the atomic ratio of the element M to the metal elements contained in the metal oxide is higher than or equal to 20 atomic % and lower than or equal to 70 atomic %, preferably higher than or equal to 30 atomic % and lower than or equal to 70 atomic %, further preferably higher than or equal to 30 atomic % and lower than or equal to 60 atomic %, still further preferably higher than or equal to 40 atomic % and lower than or equal to 60 atomic %, yet still further preferably higher than or equal to 50 atomic % and lower than or equal to 60 atomic %.

In the case where an In—Ga—Zn oxide is used for the semiconductor layer 108, a metal oxide in which the atomic ratio of indium to the metal elements is lower than or equal to that of gallium can be used. For example, it is possible to use a metal oxide with metal elements in any of the following atomic ratios: In:Ga:Zn=1:1:1, In:Ga:Zn=1:1:1.2, In:Ga:Zn=1:3:2, In:Ga:Zn=1:3:3, In:Ga:Zn=1:3:4, and a neighborhood thereof.

For the semiconductor layer 108, in particular, it is preferable to use a metal oxide in which the atomic ratio of gallium to the metal elements contained in the metal oxide is higher than or equal to 20 atomic % and lower than or equal to 60 atomic %, preferably higher than or equal to 20% atomic % and lower than or equal to 50 atomic %, further preferably higher than or equal to 30 atomic % and lower than or equal to 50 atomic %, still further preferably higher than or equal to 40% atomic % and lower than or equal to 60 atomic %, yet still further preferably higher than or equal to 50% atomic % and lower than or equal to 60 atomic %.

With the use of a metal oxide with a high content of the element M for the semiconductor layer 108, the transistor can be highly reliable against light. With use of the transistor as a transistor that is required to have high reliability against light, a highly reliable semiconductor device can be provided.

As described above, electrical characteristics and reliability of a transistor vary depending on the composition of the metal oxide used for the semiconductor layer 108. Therefore, by determining the composition of the metal oxide in accordance with the electrical characteristics and reliability required for the transistor, the semiconductor device can have both good electrical characteristics and high reliability.

The semiconductor layer 108 may have a stacked-layer structure of two or more metal oxide layers. The two or more metal oxide layers included in the semiconductor layer 108 may have the same composition or substantially the same compositions. With the stacked-layer structure of metal oxide layers having the same compositions, the manufacturing cost can be reduced because the metal oxide layers can be formed with use of the same sputtering target.

The two or more metal oxide layers included in the semiconductor layer 108 may have different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and provided over the first metal oxide layer can be suitably used. In particular, gallium or aluminum is preferably used as the element M. For another example, a stacked-layer structure of one selected from indium oxide, indium gallium oxide, and IGZO, and one selected from IAZO, IAGZO, and ITZO (registered trademark) may be employed.

It is preferable to use a metal oxide layer having crystallinity as the semiconductor layer 108. For example, a metal oxide layer having a CAAC (c-axis aligned crystal) structure described later, a polycrystalline structure, a nano-crystal (nc) structure, or the like can be used. With the use of a metal oxide layer having crystallinity as the semiconductor layer 108, the density of defect states in the semiconductor layer 108 can be reduced, which enables the semiconductor device to have high reliability.

The higher the crystallinity of the metal oxide layer used for the semiconductor layer 108 is, the lower the density of defect states in the semiconductor layer 108 can be. By contrast, the use of a metal oxide layer with low crystallinity enables a transistor to flow a large amount of current.

In the case where the metal oxide layer is formed by a sputtering method, the crystallinity of the formed metal oxide layer can be increased as the substrate temperature at the time of formation is higher. For example, the substrate temperature at the time of formation can be adjusted by the temperature of the stage where the substrate is placed. The crystallinity of the metal oxide layer can be increased as the proportion of a flow rate of an oxygen gas to the whole deposition gas (hereinafter also referred to as oxygen flow rate ratio) used at the time of formation or the oxygen partial pressure in a treatment chamber of a deposition apparatus is higher.

The semiconductor layer 108 may have a stacked-layer structure of two or more metal oxide layers having different crystallinities. For example, a stacked-layer structure of a first metal oxide layer and a second metal oxide layer over the first metal oxide layer can be employed; the second metal oxide layer can include a region having higher crystallinity than the first metal oxide layer. Alternatively, the second metal oxide layer can include a region having lower crystallinity than the first metal oxide layer. The two or more metal oxide layers included in the semiconductor layer 108 may have the same composition or substantially the same compositions. With the stacked-layer structure of metal oxide layers having the same compositions, the manufacturing cost can be reduced because the metal oxide layers can be formed with use of the same sputtering target. For example, with use of the same sputtering target and different oxygen flow rate ratios or oxygen partial pressures, a stacked-layer structure of two or more metal oxide layers having different crystallinities can be formed. The two or more metal oxide layers included in the semiconductor layer 108 may have different compositions.

The substrate temperature at the time of forming the semiconductor layer 108 is preferably higher than or equal to room temperature (25° C.) and lower than or equal to 200° C., further preferably higher than or equal to room temperature and lower than or equal to 130° C. With the substrate temperature in the above range, the bending or warpage of the substrate can be inhibited in the case where a large-area glass substrate is used.

Here, oxygen vacancies that might be formed in the semiconductor layer 108 will be described.

In the case where an oxide semiconductor is used for the semiconductor layer 108, hydrogen contained in the oxide semiconductor reacts with oxygen bonded to a metal atom to be water, and thus an oxygen vacancy (V_{O}) is sometimes formed in the oxide semiconductor. In some cases, a defect where hydrogen enters an oxygen vacancy (hereinafter, referred to as V_{O}H) functions as a donor and generates an electron serving as a carrier. In other cases, bonding of part of hydrogen to oxygen bonded to a metal atom generates electrons serving as carriers. Thus, a transistor using an oxide semiconductor that contains a large amount of hydrogen is likely to be normally-on. Moreover, hydrogen in an oxide semiconductor is easily transferred by a stress such as heat or an electric field; thus, a large amount of hydrogen in an oxide semiconductor might reduce the reliability of a transistor.

V_{O}H can serve as a donor of the oxide semiconductor. However, it is difficult to evaluate the defect quantitatively. Thus, the oxide semiconductor is sometimes evaluated by not its donor concentration but its carrier concentration. Therefore, in this specification and the like, the carrier concentration on the assumption that an electric field is not applied is sometimes used, instead of the donor concentration, as the parameter of the oxide semiconductor. That is, “carrier concentration” described in this specification and the like can be replaced with “donor concentration” in some cases.

Accordingly, in the case where an oxide semiconductor is used as the semiconductor layer 108, the amount of V_{O}H in the semiconductor layer 108 is preferably reduced as much as possible so that the semiconductor layer 108 becomes a highly purified intrinsic or substantially highly purified intrinsic semiconductor layer. In order to obtain such an oxide semiconductor with sufficiently reduced V_{O}H, it is important to remove impurities such as water and hydrogen in the oxide semiconductor (this treatment is sometimes referred to as dehydrogenation treatment) and to repair oxygen vacancies (V_{O}) by supplying oxygen to the oxide semiconductor. When an oxide semiconductor with sufficiently reduced impurities such as V_{O}H is used for a channel formation region of a transistor, stable electrical characteristics can be given. Repairing oxygen vacancies (V_{O}) by supplying oxygen to the oxide semiconductor is sometimes referred to as oxygen adding treatment.

When an oxide semiconductor is used for the semiconductor layer 108, the carrier concentration of the oxide semiconductor in a region functioning as the channel formation region is preferably lower than or equal to 1×10¹⁸ cm⁻³, further preferably lower than 1×10¹⁷ cm⁻³, still further preferably lower than 1×10¹⁶ cm⁻³, yet still further preferably lower than 1×10¹³ cm⁻³, yet still further preferably lower than 1×10¹² cm⁻³. Note that the lower limit of the carrier concentration of the oxide semiconductor in the region functioning as the channel formation region is not particularly limited and can be, for example, 1×10⁻⁹ cm⁻³.

A transistor using an oxide semiconductor (hereinafter also referred to as an OS transistor) has much higher field-effect mobility than a transistor using amorphous silicon. In addition, the OS transistor has extremely low leakage current between a source and a drain in an off state (hereinafter, also referred to as off-state current), and electric charge accumulated in a capacitor that is connected in series to the transistor can be retained for a long period. Furthermore, the power consumption of the semiconductor device can be reduced with use of the OS transistor.

The semiconductor device that is one embodiment of the present invention can be used for a display apparatus, for example. To increase the emission luminance of the light-emitting device included in a pixel circuit of a display apparatus, it is necessary to increase the amount of current flowing through the light-emitting device. For that purpose, the source-drain voltage of the driving transistor included in the pixel circuit needs to be increased. Since an OS transistor has a higher withstand voltage between the source and the drain than a transistor including silicon (hereinafter referred to as a Si transistor), a high voltage can be applied between the source and the drain of the OS transistor. Thus, by using an OS transistor as a driving transistor included in the pixel circuit, the amount of current flowing through the light-emitting device can be increased, resulting in an increase in emission luminance of the light-emitting device.

When transistors operate in a saturation region, a change in source-drain current with respect to a change in gate-source voltage can be smaller in an OS transistor than in a Si transistor. Accordingly, when an OS transistor is used as the driving transistor included in the pixel circuit, current flowing between the source and the drain can be set minutely by a change in gate-source voltage; hence, the amount of current flowing through the light-emitting device can be controlled. Accordingly, the number of gray levels in the pixel circuit can be increased.

Regarding saturation characteristics of current flowing when a transistor operates in a saturation region, even in the case where the source-drain voltage of an OS transistor increases gradually, more stable current (saturation current) can be made flow through an OS transistor than through a Si transistor. Thus, with use of an OS transistor as a driving transistor, current can be made flow stably to the light-emitting device, for example, even when a variation in current-voltage characteristics of the light-emitting device occurs. In other words, when the OS transistor operates in the saturation region, the source-drain current hardly changes with an increase in the source-drain voltage; hence, the emission luminance of the light-emitting device can be stable.

As described above, by using an OS transistor as the driving transistor included in the pixel circuit, it is possible to achieve “inhibition of black floating”, “increase in emission luminance”, “increase in the number of gray levels”, “inhibition of variation in light-emitting devices”, and the like.

A change in electrical characteristics of an OS transistor due to radiation exposure is small, i.e., an OS transistor has high tolerance to radiation; thus, an OS transistor can be suitably used even in an environment that may be exposed to radiation. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

### [Insulating Layer 110]

For the insulating layer 110, an inorganic insulating material or an organic insulating material can be used. The insulating layer 110 may have a stacked-layer structure of a layer including an inorganic material and a layer including an organic material.

An inorganic material can be suitably used for the insulating layer 110. As the inorganic material, one or more of an oxide, an oxynitride, a nitride oxide, and a nitride can be used. For the insulating layer 110, for example, one or more of silicon oxide, silicon oxynitride, aluminum oxide, hafnium oxide, yttrium oxide, zirconium oxide, gallium oxide, tantalum oxide, magnesium oxide, lanthanum oxide, cerium oxide, neodymium oxide, silicon nitride, silicon nitride oxide, and aluminum nitride can be used.

Note that in this specification and the like, an oxynitride refers to a material that contains more oxygen than nitrogen in its composition. A nitride oxide refers to a material that contains more nitrogen than oxygen in its composition. For example, a silicon oxynitride refers to a material that contains more oxygen than nitrogen in its composition, and a silicon nitride oxide refers to a material that contains more nitrogen than oxygen in its composition.

The contents of oxygen and nitrogen can be analyzed using secondary ion mass spectrometry (SIMS) or X-ray photoelectron spectroscopy (XPS). XPS is suitable when the content of a target element is high (e.g., higher than or equal to 0.5 atomic %, or higher than or equal to 1 atomic %). By contrast, SIMS is suitable when the content of a target element is low (e.g., lower than 0.5 atomic % or, or lower than 1 atomic %). To compare the contents of elements, analysis with a combination of SIMS and XPS is further preferably used.

The insulating layer 110 may have a stacked-layer structure of two or more layers. FIG. 1B and the like illustrate a structure in which the insulating layer 110 has a stacked-layer structure of an insulating layer 110a and an insulating layer 110b over the insulating layer 110a. For each of the insulating layer 110a and the insulating layer 110b, the above-described material that can be used for the insulating layer 110 can be used. Note that the insulating layer 110a and the insulating layer 110b may be formed using the same material or different materials. Note that the insulating layer 110a may have a stacked-layer structure of two or more layers. Note that the insulating layer 110b may have a stacked-layer structure of two or more layers.

The thickness of the insulating layer 110a can be larger than that of the insulating layer 110b. The film-formation speed of the insulating layer 110a is preferably high. In particular, the film-formation speed of the insulating layer 110a is preferably high in the case where the thickness of the insulating layer 110a is large. By increasing the film-formation speed of the insulating layer 110a, the productivity can be increased. For example, by increasing power at the time of forming the insulating layer 110a, the film-formation speed can be increased.

The stress of the insulating layer 110a is preferably low. When the thickness of the insulating layer 110a is increased, the stress of the insulating layer 110a is increased, so that warpage of the substrate might be caused. By making the stress of the insulating layer 110a low, a problem in the process caused by stress such as warpage of the substrate can be inhibited from arising.

The insulating layer 110b functions as a blocking film that inhibits release of gas from the insulating layer 110a. For the insulating layer 110b, a material that does not easily allow diffusion of gas is preferably used. The insulating layer 110b preferably includes a region having a higher film density than the insulating layer 110a. The blocking property of the insulating layer 110b can be enhanced by increasing the film density of the insulating layer 110b. A material containing more nitrogen than the insulating layer 110a can be used for the insulating layer 110b. The blocking property of the insulating layer 110b can be enhanced by increasing the content of nitrogen in the insulating layer 110b.

The insulating layer 110b can be thinner than the insulating layer 110a as long as the insulating layer 110b has a thickness that is sufficient for the function of a blocking film that inhibits release of gas from the insulating layer 110a. The film-formation speed of the insulating layer 110b is preferably lower than that of the insulating layer 110a. Note that by making the film-formation speed of the insulating layer 110b low, the insulating layer 110b can have increased film density, so that the blocking property of the insulating layer 110b can be enhanced. Similarly, by making the substrate temperature at the time of forming the insulating layer 110b high, the insulating layer 110b can have increased film density, so that the blocking property of the insulating layer 110b can be enhanced.

Even in the case where the same material is used for the insulating layer 110a and the insulating layer 110b, the boundary therebetween can sometimes be observed as a difference in contrast in a transmission electron microscopy (TEM) image or the like of the cross section because the insulating layer 110a and the insulating layer 110b have different film densities. In the TEM observation, the transmission electron (TE) image of a portion where the film density is high is dark-colored (dark), and the transmission electron (TE) image of a portion where the film density is low is pale (bright). Therefore, the transmission electron (TE) image of the insulating layer 110b is a dark-colored (dark) image compared to the insulating layer 110a in some cases.

The insulating layer 110b may include a region where the hydrogen concentration in the film is lower than that of the insulating layer 110a. The difference in hydrogen concentration between the insulating layer 110a and the insulating layer 110b can be examined by secondary ion mass spectrometry (SIMS), for example.

Here, the insulating layer 110 will be described in detail in an example of a structure in which a metal oxide is used for the semiconductor layer 108.

In the case where an oxide semiconductor is used for the semiconductor layer 108, an inorganic insulating material can be suitably used for each of the insulating layer 110a and the insulating layer 110b.

An oxide or an oxynitride is preferably used as the insulating layer 110a. A film from which oxygen is released by heating is preferably used as the insulating layer 110a. For the insulating layer 110a, a silicon oxide or a silicon oxynitride can be suitably used, for example.

Oxygen release from the insulating layer 110a enables oxygen supply from the insulating layer 110a to the semiconductor layer 108. The oxygen supply from the insulating layer 110a to the semiconductor layer 108, particularly to the channel formation region of the semiconductor layer 108, reduces oxygen vacancies (V_{O}) and V_{O}H in the semiconductor layer 108, so that the transistor can have favorable electrical characteristics and high reliability. The insulating layer 110a preferably has a high oxygen diffusion coefficient. A high oxygen diffusion coefficient of the insulating layer 110a facilitates diffusion of oxygen in the insulating layer 110a, so that oxygen can be efficiently supplied from the insulating layer 110a to the semiconductor layer 108. Note that examples of treatment for supplying oxygen to the semiconductor layer 108 include heat treatment in an oxygen-containing atmosphere and plasma treatment in an oxygen-containing atmosphere.

The amount of impurities (e.g., water and hydrogen) released from the insulating layer 110a itself is preferably small. With the insulating layer 110a from which a small amount of impurities is released, diffusion of impurities to the semiconductor layer 108 is inhibited, and the transistor can have favorable electrical characteristics and high reliability.

For the insulating layer 110a, silicon oxide or silicon oxynitride formed by a plasma-enhanced chemical vapor deposition (PECVD: Plasma Enhanced CVD) method can be suitably used, for example. In that case, a mixed gas including a gas containing silicon and a gas containing oxygen is preferably used as a source gas. As the gas containing silicon, one or more of silane, disilane, trisilane, and silane fluoride can be used, for example. As the gas containing oxygen, one or more of oxygen (O₂), ozone (O₃), nitrous oxide (N₂O), nitric oxide (NO), and nitrogen dioxide (NO₂) can be used, for example. Note that by increasing power at the time of forming the insulating layer 110a, the amount of impurities (e.g., water and hydrogen) released from the insulating layer 110a can be reduced.

The insulating layer 110b is preferably less likely to transmit oxygen. The insulating layer 110b functions as a blocking film that inhibits release of oxygen from the insulating layer 110a. Moreover, the insulating layer 110b is preferably less likely to transmit hydrogen. The insulating layer 110b functions as a blocking film that inhibits diffusion of hydrogen into the semiconductor layer 108 from the outside of the transistor through the insulating layer 110. The insulating layer 110b preferably has a high film density. The blocking property against oxygen and hydrogen of the insulating layer 110b can be enhanced by increasing the film density of the insulating layer 110b. The film density of the insulating layer 110b is preferably higher than that of the insulating layer 110a. The insulating layer 110b preferably includes a region containing more nitrogen than the insulating layer 110a, for example. A material containing more nitrogen than the insulating layer 110a can be used for the insulating layer 110b, for example. A nitride or a nitride oxide is preferably used for the insulating layer 110b. For example, silicon nitride or silicon nitride oxide can be suitably used for the insulating layer 110b.

When oxygen contained in the insulating layer 110a is diffused upward from a region of the insulating layer 110a that is not in contact with the semiconductor layer 108 (e.g., the top surface of the insulating layer 110a), the amount of oxygen supplied from the insulating layer 110a to the semiconductor layer 108 may be reduced. Provision of the insulating layer 110b over the insulating layer 110a can inhibit diffusion of oxygen contained in the insulating layer 110a from the region of the insulating layer 110a that is not in contact with the semiconductor layer 108. Accordingly, the amount of oxygen supplied from the insulating layer 110a to the semiconductor layer 108 is increased, whereby oxygen vacancies (V_{O}) and V_{O}H in the semiconductor layer 108 can be reduced. Consequently, the transistor can have favorable electrical characteristics and high reliability.

The conductive layer 112b is oxidized by oxygen contained in the insulating layer 110a and has high resistance in some cases. Moreover, when the conductive layer 112b is oxidized by oxygen contained in the insulating layer 110a, the amount of oxygen supplied from the insulating layer 110a to the semiconductor layer 108 may be reduced. Provision of the insulating layer 110b over the insulating layer 110a can inhibit the conductive layer 112b from being oxidized and having high resistance. In addition, the amount of oxygen supplied from the insulating layer 110a to the semiconductor layer 108 is increased and oxygen vacancies (V_{O}) and V_{O}H in the semiconductor layer 108 can be reduced, whereby the transistor can have favorable electric characteristics and high reliability.

When hydrogen is diffused in the semiconductor layer 108, hydrogen reacts with an oxygen atom contained in an oxide semiconductor to be water, and thus sometimes forms oxygen vacancies (V_{O}). Furthermore, V_{O}H is formed and the carrier concentration is increased in some cases. Provision of the insulating layer 110b over the insulating layer 110a can reduce oxygen vacancies (V_{O}) and V_{O}H in the semiconductor layer 108, whereby the transistor can have favorable electric characteristics and high reliability.

The insulating layer 110b preferably has a thickness that is sufficient for the function of a blocking film against oxygen and hydrogen. When the insulating layer 110b is thin, the function of a blocking film deteriorates in some cases. Meanwhile, when the insulating layer 110b is thick, a region of the semiconductor layer 108 in contact with the insulating layer 110a is narrowed and the amount of oxygen supplied from the insulating layer 110a to the semiconductor layer 108 is sometimes reduced. The insulating layer 110b may be thinner than the insulating layer 110a. The thickness of the insulating layer 110b is preferably larger than or equal to 5 nm and smaller than or equal to 100 nm, further preferably larger than or equal to 5 nm and smaller than or equal to 70 nm, still further preferably larger than or equal to 10 nm and smaller than or equal to 70 nm, yet still further preferably larger than or equal to 10 nm and smaller than or equal to 50 nm, yet still further preferably larger than or equal to 20 nm and smaller than or equal to 50 nm, yet still further preferably larger than or equal to 20 nm and smaller than or equal to 40 nm. Setting the thickness of the insulating layer 110b in the above range can reduce oxygen vacancies (V_{O}) and V_{O}H in the semiconductor layer 108, particularly in the channel formation region, whereby the transistor can have favorable electric characteristics and high reliability.

The amount of impurities (e.g., water and hydrogen) released from the insulating layer 110b itself is preferably small. With the insulating layer 110b from which a small amount of impurities is released, diffusion of impurities to the semiconductor layer 108 is inhibited, and the transistor can have favorable electrical characteristics and high reliability.

In the transistor 100, a region of the semiconductor layer 108 in contact with the insulating layer 110 can function as the channel formation region. That is, oxygen is selectively supplied to the channel formation region, so that oxygen vacancies (V_{O}) and V_{O}H can be reduced. Consequently, the transistor can have favorable electrical characteristics and high reliability.

### [Conductive Layer 112a, Conductive Layer 112b, and Conductive Layer 104]

The conductive layer 112a and the conductive layer 112b functioning as the source electrode and the drain electrode and the conductive layer 104 functioning as the gate electrode can each be formed using one or more of chromium, copper, aluminum, gold, silver, zinc, molybdenum, tantalum, titanium, tungsten, manganese, nickel, iron, cobalt, and niobium; or an alloy including one or more of the above-described metals as its components. For the conductive layer 104, the conductive layer 112a, and the conductive layer 112b, a conductive material with low resistance that contains one or more of copper, silver, gold, and aluminum can be suitably used. Copper or aluminum is particularly preferable because of its high mass-productivity.

For the conductive layer 104, the conductive layer 112a, and the conductive layer 112b, a conductive metal oxide (also referred to as an oxide conductor) can be used. Examples of the oxide conductor (OC) include In—Sn oxide (ITO), In—W oxide, In—W—Zn oxide, In—Ti oxide, In—Ti—Sn oxide, In—Zn oxide, In—Sn—Si oxide (ITSO), and In—Ga—Zn oxide.

Here, an oxide conductor (OC) is described. For example, when oxygen vacancies are formed in a metal oxide having semiconductor characteristics and hydrogen is added to the oxygen vacancies, a donor level is formed in the vicinity of the conduction band. As a result, the conductivity of the metal oxide is increased, so that the metal oxide becomes a conductor. The metal oxide having become a conductor can be referred to as an oxide conductor.

In addition, each of the conductive layer 104, the conductive layer 112a, and the conductive layer 112b may have a stacked-layer structure of a conductive layer containing the above-described oxide conductor (the metal oxide) and a conductive layer containing a metal or an alloy. The use of the conductive layer containing a metal or an alloy can reduce the wiring resistance.

A Cu—X alloy film (X is Mn, Ni, Cr, Fe, Co, Mo, Ta, or Ti) may be used for the conductive layer 104, the conductive layer 112a, and the conductive layer 112b. The use of a Cu—X alloy film enables the manufacturing cost to be reduced because processing can be performed by a wet etching method.

Note that the conductive layer 104, the conductive layer 112a, and the conductive layer 112b may be formed using the same material or different materials.

Here, the conductive layer 112a and the conductive layer 112b will be described in detail in an example of a structure in which a metal oxide is used for the semiconductor layer 108.

When an oxide semiconductor is used for the semiconductor layer 108, the conductive layer 112a and the conductive layer 112b are oxidized by oxygen contained in the semiconductor layer 108 and have high resistance in some cases. The conductive layer 112a and the conductive layer 112b are oxidized by oxygen contained in the insulating layer 110a and have high resistance in some cases. Moreover, when the conductive layer 112a and the conductive layer 112b are oxidized by oxygen contained in the semiconductor layer 108, oxygen vacancies (V_{O}) in the semiconductor layer 108 are increased in some cases. When the conductive layer 112a and the conductive layer 112b are oxidized by oxygen contained in the insulating layer 110a, the amount of oxygen supplied from the insulating layer 110a to the semiconductor layer 108 is reduced in some cases.

A material that is less likely to be oxidized is preferably used for the conductive layer 112a and the conductive layer 112b. An oxide conductor is preferably used for each of the conductive layer 112a and the conductive layer 112b. For example, an In—Sn oxide (ITO) or an In—Sn—Si oxide (ITSO) can be suitably used. For each of the conductive layer 112a and the conductive layer 112b, a nitride conductor may be used. Examples of the nitride conductor include tantalum nitride and titanium nitride. The conductive layer 112a and the conductive layer 112b may have a stacked-layer structure of the above-described materials.

With the use of a material that is less likely to be oxidized for each of the conductive layer 112a and the conductive layer 112b, the conductive layer 112a and the conductive layer 112b can be inhibited from being oxidized by oxygen contained in the semiconductor layer 108 or oxygen contained in the insulating layer 110a and having higher resistance. Furthermore, it is possible to increase the amount of oxygen supplied from the insulating layer 110a to the semiconductor layer 108 while an increase in oxygen vacancies (V_{O}) in the semiconductor layer 108 is inhibited. Accordingly, oxygen vacancies (V_{O}) and V_{O}H in the semiconductor layer 108 can be reduced, whereby the transistor can have favorable electric characteristics and high reliability. Note that the conductive layer 112a and the conductive layer 112b may be formed using the same material or different materials.

### [Insulating Layer 106]

The insulating layer 106 functioning as the gate insulating layer preferably has low defect density. With the insulating layer 106 having low defect density, the transistor can have favorable electrical characteristics. Furthermore, the insulating layer 106 preferably has high withstand voltage. The high withstand voltage of the insulating layer 106 results in a transistor with high reliability.

For the insulating layer 106, one or more of oxide, oxynitride, nitride oxide, and nitride, each of which has insulating property, can be used, for example. For the insulating layer 106, one or more of silicon oxide, silicon oxynitride, silicon nitride oxide, silicon nitride, aluminum oxide, aluminum oxynitride, aluminum nitride oxide, aluminum nitride, hafnium oxide, hafnium oxynitride, gallium oxide, gallium oxynitride, yttrium oxide, yttrium oxynitride, and Ga—Zn oxide can be used. The insulating layer 106 may have a single-layer structure or a stacked-layer structure. The insulating layer 106 may have a stacked-layer structure of an oxide and a nitride.

In a miniaturized transistor, the small thickness of the gate insulating layer may cause large leakage current in some cases. When a high dielectric constant material (also referred to as a high-k material) is used for the gate insulating layer, the voltage at the time of operation of the transistor can be reduced while the physical thickness is maintained. Examples of the high-k material include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

The amount of impurities (e.g., water and hydrogen) released from the insulating layer 106 itself is preferably small. With the insulating layer 106 from which a small amount of impurities is released, diffusion of impurities to the semiconductor layer 108 is inhibited, and the transistor can have favorable electrical characteristics and high reliability.

The insulating layer 106 is formed over the semiconductor layer 108, and thus is preferably a film formed under conditions where damage to the semiconductor layer 108 is small. For example, the insulating layer 106 can be formed under conditions where the film-formation speed (also referred to as film-formation rate) is sufficiently low. For example, when the insulating layer 106 is formed by a PECVD method under a low-power condition, damage to the semiconductor layer 108 can be small.

Here, the insulating layer 106 will be described in detail in an example of a structure in which a metal oxide is used for the semiconductor layer 108.

To improve the properties of the interface with the semiconductor layer 108, at least the side of the insulating layer 106 that is in contact with the semiconductor layer 108 is preferably formed using an oxide or an oxynitride. For example, one or more of silicon oxide and silicon oxynitride can be suitably used for the insulating layer 106. Moreover, a film from which oxygen is released by heating is preferably used as the insulating layer 106.

Note that the insulating layer 106 may have a stacked-layer structure. The insulating layer 106 can have a stacked-layer structure of an oxide layer or an oxynitride layer on a side that is in contact with the semiconductor layer 108 and a nitride layer on a side that is in contact with the conductive layer 104. For example, as the oxide layer or the oxynitride layer, one or more of silicon oxide and silicon oxynitride can be suitably used. As the nitride layer, silicon nitride can be suitably used.

### [Substrate 102]

Although there is no particular limitation on a material and the like of the substrate 102, it is necessary that the substrate have heat resistance high enough to withstand at least heat treatment performed later. For example, a single crystal semiconductor substrate or a polycrystalline semiconductor substrate containing silicon or silicon carbide as a material, a compound semiconductor substrate of silicon germanium or the like, an SOI substrate, a glass substrate, a quartz substrate, a sapphire substrate, a ceramic substrate, or an organic resin substrate may be used as the substrate 102. Alternatively, any of these substrates over which a semiconductor element is provided may be used as the substrate 102. Note that the shapes of the semiconductor substrate and the insulating substrate may be circular or quadrilateral.

A flexible substrate may be used as the substrate 102, and the transistor 100 and the like may be formed directly on the flexible substrate. Alternatively, a separation layer may be provided between the substrate 102 and the transistor 100 and the like. The separation layer can be used when part or the whole of a semiconductor device completed thereover is separated from the substrate 102 and transferred onto another substrate. In that case, the transistor 100 and the like can be transferred onto a substrate having low heat resistance or a flexible substrate as well.

The above is the description of the components.

Note that in the case where a metal oxide is used for the semiconductor layer 108 and the insulating layer 110b contains hydrogen, it is possible that hydrogen can diffused into a region of the semiconductor layer 108 in contact with the insulating layer 110b and that oxygen vacancies (V_{O}) and V_{O}H can be increased in the semiconductor layer 108. Thus, the region of the semiconductor layer 108 in contact with the insulating layer 110b functions as the other of the source region and the drain region, and the region of the semiconductor layer 108 in contact with the insulating layer 110a functions as the channel formation region in some cases. That is, in the semiconductor layer 108, the region in contact with the conductive layer 112b and the region in contact with the insulating layer 110b sometimes function as the other of the source region and the drain region.

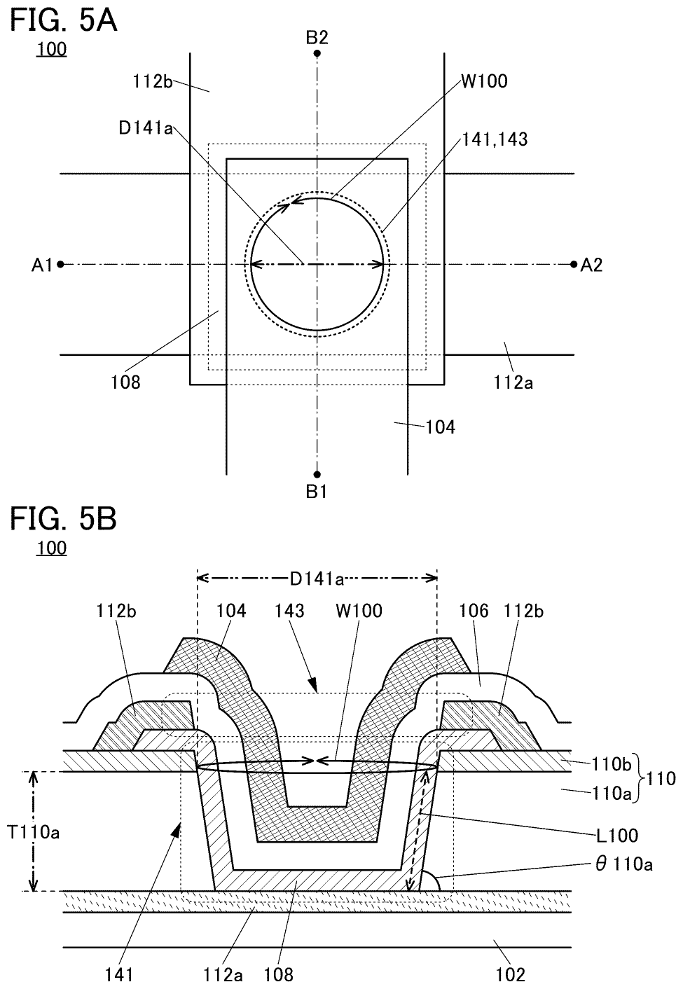

The channel length and the channel width in the case where the region of the semiconductor layer 108 in contact with the insulating layer 110b functions as the other of the source region and the drain region are described with reference to FIG. 5A and FIG. 5B. FIG. 5A is a top view of the transistor 100. FIG. 5B is an enlarged view of FIG. 1B.

The channel length L100 of the transistor 100 corresponds to the length of a side surface of the insulating layer 110a on the opening 141 side in a cross-sectional view. That is, the channel length L100 is determined by a thickness T110a of the insulating layer 110a and an angle θ1 10a formed between the side surface of the insulating layer 110a on the opening 141 side and a formation surface of the insulating layer 110a (here, the top surface of the conductive layer 112a), and is not affected by the performance of a light-exposure apparatus used for manufacturing the transistor. Thus, the channel length L100 can be a value smaller than that of the resolution limit of a light-exposure apparatus, which enables the transistor to have a minute size. For example, the channel length L100 can be within the above range. In FIG. 5B, the thickness T110a of the insulating layer 110a is indicated by a dashed-dotted double-headed arrow.

By adjusting the thickness T110a and the angle θ1 10a of the insulating layer 110a, the channel length L100 can be controlled.

The thickness T110a of the insulating layer 110a is preferably larger than or equal to 0.01 μm and smaller than 3 μm, further preferably larger than or equal to 0.05 μm and smaller than 3 μm, still further preferably larger than or equal to 0.1 μm and smaller than 3 μm, yet still further preferably larger than or equal to 0.15 μm and smaller than 3 μm, yet still further preferably larger than or equal to 0.2 μm and smaller than 3 μm, yet still further preferably larger than or equal to 0.2 μm and smaller than 2.5 μm, yet still further preferably larger than or equal to 0.2 μm and smaller than 2 μm, yet still further preferably larger than or equal to 0.2 μm and smaller than 1.5 μm, yet still further preferably larger than or equal to 0.3 μm and smaller than or equal to 1.5 μm, yet still further preferably larger than or equal to 0.3 μm and smaller than or equal to 1.2 μm, yet still further preferably larger than or equal to 0.4 μm and smaller than or equal to 1.2 μm, yet still further preferably larger than or equal to 0.4 μm and smaller than or equal to 1 μm, yet still further preferably larger than or equal to 0.5 μm and smaller than or equal to 1 μm.

The angle θ1 10a of the insulating layer 110a is preferably greater than or equal to 45° and less than 90°, further preferably greater than or equal to 50° and less than 90°, still further preferably greater than or equal to 55° and less than 90°, yet still further preferably greater than or equal to 60° and less than 90°, yet still further preferably greater than or equal to 60° and less than or equal to 85°, yet still further preferably greater than or equal to 65° and less than or equal to 85°, yet still further preferably greater than or equal to 65° and less than or equal to 80°, yet still further preferably greater than or equal to 70° and less than or equal to 80°.

In a top view, the channel width W100 is the length of the end portion of the bottom surface of the insulating layer 110b on the opening 141 side. In FIG. 5A and FIG. 5B, the channel width W100 of the transistor 100 is indicated by a solid double-headed arrow.

The channel width W100 is determined by the shape of the end portion of the bottom surface of the insulating layer 110b. In FIG. 5A and FIG. 5B, a width D141a between the end portions of the bottom surface of the insulating layer 110b facing each other in the opening 141 is indicated by a dashed double-dotted double-headed arrow. The width D141a refers to the shorter side of the smallest rectangle circumscribing the outline of the end portion of the bottom surface of the insulating layer 110b in the top view. For example, the width D141a is preferably larger than or equal to 0.2 μm and smaller than 5 μm, further preferably larger than or equal to 0.2 μm and smaller than 4.5 μm, still further preferably larger than or equal to 0.2 μm and smaller than 4 μm, yet still further preferably larger than or equal to 0.2 μm and smaller than 3.5 μm, yet still further preferably larger than or equal to 0.2 μm and smaller than 3 μm, yet still further preferably larger than or equal to 0.2 μm and smaller than 2.5 μm, yet still further preferably larger than or equal to 0.2 μm and smaller than 2 μm, yet still further preferably larger than or equal to 0.2 μm and smaller than 1.5 μm, yet still further preferably larger than or equal to 0.3 μm and smaller than or equal to 1.5 μm, yet still further preferably larger than or equal to 0.3 μm and smaller than or equal to 1.2 μm, yet still further preferably larger than or equal to 0.4 μm and smaller than or equal to 1.2 μm, yet still further preferably larger than or equal to 0.4 μm and smaller than or equal to 1 μm, yet still further preferably larger than or equal to 0.5 μm and smaller than or equal to 1 μm.

Note that hydrogen also diffuses into the region of the semiconductor layer 108 in contact with the insulating layer 110a from the insulating layer 110b in some cases. However, supply of oxygen from the insulating layer 110a to the semiconductor layer 108 inhibits an increase in oxygen vacancies (V_{O}) and V_{O}H in the region of the semiconductor layer 108 in contact with the insulating layer 110a. Thus, at least the region of the semiconductor layer 108 in contact with the insulating layer 110a can function as the channel formation region, and the transistor can have favorable electrical characteristics and high reliability.

A structure example of a transistor whose structure is partly different from that of Structure example 1 shown above will be described below. Note that description of the same portions as those in Structure example 1 shown above is omitted below in some cases. Furthermore, in drawings that are referred to later, the same hatching pattern is applied to portions having functions similar to those in Structure example 1 shown above, and the portions are not denoted by reference numerals in some cases.

### Structure Example 2

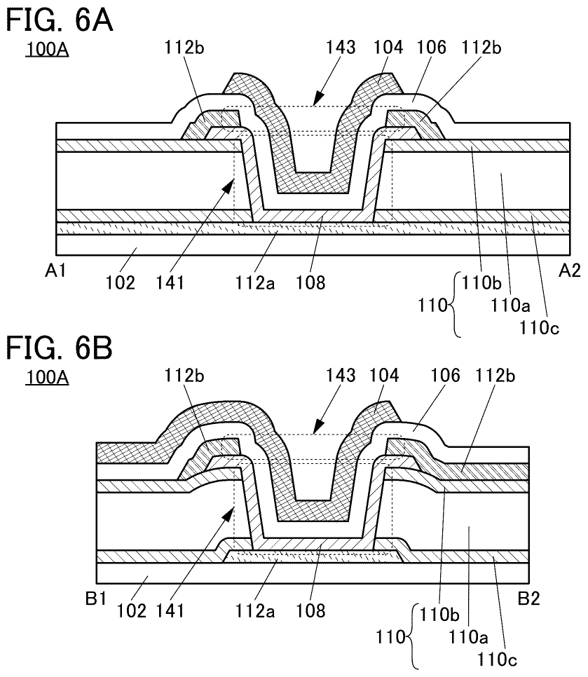

FIG. 1A can be referred to for a top view of a transistor 100A that can be used in the semiconductor device of one embodiment of the present invention. FIG. 6A is a cross-sectional view of a cut plane along the dashed-dotted line A1-A2 in FIG. 1A and FIG. 6B is a cross-sectional view of a cut plane along the dashed-dotted line B1-B2. FIG. 2 can be referred to for a perspective view of the transistor 100A.

The transistor 100A is different from the above-described transistor 100 mainly in that the insulating layer 110 includes an insulating layer 110c.

The insulating layer 110 has a stacked-layer structure of the insulating layer 110c, the insulating layer 110a over the insulating layer 110c, and the insulating layer 110b over the insulating layer 110a. The insulating layer 110c includes a region in contact with the top surface of the substrate 102 and the top surface and a side surface of the conductive layer 112a.

The insulating layer 110c functions as a blocking film that inhibits release of gas from the insulating layer 110a. For the insulating layer 110c, a material that does not easily allow diffusion of gas is preferably used. The insulating layer 110c preferably includes a region having a higher film density than the insulating layer 110a. The blocking property of the insulating layer 110c can be enhanced by increasing the film density of the insulating layer 110c. The insulating layer 110c preferably includes a region containing more nitrogen than the insulating layer 110a, for example. For the insulating layer 110c, a material containing more nitrogen than the insulating layer 110a can be used, for example. The blocking property of the insulating layer 110c can be enhanced by increasing the content of nitrogen in the insulating layer 110c.

The insulating layer 110c can be thinner than the insulating layer 110a as long as the insulating layer 110c has a thickness that is sufficient for the function of a blocking film that inhibits release of gas from the insulating layer 110a. The film-formation speed of the insulating layer 110c is preferably lower than that of the insulating layer 110a. Note that by making the film-formation speed of the insulating layer 110c low, the insulating layer 110c can have increased film density, so that the blocking property of the insulating layer 110c can be enhanced. Similarly, by making the substrate temperature at the time of forming the insulating layer 110c high, the film density of the insulating layer 110c is increased, so that the blocking property of the insulating layer 110c can be enhanced.

Even in the case where the same material is used for the insulating layer 110a and the insulating layer 110c, the boundary therebetween can sometimes be observed as a difference in contrast in a transmission electron microscopy (TEM) image or the like of the cross section because the insulating layer 110a and the insulating layer 110c have different film densities. In the TEM observation, the transmission electron (TE) image of a portion where the film density is high is dark-colored (dark), and the transmission electron (TE) image of a portion where the film density is low is pale (bright). Therefore, the transmission electron (TE) image of the insulating layer 110c is a dark-colored (dark) image compared to the insulating layer 110a in some cases.

The insulating layer 110a sometimes include a region where the hydrogen concentration in the film is higher than that of the insulating layer 110c. The difference in hydrogen concentration between the insulating layer 110a and the insulating layer 110c can be examined by secondary ion mass spectrometry (SIMS), for example.

For the insulating layer 110c, a material that can be used for the insulating layer 110b can be used. The insulating layer 110c and the insulating layer 110b may be formed using the same material or different materials.

The insulating layer 110c will be described in detail in an example of a case in which an oxide semiconductor is used for the semiconductor layer 108.

The insulating layer 110c is preferably less likely to transmit oxygen. The insulating layer 110c functions as a blocking film that inhibits release of oxygen from the insulating layer 110a.

The conductive layer 112a is oxidized by oxygen contained in the insulating layer 110a and has high resistance in some cases. Moreover, when the conductive layer 112a is oxidized by oxygen contained in the insulating layer 110a, the amount of oxygen supplied from the insulating layer 110a to the semiconductor layer 108 is reduced in some cases. Providing the insulating layer 110c between the insulating layer 110a and the conductive layer 112a can inhibit the conductive layer 112a from being oxidized and having high resistance. In addition, the amount of oxygen supplied from the insulating layer 110a to the semiconductor layer 108 is increased and oxygen vacancies (V_{O}) and V_{O}H in the semiconductor layer 108 can be reduced, whereby the transistor can have favorable electric characteristics and high reliability.

The insulating layer 110c is preferably less likely to transmit impurities. The insulating layer 110c functions as a blocking film that inhibits diffusion of impurities from the substrate 102 side into the semiconductor layer 108 through the insulating layer 110. Examples of the impurities include water, hydrogen, and sodium.

The insulating layer 110c preferably has a thickness that is sufficient for the function of a blocking film against oxygen and hydrogen. When the insulating layer 110c is thin, the function of a blocking film deteriorates in some cases. Meanwhile, when the insulating layer 110c is thick, a region where the semiconductor layer 108 is in contact with the insulating layer 110a is narrowed and the amount of oxygen supplied from the insulating layer 110a to the semiconductor layer 108 is sometimes reduced. The insulating layer 110c may be thinner than the insulating layer 110a. The thickness of the insulating layer 110c is preferably larger than or equal to 5 nm and smaller than or equal to 100 nm, further preferably larger than or equal to 5 nm and smaller than or equal to 70 nm, still further preferably larger than or equal to 10 nm and smaller than or equal to 70 nm, yet still further preferably larger than or equal to 10 nm and smaller than or equal to 50 nm, still yet still further preferably larger than or equal to 20 nm and smaller than or equal to 50 nm, yet still further preferably larger than or equal to 20 nm and smaller than or equal to 40 nm. Setting the thickness of the insulating layer 110c in the above range can reduce oxygen vacancies (V_{O}) and V_{O}H in the semiconductor layer 108, particularly in the channel formation region, whereby the transistor can have favorable electric characteristics and high reliability.

The amount of impurities (e.g., water and hydrogen) released from the insulating layer 110c itself is preferably small. With the insulating layer 110c from which a small amount of impurities is released, diffusion of impurities to the semiconductor layer 108 is inhibited, and the transistor can have favorable electrical characteristics and high reliability.

Note that when a metal oxide is used for the semiconductor layer 108 and the insulating layer 110c contains hydrogen, it is possible that hydrogen can be diffused into a region of the semiconductor layer 108 in contact with the insulating layer 110c and that oxygen vacancies (V_{O}) and V_{O}H can be increased in the semiconductor layer 108. Thus, the region of the semiconductor layer 108 in contact with the insulating layer 110c functions as one of the source region and the drain region in some cases. Similarly, the region of the semiconductor layer 108 in contact with the insulating layer 110b functions as the other of the source region and the drain region in some cases. The region of the semiconductor layer 108 in contact with the insulating layer 110a functions as the channel formation region in some cases.

In the case where the region of the semiconductor layer 108 in contact with the insulating layer 110b and the region of the semiconductor layer 108 in contact with the insulating layer 110c function as the source region and the drain region, the channel length L100 of the transistor 100A corresponds to the length of the side surface of the insulating layer 110a on the opening 141 side in the cross-sectional view (see FIG. 5B).

Note that hydrogen diffuses from the insulating layer 110c into the region of the semiconductor layer 108 in contact with the insulating layer 110a in some cases. Similarly, hydrogen diffuses from the insulating layer 110b into the region of the semiconductor layer 108 in contact with the insulating layer 110a in some cases. However, supply of oxygen from the insulating layer 110a to the semiconductor layer 108 inhibits an increase in oxygen vacancies (V_{O}) and V_{O}H in the region of the semiconductor layer 108 in contact with the insulating layer 110a. Thus, at least the region of the semiconductor layer 108 in contact with the insulating layer 110a can function as the channel formation region, and the transistor can have favorable electrical characteristics and high reliability.

Note that the structure of the insulating layer 110 described here can also be used in the other structure examples.

### Structure Example 3

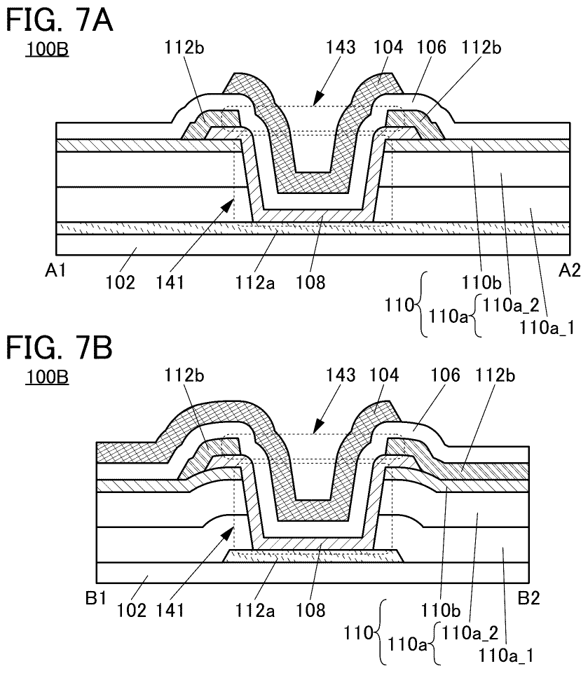

FIG. 1A can be referred to for a top view of a transistor 100B that can be used in the semiconductor device of one embodiment of the present invention. FIG. 7A is a cross-sectional view of a cut plane along the dashed-dotted line A1-A2 in FIG. 1A and FIG. 7B is a cross-sectional view of a cut plane along the dashed-dotted line B1-B2. FIG. 2 can be referred to for a perspective view of the transistor 100B.

The transistor 100B is different from the above-described transistor 100 mainly in that the insulating layer 110a has a stacked-layer structure.

The insulating layer 110a preferably has a stacked-layer structure of an insulating layer 110a_1 and an insulating layer 110a_2 over the insulating layer 110a_1. For each of the insulating layer 110a_1 and the insulating layer 110a_2, the material that can be used for the insulating layer 110a can be used. The insulating layer 110a_1 and the insulating layer 110a_2 may be formed using the same material or different materials. The insulating layer 110a_1 and the insulating layer 110a_2 may have different thicknesses.

When the thickness of the insulating layer 110a is increased, the stress of the insulating layer 110a is increased, so that warpage of the substrate might be caused. By forming the insulating layer 110a in a plurality of steps, a problem in the process caused by stress can be inhibited from arising.

Although FIG. 7A and FIG. 7B each illustrate a structure in which the insulating layer 110a has a stacked-layer structure of two layers, one embodiment of the present invention is not limited thereto. The insulating layer 110a may have a stacked-layer structure of three or more layers.

Note that in a transmission electron microscopy (TEM) image or the like of a cross section, a boundary between layers (e.g., the insulating layer 110a_1 and the insulating layer 110a_2) included in the insulating layer 110a is unclear in some cases.

Note that the structure of the insulating layer 110 described here can also be used in the other structure examples.

### Structure Example 4

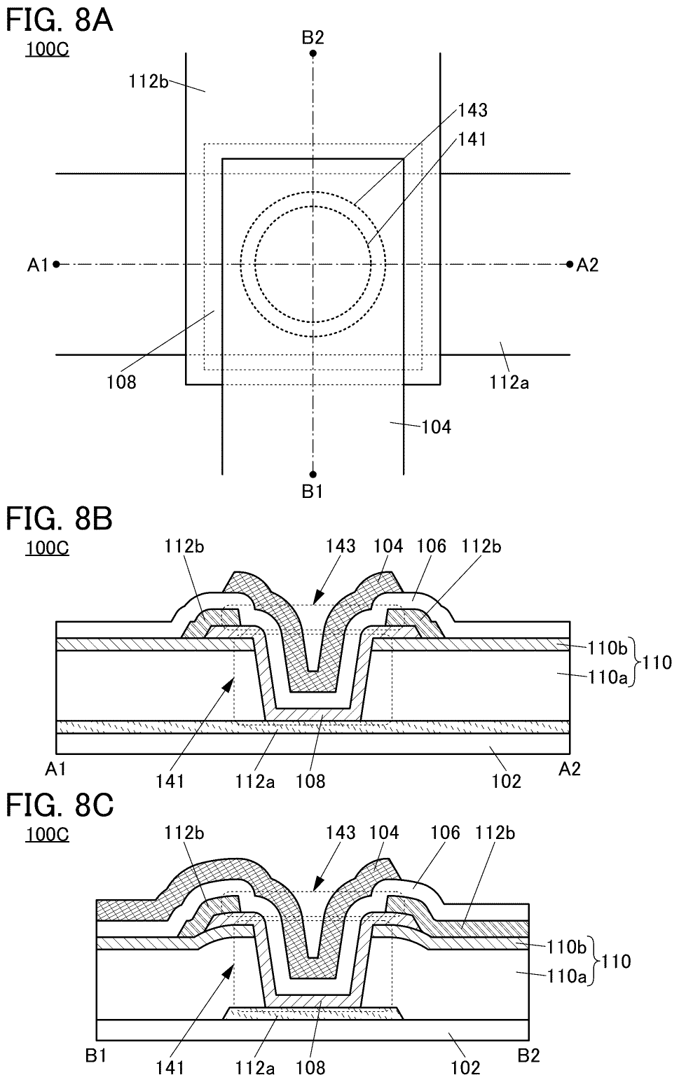

FIG. 8A is a top view of a transistor 100C that can be used in the semiconductor device of one embodiment of the present invention. FIG. 8B is a cross-sectional view of a cut plane along the dashed-dotted line A1-A2 in FIG. 8A and FIG. 8C is a cross-sectional view of a cut plane along the dashed-dotted line B1-B2. FIG. 2 can be referred to for a perspective view of the transistor 100C.

The transistor 100C is different from the transistor 100 mainly in that the top surface shape of the opening 143 does not match with the top surface shape of the opening 141.

The opening 143 preferably encompasses the opening 141 in the top view. When the end portion of the conductive layer 112b on the opening 143 side is positioned outward from the end portion of the insulating layer 110 on the opening 141 side, a step in the formation surface of a layer (e.g., the insulating layer 106) formed over the conductive layer 112b and the semiconductor layer 108 becomes small. Accordingly, coverage with the layer formed over the conductive layer 112b and the semiconductor layer 108 can be improved, so that generation of defects such as step disconnection or voids in the layer can be inhibited.

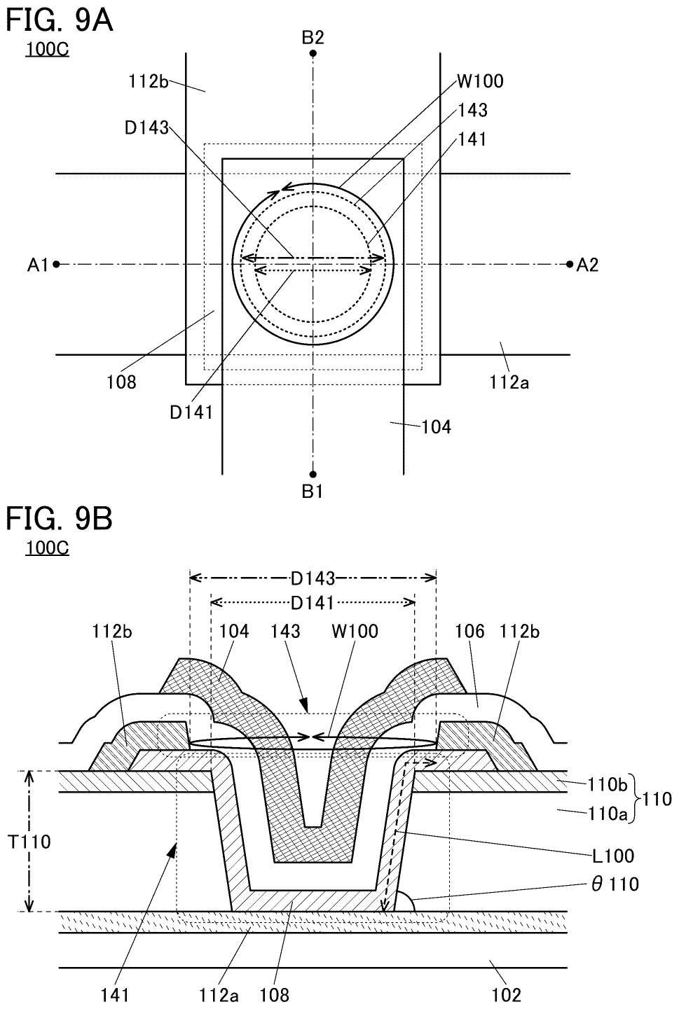

Here, the channel length and channel width of the transistor 100C are described with reference to FIG. 9A and FIG. 9B. FIG. 9A is a top view of the transistor 100C. FIG. 9B is an enlarged view of FIG. 8B.

In FIG. 9B, the channel length L100 of the transistor 100C is indicated by a dashed double-headed arrow. In FIG. 9A and FIG. 9B, the width D141 of the opening 141 is indicated by a dotted double-headed arrow, and the width D143 of the opening 143 is indicated by a dashed double-dotted double-headed arrow. The width D141 refers to the shorter side of the smallest rectangle circumscribing the opening 141 in the top view.

Here, the channel length L100 of the transistor 100C corresponds to the sum of the distance between the end portion of the conductive layer 112b on the opening 143 side and the end portion of the insulating layer 110 on the opening 141 side and the length of the side surface of the insulating layer 110 on the opening 141 side. That is, the channel length L100 can be adjusted by the width D141 of the opening 141, the width D143 of the opening 143, the thickness T110 of the insulating layer 110, and the angle θ1 10.

The channel length L100 is preferably within the above range. The width D143 is preferably within the above range. The width D141 is preferably smaller than the width D143. Furthermore, for example, the width D141 is preferably larger than or equal to 0.2 μm and smaller than 5 μm, further preferably larger than or equal to 0.2 μm and smaller than 4.5 μm, still further preferably larger than or equal to 0.2 μm and smaller than 4 μm, yet still further preferably larger than or equal to 0.2 μm and smaller than 3.5 μm, yet still further preferably larger than or equal to 0.2 μm and smaller than 3 μm, yet still further preferably larger than or equal to 0.2 μm and smaller than 2.5 μm, yet still further preferably larger than or equal to 0.2 μm and smaller than 2 μm, yet still further preferably larger than or equal to 0.2 μm and smaller than 1.5 μm, yet still further preferably larger than or equal to 0.3 μm and smaller than or equal to 1.5 μm, yet still further preferably larger than or equal to 0.3 μm and smaller than or equal to 1.2 μm, yet still further preferably larger than or equal to 0.4 μm and smaller than or equal to 1.2 μm, yet still further preferably larger than or equal to 0.4 μm and smaller than or equal to 1 μm, yet still further preferably larger than or equal to 0.5 μm and smaller than or equal to 1 μm.

In FIG. 9A and FIG. 9B, the channel width W100 of the transistor 100C is indicated by a solid double-headed arrow. In the top view, the channel width W100 is the length of the end portion of the conductive layer 112b on the opening 143 side. For example, in the case where the top surface shape of the opening 143 is circle, the width D143 corresponds to the diameter of the opening 143, and the channel width W100 can be calculated to be “D143×π”.

Note that when a metal oxide is used for the semiconductor layer 108 and the insulating layer 110b contains hydrogen, the region of the semiconductor layer 108 in contact with the insulating layer 110b functions as the other of the source region and the drain region and the region of the semiconductor layer 108 in contact with the insulating layer 110a functions as the channel formation region in some cases. That is, in the semiconductor layer 108, the region in contact with the conductive layer 112b and the region in contact with the insulating layer 110b sometimes function as the other of the source region and the drain region.

For the channel length and the channel width in the case where the region of the semiconductor layer 108 in contact with the insulating layer 110b functions as the other of the source region and the drain region, the description regarding FIG. 5A and FIG. 5B can be referred to; thus, the detailed description is omitted.

Note that the structures of the opening 141 and the opening 143 described here can also be used in the other structure examples.

### Structure Example 5

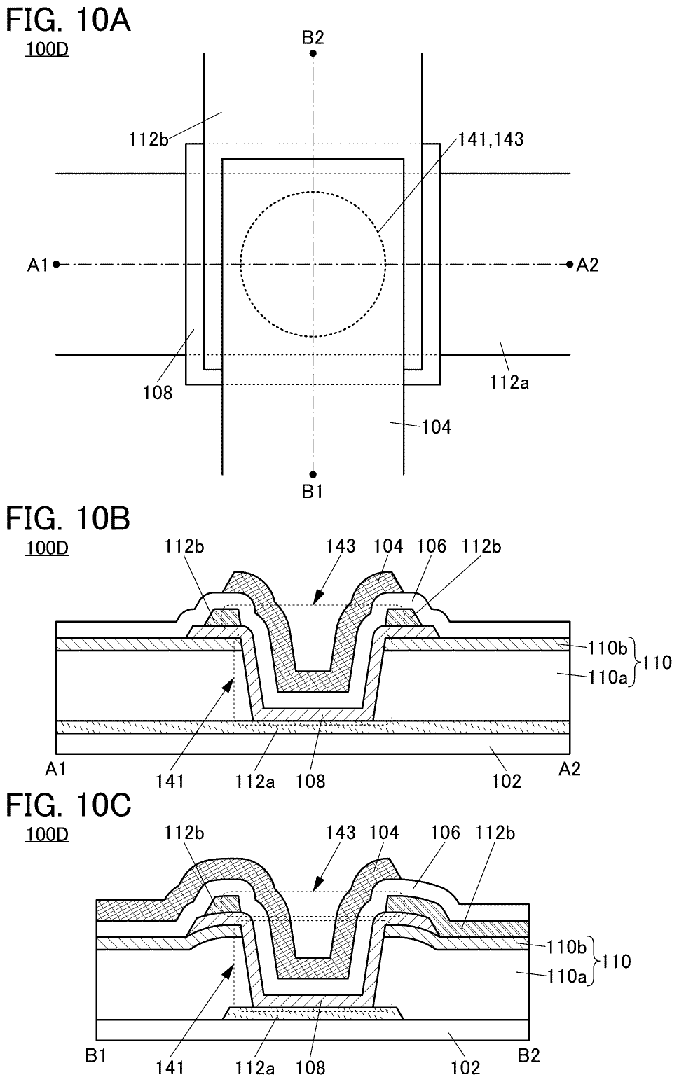

FIG. 10A is a top view of a transistor 100D that can be used in the semiconductor device of one embodiment of the present invention. FIG. 10B is a cross-sectional view of a cut plane along the dashed-dotted line A1-A2 in FIG. 10A and FIG. 10C is a cross-sectional view of a cut plane along the dashed-dotted line B1-B2.

The transistor 100D is different from the above-described transistor 100 mainly in that the insulating layer 106 includes a region in contact with the side surface of part of the semiconductor layer 108.

Part of the end portion of the conductive layer 112b on the side not facing the opening 143 is positioned over the semiconductor layer 108. It can also be expressed that part of the end portion of the conductive layer 112b on the side not facing the opening 143 is in contact with the top surface of the semiconductor layer 108. When the width of the conductive layer 112b is smaller than the width of the semiconductor layer 108, the area occupied by the conductive layer 112b can be reduced, so that a small-sized semiconductor device can be provided.

Note that the structure of the insulating layer 106 described here can also be used in the other structure examples.

### Example of Manufacturing Method

A method for manufacturing the semiconductor device of one embodiment of the present invention will be described below with reference to drawings. Here, a structure in which an oxide semiconductor is used for the semiconductor layer 108 of the transistor 100A illustrated in FIG. 6A and the like is described by way of example.

Note that thin films that form the semiconductor device (insulating films, semiconductor films, conductive films, and the like) can be formed by a sputtering method, a chemical vapor deposition (CVD) method, a vacuum evaporation method, a pulsed laser deposition (PLD) method, an atomic layer deposition (ALD) method, or the like. Examples of the CVD method include a plasma enhanced chemical vapor deposition (PECVD: Plasma Enhanced CVD) method and a thermal CVD method. As an example of the thermal CVD method, a metal organic chemical vapor deposition (MOCVD: Metal Organic CVD) method can be given.

The thin films that form the semiconductor device (insulating films, semiconductor films, conductive films, and the like) can be formed by a method such as spin coating, dipping, spray coating, ink-jetting, dispensing, screen printing, offset printing, a doctor knife, a slit coater, a roll coater, a curtain coater, or a knife coater.

When the thin films that form the semiconductor device are processed, a photolithography method or the like can be used for the processing. Besides, a nanoimprinting method, a sandblasting method, a lift-off method, or the like may be used for the processing of the thin films. Alternatively, island-shaped thin films may be directly formed by a deposition method using a shielding mask such as a metal mask.

As the photolithography method, two typical methods are given below. One of the methods is that a resist mask is formed over a thin film that is to be processed, the thin film is processed by etching or the like, and then the resist mask is removed. The other method is that a photosensitive thin film is formed and then light exposure and development are performed, so that the thin film is processed into a desired shape.

As light for light exposure in a photolithography method, it is possible to use the i-line (wavelength: 365 nm), the g-line (wavelength: 436 nm), the h-line (wavelength: 405 nm), or light in which the i-line, the g-line, and the h-line are mixed, for example. In addition, ultraviolet light, KrF laser light, ArF laser light, or the like can be used. Light exposure may be performed by liquid immersion light exposure technique. As the light used for light exposure, extreme ultraviolet (EUV) light or X-rays may also be used. Furthermore, instead of the light used for light exposure, an electron beam can be used. It is preferable to use extreme ultraviolet light, X-rays, or an electron beam because extremely minute processing can be performed. Note that a photomask is not needed when light exposure is performed by scanning with a beam such as an electron beam.

For etching of thin films, a dry etching method, a wet etching method, a sandblast method, or the like can be used.

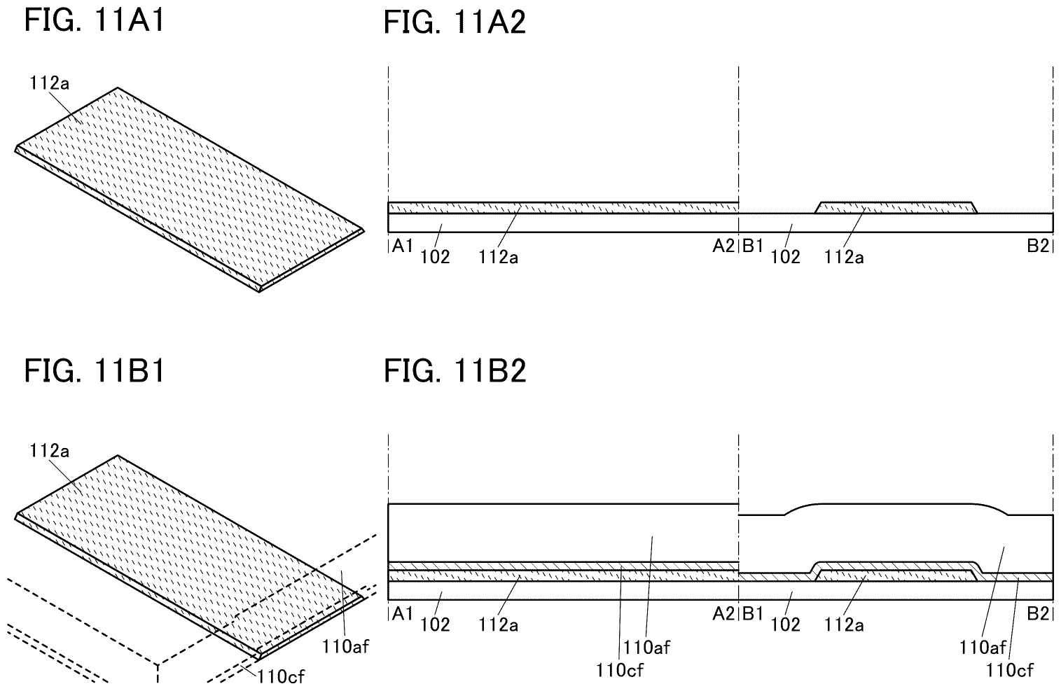

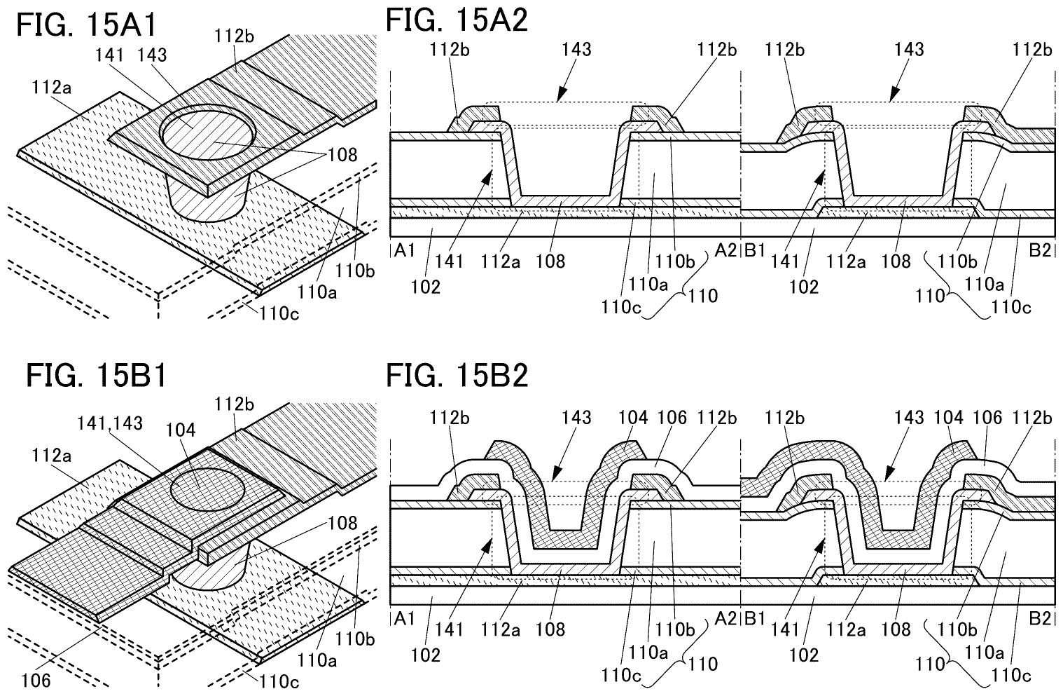

FIG. 11A1 to FIG. 15B2 are drawings each illustrating a method for manufacturing the transistor 100A. In each drawing, A1 and B1 are perspective views, and A2 and B2 are cross-sectional views of cut planes along the dashed-dotted line A1-A2 and the dashed-dotted line B1-B2. Note that the substrate 102 is omitted in A1 and B1 of each drawing. Furthermore, the insulating layer 110 is illustrated to be seen through, and its outline is indicated by a dashed line.

[Formation of Conductive Layer 112a]

A conductive film to be the conductive layer 112a is formed over the substrate 102. A sputtering method can be suitably used for forming the conductive firm, for example. The conductive film is processed after a resist mask is formed over the conductive film by a photolithography step, whereby the island-shaped conductive layer 112a functioning as one of the source electrode and the drain electrode is formed (FIG. 11A1 and FIG. 11A2). For the processing of the conductive film, one or both of a wet etching method and a dry etching method may be used.

[Formation of Insulating Film 110cf and Insulating Film 110af]

Next, an insulating film 110cf to be the insulating layer 110c and an insulating film 110af to be the insulating layer 110a are formed over the substrate 102 and the conductive layer 112a (FIG. 11B1 and FIG. 11B2).

A PECVD method can be suitably used for forming the insulating film 110cf and the insulating film 110af, for example. It is preferable that the insulating film 110af be formed in a vacuum successively after the formation of the insulating film 110cf, without exposure of a surface of the insulating film 110cf to the air. The insulating film 110cf and the insulating film 110af are successively formed, whereby impurities derived from the air can be inhibited from being attached to the surface of the insulating film 110cf. Examples of the impurities include water and organic substances.

The substrate temperature at the time of forming the insulating film 110cf and the insulating film 110af is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. When the substrate temperature at the time of forming the insulating film 110cf and the insulating film 110af is in the above range, impurities (e.g., water and hydrogen) released from the insulating film 110cf and the insulating film 110af themselves can be reduced, which inhibits diffusion of the impurities to the semiconductor layer 108. Consequently, the transistor can have favorable electrical characteristics and high reliability.

Note that since the insulating film 110cf and the insulating film 110af are formed earlier than the semiconductor layer 108, there is no need to consider oxygen release from the semiconductor layer 108 due to heat applied thereto at the time of the formation of the insulating film 110cf and the insulating film 110af.

Heat treatment may be performed after the insulating film 110cf and the insulating film 110af are formed. By the heat treatment, water or hydrogen can be released from the surface and inside of the insulating film 110cf and the insulating film 110af.

The heat treatment temperature is preferably higher than or equal to 150° C. and lower than the strain point of the substrate, further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. The heat treatment can be performed in an atmosphere containing one or more of a noble gas, nitrogen, and oxygen. As a nitrogen-containing atmosphere or an oxygen-containing atmosphere, clean dry air (CDA) may be used. Note that the content of hydrogen, water, or the like in the atmosphere is preferably as low as possible. As the atmosphere, a high-purity gas with a dew point of lower than or equal to −60° C., preferably lower than or equal to −100° C. is preferably used. With the use of an atmosphere where the content of hydrogen, water, or the like is as low as possible, entry of hydrogen, water, or the like into the insulating film 110cf and the insulating film 110af can be prevented as much as possible. An oven, a rapid thermal annealing (RTA) apparatus, or the like can be used for the heat treatment. The use of the RTA apparatus can shorten the heat treatment time.

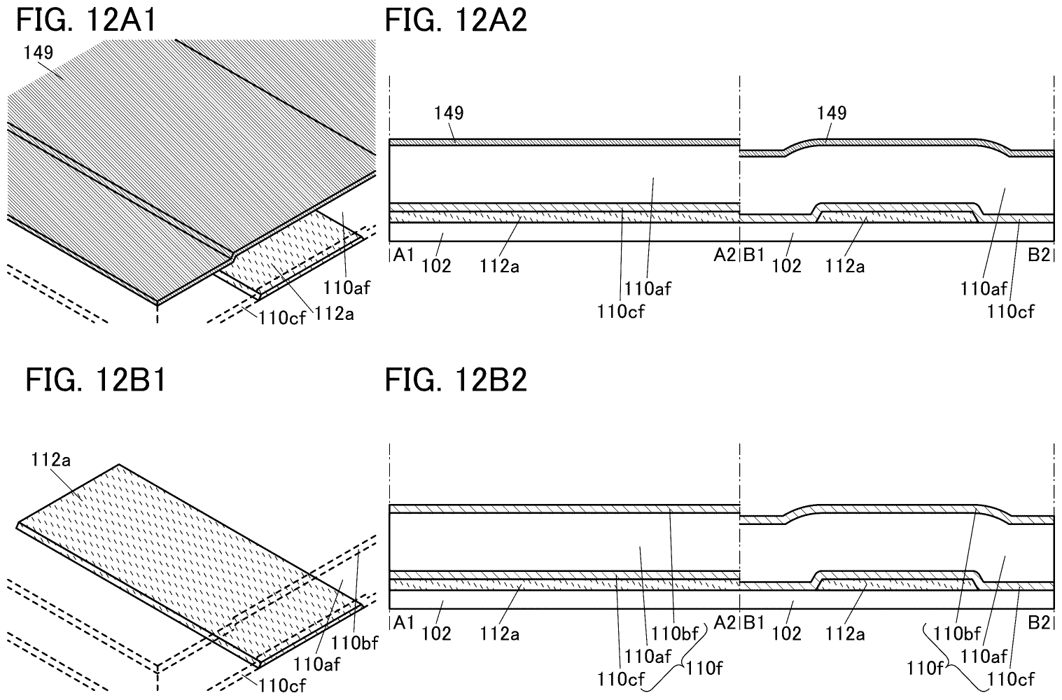

Then, oxygen is supplied to the insulating film 110af. Here, a method using a metal oxide layer is described by way of example. Next, a metal oxide layer 149 is formed over the insulating film 110af (FIG. 12A1 and FIG. 12A2).

There is no limitation on the conductivity of the metal oxide layer 149. As the metal oxide layer 149, at least one of an insulating layer, a semiconductor layer, and a conductive layer can be used. For the metal oxide layer 149, aluminum oxide, hafnium oxide, hafnium aluminate, indium oxide, indium tin oxide (ITO), or indium tin oxide containing silicon (ITSO) can be used, for example.

For the metal oxide layer 149, an oxide material containing one or more elements that are the same as those of the semiconductor layer 108 is preferably used. It is particularly preferable to use an oxide semiconductor material that can be used for the semiconductor layer 108.

A metal oxide film formed using a sputtering target having the same composition as the semiconductor layer 108 can be used as the metal oxide layer 149. The sputtering target having the same composition as the semiconductor layer 108 is preferably used, in which case the same manufacturing apparatus and the same sputtering target can be used.

When a metal oxide material containing indium and gallium is used for both the semiconductor layer 108 and the metal oxide layer 149, a material whose composition (content) of gallium is higher than that in the semiconductor layer 108 can be used for the metal oxide layer 149. It is preferable to use a material whose composition (content) of gallium is high for the metal oxide layer 149, in which case an oxygen blocking property can be further increased. Here, when the semiconductor layer 108 is formed using a material in which the composition of indium is higher than that in the metal oxide layer 149, the field-effect mobility of the transistor can be increased.

The metal oxide layer 149 is preferably formed in, for example, an oxygen-containing atmosphere. It is particularly preferable to form the metal oxide layer 149 by a sputtering method in an oxygen-containing atmosphere. In that case, oxygen can be favorably supplied to the insulating film 110af at the time of forming the metal oxide layer 149.

For example, the metal oxide layer 149 may be formed by a reactive sputtering method using oxygen as a film formation gas and a metal target. When aluminum is used for the metal target, for instance, an aluminum oxide film can be formed.

At the time of forming the metal oxide layer 149, the amount of oxygen supplied into the insulating film 110af can be increased with a higher flow rate ratio of oxygen to the deposition gas introduced into a treatment chamber of a deposition apparatus (the oxygen flow rate ratio) or with a higher oxygen partial pressure in the treatment chamber. The oxygen flow rate ratio or the oxygen partial pressure is, for example, higher than or equal to 50% and lower than or equal to 100%, preferably higher than or equal to 65% and lower than or equal to 100%, further preferably higher than or equal to 80% and lower than or equal to 100%, still further preferably higher than or equal to 90% and lower than or equal to 100%. It is particularly preferable that the oxygen flow rate ratio be 100% and the oxygen partial pressure be as close to 100% as possible.

When the metal oxide layer 149 is formed by a sputtering method in an oxygen-containing atmosphere in the above manner, oxygen can be supplied to the insulating film 110af and release of oxygen from the insulating film 110af can be prevented during the formation of the metal oxide layer 149. As a result, a large amount of oxygen can be enclosed in the insulating film 110af. Moreover, a large amount of oxygen can be supplied to the semiconductor layer 108 by heat treatment performed later. Consequently, oxygen vacancies (V_{O}) and V_{O}H in the semiconductor layer 108 can be reduced, whereby a transistor with favorable electrical characteristics and high reliability can be obtained.

After the metal oxide layer 149 is formed, heat treatment may be performed. The above description can be referred to for the heat treatment; thus, the detailed description thereof is omitted. By the heat treatment performed after the formation of the metal oxide layer 149, oxygen can be effectively supplied from the metal oxide layer 149 to the insulating film 110af.

After the formation of the metal oxide layer 149 or the above-described heat treatment, oxygen may be further supplied to the insulating film 110af through the metal oxide layer 149. As a method for supplying oxygen, an ion implantation method, an ion doping method, a plasma immersion ion implantation method, plasma treatment, or the like can be used, for example. For the plasma treatment, an apparatus in which an oxygen gas is transformed into plasma by high-frequency power can be suitably used. Examples of an apparatus in which a gas is transformed into plasma by high-frequency power include a plasma etching apparatus and a plasma ashing apparatus.

Then, the metal oxide layer 149 is removed.

There is no particular limitation on a method for removing the metal oxide layer 149, and a wet etching method can be suitably used. With the use of a wet etching method, the insulating film 110af can be inhibited from being etched at the time of removing the metal oxide layer 149. This can inhibit a reduction in the thickness of the insulating film 110af and the thickness of the insulating layer 110a can be uniform.

The treatment for supplying oxygen to the insulating film 110af is not limited to the above-described method. For example, an oxygen radical, an oxygen atom, an oxygen atomic ion, an oxygen molecular ion, or the like is supplied to the insulating film 110af by an ion doping method, an ion implantation method, plasma treatment, or the like. Alternatively, a film that inhibits oxygen release may be formed over the insulating film 110af, and then oxygen may be supplied to the insulating film 110af through the film. It is preferable to remove the film after supply of oxygen. As the above film that inhibits oxygen release, a conductive film or a semiconductor film containing one or more of indium, zinc, gallium, tin, aluminum, chromium, tantalum, titanium, molybdenum, nickel, iron, cobalt, and tungsten can be used.

Note that treatment for supplying oxygen to the insulating film 110af is not necessarily performed.

### [Formation of Insulating Film 110Bf]

Next, an insulating film 110bf to be the insulating layer 110b is formed over the insulating film 110af (see FIG. 12B1 and FIG. 12B2). For the formation of the insulating film 110bf, the description of the formation of the insulating film 110af and the insulating film 110cf can be referred to; thus, the detailed description thereof is omitted.

### [Formation of the Opening 141]

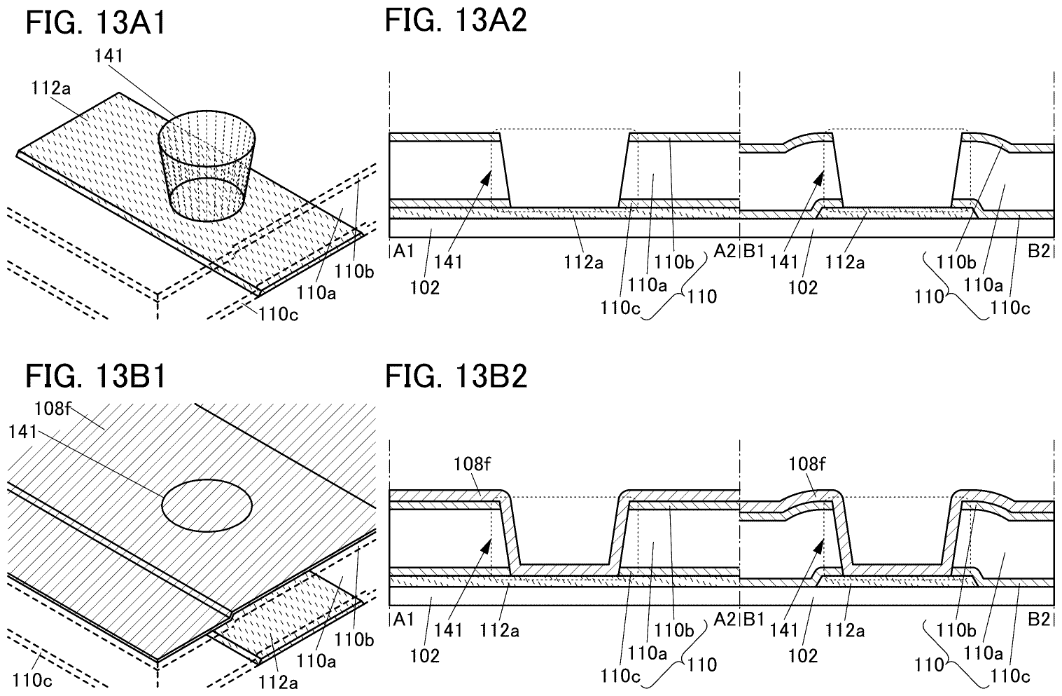

Next, the insulating film 110f (the insulating film 110af, the insulating film 110bf, and the insulating film 110cf) in the region overlapping with the conductive layer 112a is removed to form the insulating layer 110 (the insulating layer 110a, the insulating layer 110b, and the insulating layer 110c) including the opening 141 (FIG. 13A1 and FIG. 13A2). For the formation of the opening 141, either one or both of a wet etching method and a dry etching method can be used. The opening 141 can be suitably formed by a dry etching method, for example.

### [Formation of Semiconductor Layer 108]

Subsequently, a metal oxide film 108f to be the semiconductor layer 108 is formed to cover the opening 141 (FIG. 13B1 and FIG. 13B2). The metal oxide film 108f is provided to be in contact with the top surface and the side surface of the insulating layer 110 and the top surface of the conductive layer 112a.

The metal oxide film 108f is preferably formed by a sputtering method using a metal oxide target.

The metal oxide film 108f is preferably a dense film with as few defects as possible. The metal oxide film 108f is preferably a highly purified film in which impurities containing hydrogen elements are reduced as much as possible. It is particularly preferable to use a metal oxide film having crystallinity as the metal oxide film 108f.

In forming the metal oxide film 108f, an oxygen gas is preferably used. In the case of using an oxygen gas at the time of forming the metal oxide film 108f, oxygen can be suitably supplied into the insulating layer 110. For example, in the case where an oxide or an oxynitride is used for the insulating layer 110a, oxygen can be favorably supplied to the insulating layer 110a.

By the supply of oxygen to the insulating layer 110a, oxygen is supplied to the semiconductor layer 108 in a later step, so that oxygen vacancies (V_{O}) and V_{O}H in the semiconductor layer 108 can be reduced.

In depositing the metal oxide film 108f, an oxygen gas and an inert gas (e.g., a helium gas, an argon gas, or a xenon gas) may be mixed. At the time of depositing the metal oxide film 108f, the crystallinity of the metal oxide film 108f can be increased and a transistor with higher reliability can be obtained with a higher flow rate ratio of oxygen to the deposition gas or with a higher oxygen partial pressure in the treatment chamber of the deposition apparatus. On the other hand, when the oxygen flow rate ratio or the oxygen partial pressure is lower, the crystallinity of the metal oxide film 108f is reduced and a transistor with high on-state current can be obtained.

In forming the metal oxide film 108f, as the substrate temperature becomes higher, a denser metal oxide film having higher crystallinity can be formed. On the other hand, as the substrate temperature becomes lower, the metal oxide film 108f having lower crystallinity and higher electric conductivity can be formed.

The metal oxide film 108f is formed at a substrate temperature higher than or equal to room temperature and lower than or equal to 250° C., preferably higher than or equal to room temperature and lower than or equal to 200° C., further preferably higher than or equal to room temperature and lower than or equal to 140° C. For example, when the substrate temperature is higher than or equal to room temperature and lower than or equal to 140° C., high productivity is achieved, which is preferable. Furthermore, when the metal oxide film 108f is formed at the substrate temperature set at room temperature or without heating the substrate, the crystallinity can be made low.

Before the formation of the metal oxide film 108f, at least one of treatment for desorbing water, hydrogen, an organic substance, and the like adsorbed onto the surface of the insulating layer 110 and treatment for supplying oxygen into the insulating layer 110 is preferably performed. For example, heat treatment can be performed at a temperature higher than or equal to 70° C. and lower than or equal to 200° C. in a reduced-pressure atmosphere. Plasma treatment may be performed in an oxygen-containing atmosphere. Oxygen may be supplied to the insulating layer 110 by plasma treatment in an atmosphere containing an oxidizing gas such as dinitrogen monoxide (N₂O). Performing plasma treatment containing a dinitrogen monoxide gas can supply oxygen while suitably removing an organic substance on the surface of the insulating layer 110. It is preferable that the metal oxide film 108f be formed successively after such treatment, without exposure of the surface of the insulating layer 110 to the air.

Note that in the case where the semiconductor layer 108 has a stacked-layer structure, an upper metal oxide film is preferably formed successively after formation of a lower metal oxide film without exposure of the surface of the lower metal oxide layer to the air.

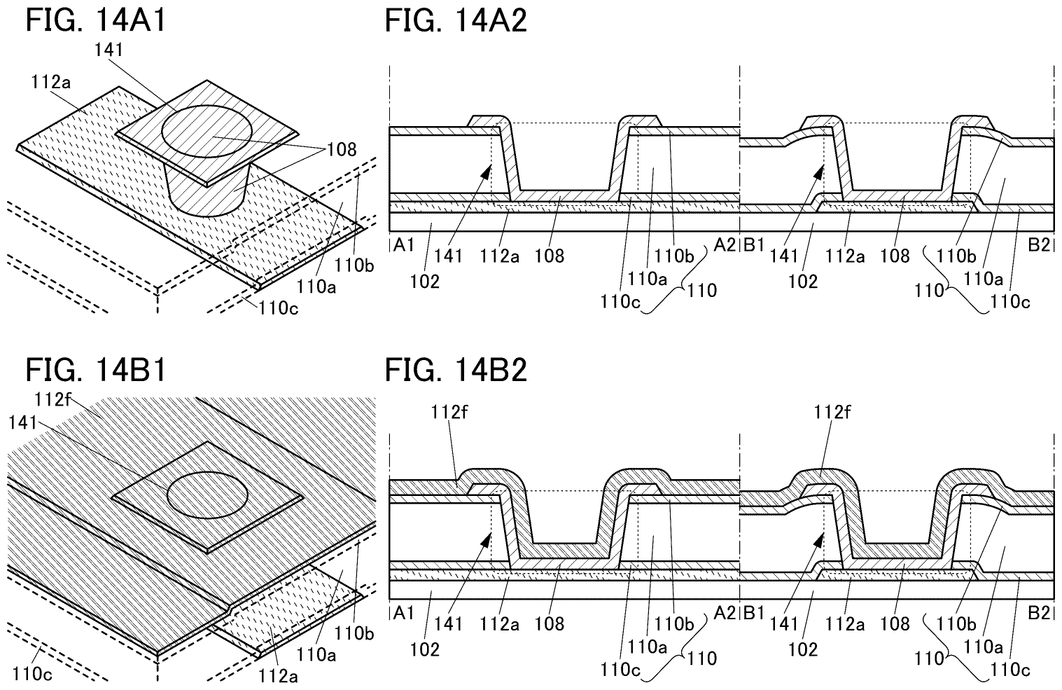

Next, the metal oxide film 108f is processed into an island shape to form the semiconductor layer 108 (FIG. 14A1 and FIG. 14A2).

For the formation of the semiconductor layer 108, either one or both of a wet etching method and a dry etching method can be used. A wet etching method can be suitably used to form the semiconductor layer 108, for example. At this time, part of the insulating layer 110 in the region that does not overlap with the semiconductor layer 108 is etched and thinned in some cases. For example, in some cases, the insulating layer 110b of the insulating layer 110 is removed by etching and a surface of the insulating layer 110a is exposed. Note that in etching of the metal oxide film 108f, a reduction in the thickness of the insulating layer 110b can be inhibited when a material having high etching selectivity is used for the insulating layer 110b.

Here, it is preferable that heat treatment be performed after the metal oxide film 108f is formed or after the metal oxide film 108f is processed into the semiconductor layer 108. The heat treatment can remove hydrogen or water contained in the metal oxide film 108f or the semiconductor layer 108 or adsorbed on the surface of the metal oxide film 108f or the semiconductor layer 108. Furthermore, the heat treatment improves the film quality of the metal oxide film 108f or the semiconductor layer 108 in some cases (e.g., reduces the number of defects or increases the crystallinity).

The heat treatment can also supply oxygen from the insulating layer 110a to the metal oxide film 108f or the semiconductor layer 108. At this time, it is further preferable that the heat treatment be performed before the metal oxide film 108f is processed into the semiconductor layer 108. The above description can be referred to for the heat treatment; thus, the detailed description thereof is omitted.

Note that the heat treatment is not necessarily performed when not needed. The heat treatment is not performed in this step, and heat treatment performed in a later step may also serve as the heat treatment in this step. In some cases, treatment at a high temperature in a later step (e.g., a film formation step) or the like can serve as the heat treatment in this step.

[Formation of Conductive Layer 112b]

Then, a conductive film 112f to be the conductive layer 112b is formed over the semiconductor layer 108 (FIG. 14B1 and FIG. 14B2). For formation of the conductive film 112f, a sputtering method can be suitably used, for example.

Next, the conductive film 112f is processed to form the conductive layer 112b having the opening 143 (FIG. 15A1 and FIG. 15A2). The opening 143 is provided in a region overlapping with the opening 141. For the formation of the conductive layer 112b, either one or both of a wet etching method and a dry etching method can be used. A wet etching method can be suitably used to form the conductive layer 112b, for example.

It is preferable that the conductive layer 112b not be provided inside the opening 141. Specifically, it is preferable that the conductive layer 112b not be in contact with the semiconductor layer 108 in the opening 141. In the case where the conductive layer 112b is provided also inside the opening 141, the channel length L100 of the transistor is shorter than the length of the side surface of the insulating layer 110, which may make it difficult to control the channel length L100 in some cases. Therefore, the top surface shape of the opening 143 preferably matches with the top surface shape of the opening 141, or the opening 143 preferably encompasses the opening 141 in the top view. Note that the opening 143 is formed to encompass the opening 141, whereby the transistor 100C illustrated in FIG. 8A or the like can be manufactured.

Note that at the time of forming the conductive layer 112b, the thickness of the semiconductor layer 108 in a region not overlapping with the conductive layer 112b is smaller than the thickness of the semiconductor layer 108 in a region overlapping with the conductive layer 112b in some cases. The thickness of the insulating layer 110 in a region not overlapping with the conductive layer 112b is smaller than the thickness of the insulating layer 110 in a region overlapping with the conductive layer 112b in some cases. For example, in some cases, the insulating layer 110b of the insulating layer 110 is removed by etching and a surface of the insulating layer 110a is exposed. Note that in etching of the conductive film 112f, a reduction in the thickness of the insulating layer 110b can be inhibited when a material having high etching selectivity is used for the insulating layer 110b.

After the conductive layer 112b is formed, cleaning treatment may be performed. As the cleaning treatment, wet cleaning using a cleaning solution or the like, plasma treatment using plasma, or cleaning by heat treatment can be used. The cleaning described above may be performed in combination as appropriate.

At the time of forming the conductive layer 112b, the surface of the semiconductor layer 108 may be damaged. In some cases, V_{O} is formed in the damaged semiconductor layer 108 and V_{O}H is further formed. The damaged layer can be removed by performing cleaning treatment after the formation of the conductive layer 112b. In addition, the cleaning treatment can remove impurities (e.g., a metal and an organic substance) attached to the surface of the semiconductor layer 108 at the time of forming the conductive layer 112b.

For the wet cleaning, a cleaning solution containing one or more of phosphoric acid, oxalic acid, and hydrochloric acid can be used, for example. A cleaning solution containing phosphoric acid can be suitably used for the wet cleaning. The concentration of the cleaning solution is preferably determined in consideration of the etching rate to the semiconductor layer 108. For example, in the case of using a cleaning solution containing phosphoric acid, the phosphoric acid concentration is preferably higher than or equal to 0.01 weight % and lower than or equal to 5 weight %, further preferably higher than or equal to 0.02 weight % and lower than or equal to 4 weight %, still further preferably higher than or equal to 0.05 weight % and lower than or equal to 3 weight %, yet still further preferably higher than or equal to 0.1 weight % and lower than or equal to 2 weight %, yet still further preferably higher than or equal to 0.15 weight % and lower than or equal to 1 weight %. With the above-described concentration range, the semiconductor layer 108 can be inhibited from disappearing, and the damaged layer of the semiconductor layer 108 and impurities (e.g., a metal and an organic substance) attached to the semiconductor layer 108 can be removed efficiently.

For the plasma treatment, a gas containing one or more of oxygen, ozone, nitrogen, dinitrogen monoxide (N₂O), and argon can be used, for example. The plasma treatment is preferably performed using a gas containing oxygen. In particular, with the use of a gas containing dinitrogen monoxide (N₂₀), an organic substance on the surface of the semiconductor layer 108 can be favorably removed. A PECVD apparatus or an etching apparatus can be used for the plasma treatment, for example.

Note that in the case where a PECVD method is used to form the insulating layer 106, plasma treatment and the formation of the insulating layer 106 may be successively performed with a PECVD apparatus. By successively forming the insulating layer 106 with the same apparatus after the plasma treatment, the surface of the semiconductor layer 108 is not exposed to the air, so that impurities (e.g., water and an organic substance) can be inhibited from being attached to the interface between the semiconductor layer 108 and the insulating layer 106.

### [Formation of Insulating Layer 106]

Then, the insulating layer 106 is formed to cover the semiconductor layer 108, the conductive layer 112b, and the insulating layer 110. For formation of the insulating layer 106, a PECVD method can be suitably used, for example.

In the case where an oxide semiconductor is used for the semiconductor layer 108, the insulating layer 106 preferably functions as a barrier film that inhibits diffusion of oxygen. The insulating layer 106 having a function of inhibiting diffusion of oxygen inhibits diffusion of oxygen into the conductive layer 104 from above the insulating layer 106 and can inhibit oxidation of the conductive layer 104 accordingly. Consequently, the transistor can have favorable electrical characteristics and high reliability.

When the temperature at the time of forming the insulating layer 106 functioning as the gate insulating layer is increased, an insulating layer with few defects can be formed. However, the high temperature at the time of forming the insulating layer 106 sometimes allows release of oxygen from the semiconductor layer 108, which increases oxygen vacancies (V_{O}) and V_{O}H in the semiconductor layer 108. The insulating layer 106 is preferably formed at a substrate temperature higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., for example, yet still further preferably higher than or equal to 300° C. and lower than or equal to 400° C. When the substrate temperature at the time of forming the insulating layer 106 is in the above range, release of oxygen from the semiconductor layer 108 can be inhibited while the defects in the insulating layer 106 can be reduced. Consequently, the transistor can have favorable electrical characteristics and high reliability.

Before the formation of the insulating layer 106, a surface of the semiconductor layer 108 may be subjected to plasma treatment. By the plasma treatment, an impurity, such as water, adsorbed onto the surface of the semiconductor layer 108 can be reduced. Therefore, impurities at the interface between the semiconductor layer 108 and the insulating layer 106 can be reduced, and thus a highly reliable transistor can be achieved. The plasma treatment is suitable in the case where the surface of the semiconductor layer 108 is exposed to the air between the formation of the semiconductor layer 108 and the formation of the insulating layer 106, in particular. For example, plasma treatment can be performed in an atmosphere containing oxygen, ozone, nitrogen, dinitrogen monoxide, argon, or the like. The plasma treatment and the formation of the insulating layer 106 are preferably performed successively without exposure to the air.

### [Formation of Conductive Layer 104]

Next, a conductive film to be the conductive layer 104 is formed over the insulating layer 106. A sputtering method can be suitably used for forming the conductive firm, for example. A resist mask is formed over the conductive film by a photolithography step and then, the conductive film is processed, so that the conductive layer 104 with an island shape, which functions as the gate electrode, can be formed (FIG. 15B1 and FIG. 15B2).

Through the above steps, the transistor 100A can be manufactured.

This embodiment can be combined with any of the other embodiments as appropriate. In this specification, in the case where a plurality of structure examples are described in one embodiment, the structure examples can be combined as appropriate.

### Embodiment 2

In this embodiment, a display apparatus using the semiconductor device of one embodiment of the present invention is described.

The display apparatus in this embodiment can be a high-definition display apparatus. Accordingly, the display apparatus in this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The display apparatus in this embodiment can be a high-resolution display apparatus or a large-sized display apparatus. Accordingly, the display apparatus in this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer or the like, digital signage, and a large game machine such as a pachinko machine.

### <Display Apparatus 200A>

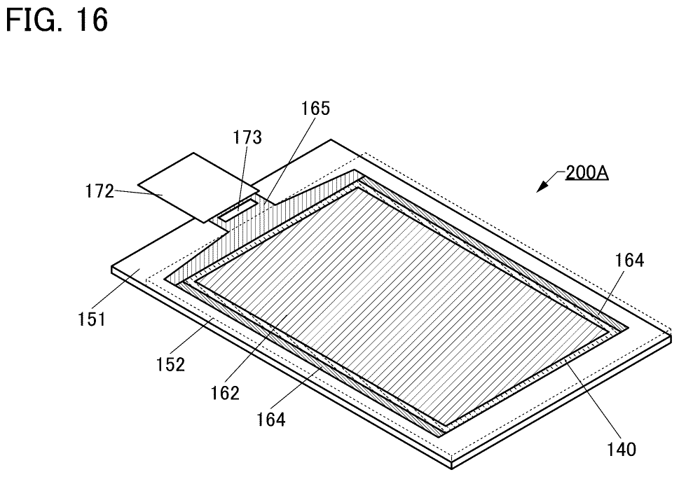

FIG. 16 is a perspective view of a display apparatus 200A.

In the display apparatus 200A, a substrate 152 and a substrate 151 are attached to each other. In FIG. 16, the substrate 152 is denoted by a dashed line.

The display apparatus 200A includes a display portion 162, a connection portion 140, a circuit 164, a wiring 165, and the like. FIG. 16 illustrates an example in which an IC 173 and an FPC 172 are mounted on the display apparatus 200A. Thus, the structure illustrated in FIG. 16 can be regarded as a display module including the display apparatus 200A, the IC (integrated circuit), and the FPC.

A plurality of pixels are arranged in a matrix in the display portion 162. Each of the pixels includes a plurality of subpixels.

Each subpixel includes a display device (also referred to as a display element). Examples of the display device include a liquid crystal device (also referred to as a liquid crystal element) and a light-emitting device. As the light-emitting device, an OLED (Organic Light Emitting Diode) or a QLED (Quantum-dot Light Emitting Diode) is preferably used, for example. Examples of a light-emitting substance contained in the light-emitting device include a substance emitting fluorescent light (a fluorescent material), a substance emitting phosphorescent light (a phosphorescent material), a substance exhibiting thermally activated delayed fluorescence (a thermally activated delayed fluorescent (TADF) material), and an inorganic compound (e.g., a quantum dot material). Alternatively, an LED (Light Emitting Diode) such as a micro-LED can be used as the light-emitting device.

The light-emitting device can emit infrared, red, green, blue, cyan, magenta, yellow, or white light, for example. When the light-emitting device has a microcavity structure, the color purity can be further increased.

In the following description, a structure where a light-emitting device is used as the display device is given as an example.

A display apparatus of one embodiment of the present invention includes light-emitting devices of different colors, which are separately formed, and can perform full-color display.

The display apparatus of one embodiment of the present invention can have any of the following structures: a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces.

The connection portion 140 is provided outside the display portion 162. The connection portion 140 can be provided along one side or a plurality of sides of the display portion 162, for example. There is no particular limitation on the top surface shape of the connection portion 140, and the shape can be a belt-like shape, an L shape, a U shape, a frame-like shape, or the like. The number of the connection portions 140 may be one or more. FIG. 16 illustrates an example where the connection portion 140 is provided to surround the four sides of the display portion 162. The common electrode of the light-emitting device is electrically connected to a conductive layer in the connection portion 140, and thus a potential can be supplied to the common electrode. The connection portion 140 can also be referred to as a cathode contact portion.

As the circuit 164, a scan line driver circuit can be used, for example.

The wiring 165 has a function of supplying a signal and power to the display portion 162 and the circuits 164. The signal and power are input to the wiring 165 from the outside through the FPC 172 or from the IC 173.

FIG. 16 illustrates an example where the IC 173 is provided over the substrate 151 by a chip on glass (COG) method, a chip on film (COF) method, or the like. An IC including a scan line driver circuit, a signal line driver circuit, or the like can be used as the IC 173, for example. Note that the display apparatus 200A and the display module are not necessarily provided with an IC. The IC may be mounted on the FPC by a COF method or the like.

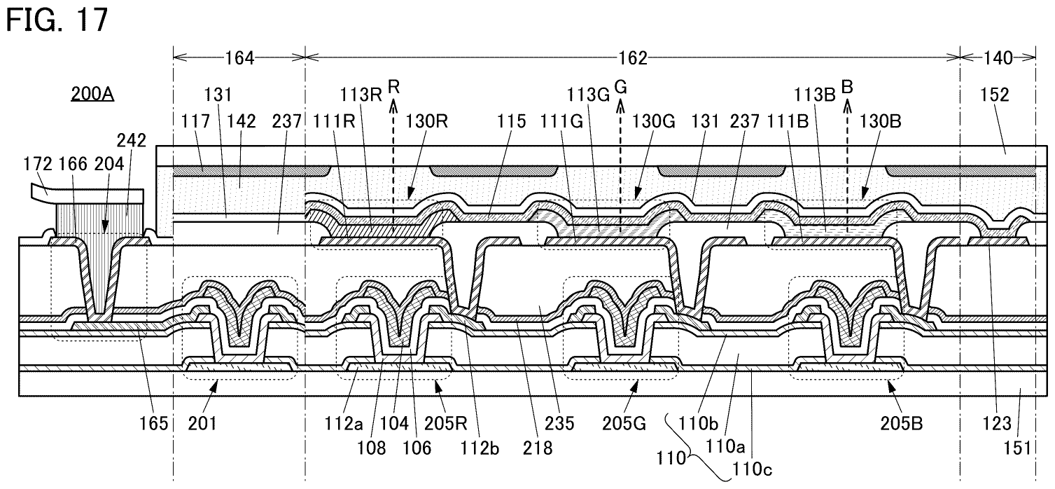

FIG. 17 illustrates an example of cross sections of part of a region including the FPC 172, part of the circuit 164, part of the display portion 162, part of the connection portion 140, and part of a region including an end portion of the display apparatus 200A.

The display apparatus 200A illustrated in FIG. 17 includes a transistor 201, a transistor 205R, a transistor 205G, a transistor 205B, a light-emitting device 130R, a light-emitting device 130G, a light-emitting device 130B, and the like between the substrate 151 and the substrate 152.

The transistor 201, the transistor 205R, the transistor 205G, and the transistor 205B are provided over the substrate 151. An insulating layer 218 and an insulating layer 235 over the insulating layer 218 are provided to cover the transistor 201, the transistor 205R, the transistor 205G, and the transistor 205B. The light-emitting device 130R, the light-emitting device 130G, and the light-emitting device 130B are provided over the insulating layer 235.

Matters common to the light-emitting device 130R, the light-emitting device 130G, and the light-emitting device 130B are sometimes described with use of the term light-emitting device 130 without any letter of the alphabet distinguishing these light-emitting devices. Likewise, in the description of matters common to the components that are distinguished using letters of the alphabet, such as the transistor 205R, the transistor 205G, and the transistor 205B, reference numerals without the letters of the alphabet are sometimes used.

The transistor 201, the transistor 205R, the transistor 205G, and the transistor 205B are each formed over the substrate 151. These transistors can be formed using the same material in the same step. The transistor described in Embodiment 1 can be suitably used as each of the transistor 201, the transistor 205R, the transistor 205G, and the transistor 205B. FIG. 17 illustrates the structure in which the transistor 100A illustrated in FIG. 6 is used as each of the transistor 201, the transistor 205R, the transistor 205G, and the transistor 205B. With the use of the transistor described in Embodiment 1 for the display portion 162, a high-definition display apparatus can be provided. With the use of the transistor described in Embodiment 1 for the circuit 164, the display apparatus can have a narrow bezel.

Note that the transistor included in the circuit 164 and the transistor included in the display portion 162 may have the same structure or different structures. The same structure or two or more kinds of structures may be employed for a plurality of transistors included in the circuit 164. Similarly, the same structure or two or more kinds of structures may be employed for a plurality of transistors included in the display portion 162.

All of the transistors included in the display portion 162 may be OS transistors or Si transistors. Alternatively, some of the transistors included in the display portion 162 may be OS transistors and the others may be Si transistors. As a Si transistor, a transistor using LTPS (hereinafter, referred to as a LTPS transistor) may be used.

For example, when both an LTPS transistor and an OS transistor are used in the display portion 162, the display apparatus can have low power consumption and high drive capability. In addition, a structure in which the LTPS transistor and the OS transistor are combined is referred to as LTPO in some cases. In a favorable example, a structure is given in which the OS transistor is used as a transistor functioning as a switch for controlling electrical continuity and discontinuity between wirings and the LTPS transistor is used as a transistor for controlling current.

For example, one transistor included in the display portion 162 can function as a transistor for controlling current flowing through the light-emitting device and be referred to as a driving transistor. One of a source and a drain of the driving transistor is electrically connected to the pixel electrode of the light-emitting device. An LTPS transistor is preferably used as the driving transistor. Accordingly, the amount of current flowing through the light-emitting device can be increased in the pixel circuit. By contrast, another transistor included in the display portion 162 may function as a switch for controlling selection or non-selection of a pixel and be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., 1 fps or lower); thus, power consumption can be reduced by stopping the driver in displaying a still image.

The light-emitting device 130R, the light-emitting device 130G, and the light-emitting device 130B each include a pair of electrodes and a layer between the pair of electrodes. The layer includes at least a light-emitting layer. One of the pair of electrodes of the light-emitting device functions as an anode, and the other electrode functions as a cathode. The case where the pixel electrode functions as an anode and the common electrode functions as a cathode is described below in some cases by way of example.

The light-emitting device 130R includes a pixel electrode 111R over an insulating layer 235, an island-shaped layer 113R over the pixel electrode 111R, and a common electrode 115 over the island-shaped layer 113R.

The light-emitting device 130G includes a pixel electrode 111G over the insulating layer 235, an island-shaped layer 113G over the pixel electrode 111G, and the common electrode 115 over the island-shaped layer 113G.

The light-emitting device 130B includes a pixel electrode 111B over the insulating layer 235, an island-shaped layer 113B over the pixel electrode 111B, and the common electrode 115 over the island-shaped layer 113B.

Each of the layer 113R, the layer 113G, and the layer 113B includes at least a light-emitting layer. For example, the light-emitting device 130R emits red (R) light, the light-emitting device 130G emits green (G) light, and the light-emitting device 130B emits blue (B) light. For example, the layer 113R, the layer 113G, and the layer 113B can respectively include a light-emitting layer that emits red light, a light-emitting layer that emits green light, and a light-emitting layer that emits blue light. In other words, the layer 113R, the layer 113G, and the layer 113B can respectively include a light-emitting material that emits red light, a light-emitting material that emits green light, and a light-emitting material that emits blue light. Each of the layer 113R, the layer 113G, and the layer 113B may each include one or more functional layers. Examples of the functional layers include carrier-injection layers (a hole-injection layer and an electron-injection layer), carrier-transport layers (a hole-transport layer and an electron-transport layer), carrier-blocking layers (a hole-blocking layer and an electron-blocking layer), and the like.

Although the layer 113R, the layer 113G, and the layer 113B have the same thickness in FIG. 17, the present invention is not limited thereto. The layer 113R, the layer 113G, and the layer 113B may have different thicknesses. For example, the thicknesses of the layer 113R, the layer 113G, and the layer 113B are preferably set to an optical path length that can intensify light emitted from each layer. A microcavity structure can be achieved in this manner, and the color purity of each light-emitting device 130 can be increased.

The layer 113R, the layer 113G, and the layer 113B can be formed by a vacuum evaporation method using a fine metal mask, for example. In the vacuum evaporation method using a fine metal mask, the layer 113R, the layer 113G, and the layer 113B can be formed in an area wider than an opening of the fine metal mask. The end portions of the layer 113R, the layer 113G, and the layer 113B each have a tapered shape. Note that a sputtering method using a fine metal mask or an inkjet method may be used to form the layer 113R, the layer 113G, and the layer 113B.

The light-emitting device of this embodiment may have either a single structure (a structure including only one light-emitting unit) or a tandem structure (a structure including a plurality of light-emitting units). The light-emitting unit includes at least one light-emitting layer.

In the case of using a tandem light-emitting device, preferably, the layer 113R includes a plurality of light-emitting units that emit red light, the layer 113G includes a plurality of light-emitting units that emit green light, and the layer 113B includes a plurality of light-emitting units that emit blue light, for example. A charge-generation layer is preferably provided between the light-emitting units.

The common electrode 115 is shared between the light-emitting device 130R, the light-emitting device 130G, and the light-emitting device 130B. The common electrode 115 is electrically connected to a conductive layer 123 provided in the connection portion 140. As the conductive layer 123, a conductive layer formed using the same material and the same step as the pixel electrode 111R, the pixel electrode 111G, and the pixel electrode 111B is preferably used. Preferably, none of the layer 113R, the layer 113G, and the layer 113B are provided over the conductive layer 123.

In the connection portion 140, the common electrode 115 is provided over the conductive layer 123. The common electrode 115 can be formed by a sputtering method or a vacuum evaporation method, for example. Alternatively, a film formed by an evaporation method and a film formed by a sputtering method may be stacked. A mask (also referred to as an area mask or a rough metal mask to be distinguished from a fine metal mask) for specifying the area where the common electrode 115 is formed may be used to form the common electrode 115.

The insulating layer 218 provided over the transistor 205R, the transistor 205G, and the transistor 205B functions as a protective layer for the transistor 205R, the transistor 205G, and the transistor 205B. The insulating layer 218 is preferably formed using a material through which impurities are not easily diffused. The insulating layer 218 functions as a blocking film that inhibits the diffusion of impurities from the outside into the transistors. Examples of the impurities include water and hydrogen. With the insulating layer 218, the reliability of the display apparatus can be increased.

The insulating layer 218 can be an insulating layer including an inorganic material or an insulating layer including an organic material. An inorganic material can be suitably used for the insulating layer 218. As the inorganic insulating material, one or more of oxide, oxynitride, nitride oxide, and nitride can be used. Specifically, for example, one or more of an inorganic insulating material such as silicon nitride, silicon nitride oxide, silicon oxynitride, aluminum oxide, aluminum oxynitride, aluminum nitride, hafnium oxide, or hafnium aluminate can be used. For example, silicon nitride oxide can be suitably used for the insulating layer 218 because the amount of impurities (such as water and hydrogen) released from the silicon nitride oxide itself is small and a film of silicon nitride oxide can function as a blocking film that inhibits the diffusion of impurities into the transistors from above the transistors. As an organic material, for example, one or more of an acrylic resin and a polyimide resin can be used. As an organic material, a photosensitive material may be used. A stack including two or more of the above insulating films may also be used. The insulating layer 218 may have a stacked-layer structure of an insulating layer including an inorganic material and an insulating layer including an organic material.

Increasing the temperature at the time of forming an insulating film to be the insulating layer 218 can enhance the property of blocking impurities (e.g., water and hydrogen). However, in the case where an oxide semiconductor is used for the semiconductor layer 108, the high temperature at the time of forming the insulating film sometimes allows release of oxygen from the semiconductor layer 108, which increases the oxygen vacancies (V_{O}) and V_{O}H in the semiconductor layer 108 in some cases. The substrate temperature at the time of forming the insulating film is preferably higher than or equal to 180° C. and lower than or equal to 450° C., further preferably higher than or equal to 200° C. and lower than or equal to 450° C., further preferably higher than or equal to 250° C. and lower than or equal to 450° C., further preferably higher than or equal to 300° C. and lower than or equal to 450° C., further preferably higher than or equal to 300° C. and lower than or equal to 400° C. With the substrate temperature at the time of forming the insulating film in the above range, release of oxygen from the semiconductor layer 108 can be inhibited while the insulating layer 218 can have an improved blocking property. Consequently, the transistor can have favorable electrical characteristics and high reliability.

The insulating layer 235 has a function of reducing unevenness caused by the transistor 205R, the transistor 205G, and the transistor 205B to planarize a formation surface of the light-emitting device 130. Note that in this specification and the like, the insulating layer 235 is referred to as a planarization layer in some cases.

For the insulating layer 235, an organic material can be favorably used. As the organic material, a photosensitive organic resin is preferably used, and for example, a photosensitive resin composite containing an acrylic resin is preferably used. Note that in this specification and the like, an acrylic resin refers to not only a polymethacrylic acid ester or a methacrylic resin, but also acrylic polymers in a broad sense in some cases.

Alternatively, the insulating layer 235 may be formed using an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. Alternatively, the insulating layer 235 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used for the photosensitive resin. As the photosensitive organic resin, either a positive material or a negative material may be used.

The insulating layer 235 may have a stacked-layer structure of an organic insulating layer and an inorganic insulating layer. For example, the insulating layer 235 can have a stacked-layer structure of an organic insulating layer and an inorganic insulating layer over the organic insulating layer. An inorganic insulating layer provided on the outermost surface of the insulating layer 235 can function as an etching protective layer. This can inhibit a decrease in the planarity of the insulating layer 235, which is caused by etching of part of the insulating layer 235 in the formation of the pixel electrode 111.

The low planarity of the top surface of the insulating layer 235, which is the formation surface of the light-emitting device 130, may cause a defect such as a connection defect due to disconnection of the common electrode 115 or an increase in electric resistance due to the locally thinned regions of the common electrode 115 in some cases. In addition, the low planarity of the top surface of the insulating layer 235 may lower the processing accuracy of the layer to be formed over the insulating layer 235 in some cases. Planarizing the top surface of the insulating layer 235 increases the processing accuracy of the light-emitting device 130 and the like to be provided over the insulating layer 235, whereby a high-definition display apparatus can be provided. Furthermore, since a connection defect due to disconnection of the common electrode 115 and an increase in electric resistance due to local thinning of the common electrode 115 can be prevented, the display apparatus can have high display quality.

In some cases, the insulating layer 235 is partly removed when the pixel electrode 111R, the pixel electrode 111G, and the pixel electrode 111B are formed. The insulating layer 235 may have a concave portion in a region overlapping with none of the pixel electrode 111R, the pixel electrode 111G, and the pixel electrode 111B.

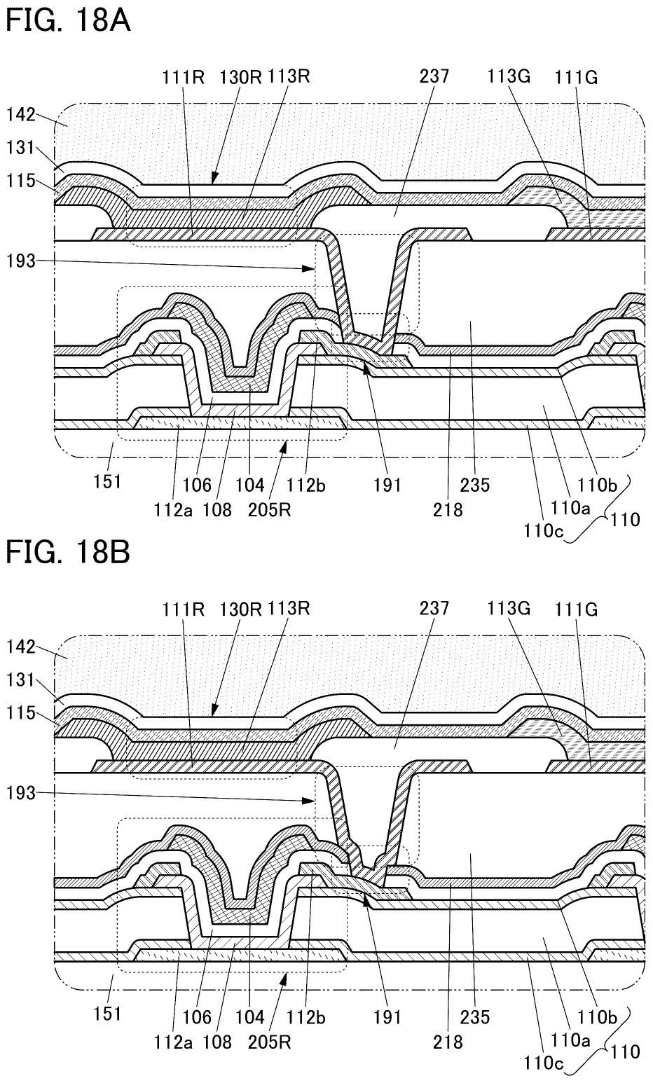

FIG. 18A is an enlarged view of the light-emitting device 130R, the transistor 205R, and the vicinity thereof. The insulating layer 106 and the insulating layer 218 have an opening 191 in a region overlapping with the conductive layer 112b of the transistor 205R. The conductive layer 112b is exposed in the opening 191. The insulating layer 235 includes the opening 193 in a region overlapping with the opening 191. The pixel electrode 111R is provided to cover the opening 191 and the opening 193. The pixel electrode 111R includes a region in contact with the top surface and the side surface of the insulating layer 235, the side surface of the insulating layer 218, the side surface of the insulating layer 106, and the top surface of the conductive layer 112b. The light-emitting device 130R is electrically connected to the transistor 205R through the opening 191 and the opening 193.

FIG. 18A illustrates an example in which the position of the end portion of the insulating layer 106 on the opening 191 side and the position of the end portion of the insulating layer 218 on the opening 191 side match or substantially match with each other and the position of the end portion of the insulating layer 235 on the opening 193 side and the position of the end portion of the insulating layer 218 on the opening 191 side match or substantially match with each other, but one embodiment of the present invention is not limited to the example. It is acceptable that the position of the end portion of the insulating layer 106 on the opening 191 side does not match with the position of the end portion of the insulating layer 218 on the opening 191 side. It is also acceptable that the position of the end portion of the insulating layer 235 on the opening 193 side does not match with the position of the end portion of the insulating layer 218 on the opening 191 side. For example, as illustrated in FIG. 18B, an end portion of the insulating layer 235 on the opening 193 side is preferably positioned inward from the end portion of the insulating layer 218 on the opening 191 side. That is, an end portion of the insulating layer 235 on the opening 193 side is preferably in contact with the top surface of the insulating layer 218. It can be expressed that the opening 193 encompasses the opening 191. This structure can improve the coverage with the pixel electrode 111R. Furthermore, the end portion of the insulating layer 106 on the opening 191 side may be positioned outward from the end portion of the insulating layer 218 on the opening 191 side.

Detailed description is omitted, regarding the pixel electrode 111G in the light-emitting device 130G and the conductive layer 112b in the transistor 205G, and the pixel electrode 111B in the light-emitting device 130B and the conductive layer 112b in the transistor 205B, which are similar to the pixel electrode 111R in the light-emitting device 130R and the conductive layer 112b in the transistor 205R.

FIG. 17 and the like illustrate the structure in which the pixel electrode 111R, the pixel electrode 111G, and the pixel electrode 111B are each electrically connected to the conductive layer 112b, but one embodiment of the present invention is not limited to the structure. The pixel electrode 111R, the pixel electrode 111G, and the pixel electrode 111B may each be electrically connected to the conductive layer 112a. In that case, the pixel electrode 111R, the pixel electrode 111G, and the pixel electrode 111B can be electrically connected to the conductive layer 112a through openings provided in the insulating layer 110, the insulating layer 106, the insulating layer 218, and the insulating layer 235. The structure of the pixel electrode that can be applied to the display apparatus of one embodiment of the present invention is not limited to the structure of the pixel electrode 111 illustrated in FIG. 17 and the like.

An insulating layer 237 covers end portions of the top surfaces of the pixel electrode 111R, the pixel electrode 111G, and the pixel electrode 111B. The insulating layer 237 functions as a partition (also referred to as a bank or a spacer). The insulating layer 237 can be an insulating layer including an inorganic material or an insulating layer including an organic material. The material that can be used for the insulating layer 218 or the material that can be used for the insulating layer 235 can be used for the insulating layer 237. The insulating layer 237 may have a stacked-layer structure of an inorganic insulating layer and an organic insulating layer.

The insulating layer 237 can inhibit a contact between the pixel electrode 111 and the common electrode 115 to prevent a short-circuit in the light-emitting device 130. An end portion of the insulating layer 237 preferably has a tapered shape. When the end portion of the insulating layer 237 has a tapered shape, coverage with a film formed later can be increased. In particular, a photosensitive material is preferably used for an organic insulating layer, in which case the shape of the end portion can be easily controlled by the conditions of light exposure and development. Note that an inorganic insulating layer may be used for the insulating layer 237. Using an inorganic insulating layer for the insulating layer 237 enables the high-definition display apparatus.

When a photosensitive organic material is used for a film to be the insulating layer 237, the insulating layer 237 can be formed in a manner in which a composition containing an organic material is applied by a spin coating method, and then is subjected to selective light exposure and development. In the case of using the photosensitive organic material, a positive-type photosensitive resin or a negative-type photosensitive resin may be used. Light used for the exposure preferably includes the i-line. Light used for the exposure may include at least one of the g-line and the h-line. Adjusting the amount of light exposed can adjust the width of the opening. As another formation method, one or more of a sputtering method, an evaporation method, a droplet discharging method (e.g., an inkjet method), a screen printing method, and an offset printing method may be used.

The pixel electrode 111R, the pixel electrode 111G, and the pixel electrode 111B are provided with concave portions so as to cover the opening in the insulating layer 106, the insulating layer 218, and the insulating layer 235. The insulating layer 237 is embedded in the concave portions. For example, the insulating layer 237 covering the end portions of the top surface of the pixel electrode 111 and the openings is formed, and then the layer 113R, the layer 113G, and the layer 113B that have island-shapes can be formed with a fine metal mask.

The layer 113R, the layer 113G, and the layer 113B may be provided over the insulating layer 237. Although adjacent layers 113 are not in contact with each other in the structure shown in FIG. 17, one embodiment of the present invention is not limited to the structure. Adjacent layers 113 may be in contact with each other over the insulating layer 237. Adjacent layers 113 may overlap with each other over the insulating layer 237. Over the insulating layer 237, for example, the layer 113R may be in contact with the layer 113G, and the layer 113G and the layer 113R may overlap with each other.

The insulating layer 237 can be used in other structure examples.

The protective layer 131 is provided over the light-emitting device 130R, the light-emitting device 130G, and the light-emitting device 130B. The protective layer 131 and the substrate 152 are bonded to each other with an adhesive layer 142 therebetween. The substrate 152 is provided with a light-blocking layer 117. A solid sealing structure, a hollow sealing structure, or the like can be employed to seal the light-emitting devices. In FIG. 17, a solid sealing structure is employed, in which a space between the substrate 152 and the substrate 151 is filled with the adhesive layer 142. Alternatively, a hollow sealing structure may be employed, in which the space is filled with an inert gas (e.g., nitrogen or argon). In this case, the adhesive layer 142 may be provided not to overlap with the light-emitting devices. Alternatively, the space may be filled with a resin different from the frame-like adhesive layer 142.

The protective layer 131 is preferably provided over the light-emitting device 130R, the light-emitting device 130G, and the light-emitting device 130B. The protective layer 131 can inhibit oxidation of the common electrode 115 and entry of impurities (e.g., moisture and oxygen) into the light-emitting devices. Thus, the light-emitting devices are inhibited from deteriorating and the reliability of the display apparatus can be increased. The protective layer 131 may have a single-layer structure or a stacked structure including two or more layers. There is no limitation on the conductivity of the protective layer 131. As the protective layer 131, at least one type of insulating layers, semiconductor layers, and conductive layers can be used.

An inorganic substance can be used for the protective layer 131. For example, one or more of oxide, oxynitride, nitride oxide, and nitride can be used for the protective layer 131. Specifically, silicon oxide, silicon oxynitride, silicon nitride oxide, silicon nitride, aluminum oxide, aluminum oxynitride, and hafnium oxide can be given. In particular, the protective layer 131 preferably includes a nitride or a nitride oxide, and further preferably includes a nitride.

As the protective layer 131, a layer containing In—Sn oxide (ITO), In—Zn oxide, Ga—Zn oxide, Al—Zn oxide, In—Ga—Zn oxide (IGZO), or the like can also be used. The layer preferably has high resistance, specifically, higher resistance than the common electrode 115. The layer may further contain nitrogen.

When light emitted from the light-emitting device is extracted through the protective layer 131, the protective layer 131 preferably has a high visible-light-transmitting property. For example, In—Sn oxide, In—Ga—Zn oxide, and aluminum oxide are preferable because they have a high visible-light-transmitting property.

Furthermore, the protective layer 131 may include an organic film. For example, the protective layer 131 may include both an organic film and an inorganic film.

Examples of methods of forming the protective layer 131 include a vacuum evaporation method, a sputtering method, a CVD method, and an ALD method. The protective layer 131 may have a stacked-layer structure of layers formed by different formation methods.

The protective layer 131 is provided at least in the display portion 162, and preferably provided to cover the entire display portion 162. The protective layer 131 is preferably provided to cover not only the display portion 162 but also the connection portion 140 and the circuit 164. It is further preferable that the protective layer 131 be provided to extend to the end portion of the display apparatus 200A.

The connection portion 204 is provided in a region of the substrate 151 not overlapping with the substrate 152. In the connection portion 204, the wiring 165 is electrically connected to the FPC 172 through the conductive layer 166 and a connection layer 242. The conductive layer 166 can be formed through the same step as the pixel electrode 111R, the pixel electrode 111G, and the pixel electrode 111B. On the top surface of the connection portion 204, the conductive layer 166 is exposed. Thus, the connection portion 204 and the FPC 172 can be electrically connected to each other through the connection layer 242.

As the connection layer 242, for example, an anisotropic conductive film (ACF) or an anisotropic conductive paste (ACP) can be used.

The connection portion 204 includes a portion not provided with the protective layer 131 so that the FPC 172 and the conductive layer 166 can be electrically connected to each other. For example, the protective layer 131 is formed over the entire surface of the display apparatus 200A and then a region of the protective layer 131 overlapping with the conductive layer 166 is removed using a mask, so that the conductive layer 166 can be exposed.

A stacked-layer structure of at least one organic layer and a conductive layer may be provided over the conductive layer 166, and the protective layer 131 may be provided over the stacked structure. Then, a separation trigger (a portion that can be a trigger of separation) may be formed in the stacked structure using a laser or a sharp cutter (e.g., a needle or a utility knife) to selectively remove the stacked structure and the protective layer 131 thereover, so that the conductive layer 166 is exposed. For example, the protective layer 131 can be selectively removed when an adhesive roller is pressed to the substrate 151 and then moved relatively while being rolled. Alternatively, an adhesive tape may be attached to the substrate 151 and then peeled. Since adhesion between the organic layer and the conductive layer or between the organic layers is low, separation occurs at the interface between the organic layer and the conductive layer or in the organic layer. Thus, a region of the protective layer 131 overlapping with the conductive layer 166 can be selectively removed. Note that when the organic layer and the like remain over the conductive layer 166, the remaining organic layer and the like can be removed by an organic solvent or the like.

As the organic layer, it is possible to use at least one of the organic layers (the layer functioning as the light-emitting layer, the carrier-blocking layer, the carrier-transport layer, or the carrier-injection layer) used for the layer 113B, the layer 113G, or the layer 113R, for example. The organic layer may be formed during the formation of the layer 113B, the layer 113G, or the layer 113R, or may be provided separately. The conductive layer can be formed using the same step and the same material as the common electrode 115. An ITO film is preferably formed as the common electrode 115 and the conductive layer, for example. Note that in the case where a stacked structure is used for the common electrode 115, at least one of the layers included in the common electrode 115 is provided as the conductive layer.

The top surface of the conductive layer 166 may be covered with a mask so that the protective layer 131 cannot be provided over the conductive layer 166. As the mask, a metal mask (area metal mask) or a tape or a film having adhesiveness or attachability may be used. The protective layer 131 is formed while the mask is placed and then the mask is removed, whereby the conductive layer 166 can be kept exposed even after the protective layer 131 is formed.

With such a method, a region not provided with the protective layer 131 can be formed in the connection portion 204, and the conductive layer 166 and the FPC 172 can be electrically connected to each other through the connection layer 242 in the region.

The conductive layer 123 is provided over the insulating layer 235 in the connection portion 140. End portions of the conductive layer 123 are covered with the insulating layer 237. The common electrode 115 is provided over the conductive layer 123.

The display apparatus 200A illustrated in FIG. 17 is a top-emission display apparatus. Light emitted from the light-emitting devices is emitted toward the substrate 152. For the substrate 152, a material having a high visible-light-transmitting property is preferably used. The pixel electrode 111 includes a material that reflects visible light, and the common electrode 115 includes a material that transmits visible light. In FIG. 17, dashed arrows indicate light R, light G, and light B, which are emitted toward the substrate 152 from the light-emitting device 130R, the light-emitting device 130G, and the light-emitting device 130B, respectively.

The light-blocking layer 117 is preferably provided on the surface of the substrate 152 on the substrate 151 side. The light-blocking layer 117 can be provided in a region between adjacent light-emitting devices, in the connection portion 140, and in the circuit 164. The light-blocking layer 117 can prevent color mixture by blocking light emitted from adjacent subpixels. Furthermore, external light can be inhibited from reaching the transistor 201, the transistor 205R, the transistor 205G, and the transistor 205B, so that deterioration of the transistor 201, the transistor 205R, the transistor 205G, and the transistor 205B can be inhibited. Note that a structure without the light-blocking layer 117 may be employed.

A variety of optical members can be provided on the outside of the substrate 152. Examples of optical members include a polarizing plate, a retardation plate, a light diffusion layer (e.g., a diffusion film), an anti-reflective layer, and a light-condensing film. Furthermore, a surface protective layer such as an antistatic film inhibiting the attachment of dust, a water repellent film inhibiting the attachment of stain, a hard coat film inhibiting generation of a scratch caused by the use, or an impact-absorbing layer be provided on the outside of the substrate 152. For example, it is preferable to provide, as the surface protective layer, a glass layer or a silica layer (SiOₓ layer) because the surface contamination or damage can be prevented. The surface protective layer may be formed using diamond-like carbon (DLC), aluminum oxide (AlOₓ), a polyester-based material, a polycarbonate-based material, or the like. For the surface protective layer, a material having a high transmittance of visible light is preferably used. The surface protective layer is preferably formed using a material with high hardness.

A material that can be used for the substrate 102 can be used for each of the substrate 151 and the substrate 152. The substrate through which light from the light-emitting device is extracted is formed using a material that transmits the light. A polarizing plate may be used as the substrate through which light from the light-emitting device is extracted.

When the substrate 151 and the substrate 152 are formed using a flexible material, the flexibility of the display apparatus can be increased. For each of the substrate 151 and the substrate 152, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used as each of the substrate 151 and the substrate 152.

In the case where a circularly polarizing plate overlaps with the display apparatus, a highly optically isotropic substrate is preferably used as the substrate included in the display apparatus. A highly optically isotropic substrate has a low birefringence (i.e., a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of a highly optically isotropic film include a triacetyl cellulose (TAC, also referred to as cellulose triacetate) film, a cycloolefin polymer (COP) film, a cycloolefin copolymer (COC) film, and an acrylic film.

When a film used as the substrate absorbs water, the shape of the display apparatus might be changed, e.g., creases might be caused. Thus, as the substrate, a film with a low water absorption rate is preferably used. For example, the water absorption rate of the film is preferably 1% or lower, further preferably 0.1% or lower, still further preferably 0.01% or lower.

For the resin layer 142, a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, and an ethylene vinyl acetate (EVA) resin. In particular, a material with low moisture permeability, such as an epoxy resin, is preferable. A two-component-mixture-type resin may be used. An adhesive sheet or the like may be used.

Structure examples that are different from the structures of the aforementioned display apparatus are described below. Note that portions similar to those of the aforementioned display apparatus are omitted in some cases. In the drawings mentioned below, the same hatching pattern is used for a portion having a function similar to that of the aforementioned display apparatus, and the portion is not denoted by a reference numeral in some cases.

### <Display Apparatus 200B>

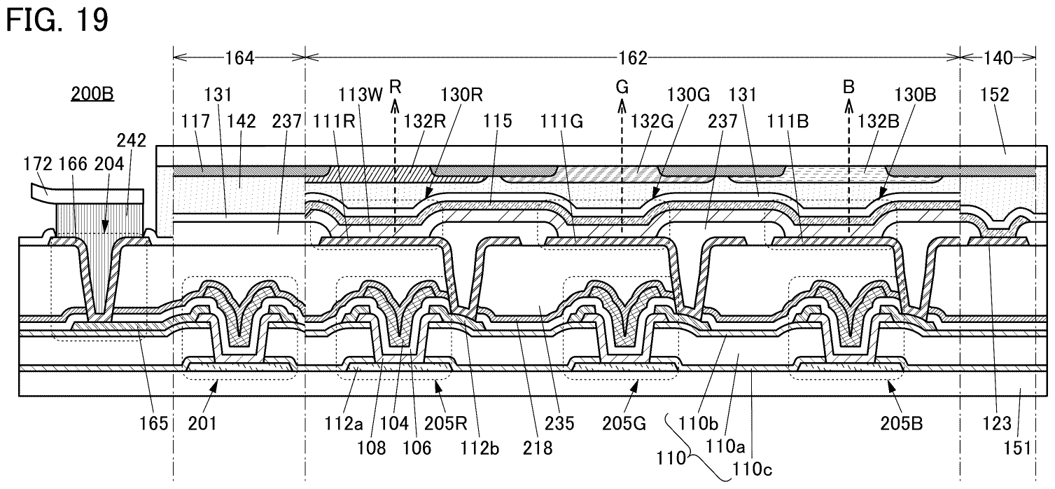

A display apparatus 200B illustrated in FIG. 19 differs from the display apparatus 200A illustrated in FIG. 17 mainly in the structures of the light-emitting device 130R, the light-emitting device 130G, and the light-emitting device 130B.

The light-emitting device 130R includes a layer 113W instead of the layer 113R. The light-emitting device 130G includes the layer 113W instead of the layer 113G. The light-emitting device 130B includes the layer 113W instead of the layer 113B. For example, the layer 113W has a structure in which white light can be emitted. The layer 113W can be formed by a vacuum evaporation method or a sputtering method, for example. The layer 113W can be shared between the light-emitting device 130R, the light-emitting device 130G, and the light-emitting device 130B. The layer 113W shared between the plurality of light-emitting devices 130 enables the layer 113W to be formed without a fine metal mask. The layer 113W is provided in the display portion 162. For example, an area mask can be used to form the layer 113W.

An optical adjustment layer (not illustrated) may be provided between the pixel electrode 111 and the layer 113. As the optical adjustment layer, a conductive layer having a visible-light-transmitting property can be used. The thicknesses of the optical adjustment layers may differ among the light-emitting device 130R, the light-emitting device 130G, and the light-emitting device 130B. The thicknesses of the optical adjustment layers are preferably adjusted so as to make the optical path lengths that can intensify light emitted from the light-emitting devices 130. Thus, intensified light with a desired wavelength can be obtained from the light-emitting devices 130 even when the layer 113W that emits white light is used.

A coloring layer 132R transmitting red light, a coloring layer 132G transmitting green light, and a coloring layer 132B transmitting blue light may be provided on the surface of the substrate 152 that faces the adhesive layer 142. The coloring layer 132R is provided in a region overlapping with the light-emitting device 130R. The coloring layer 132G is provided in a region overlapping with the light-emitting device 130G. The coloring layer 132B is provided in a region overlapping with the light-emitting device 130B. For example, light with an unnecessary wavelength emitted from the red-light-emitting device 130R can be blocked by the coloring layer 132R. Such a structure can further increase the color purity of light emitted from each light-emitting device. Note that a similar effect can be obtained in a combination of the light-emitting device 130G and the coloring layer 132G or a combination of the light-emitting device 130B and the coloring layer 132B.

The coloring layer 132R, the coloring layer 132G, and the coloring layer 132B can be used in other structure examples.

### <Display Apparatus 200C>

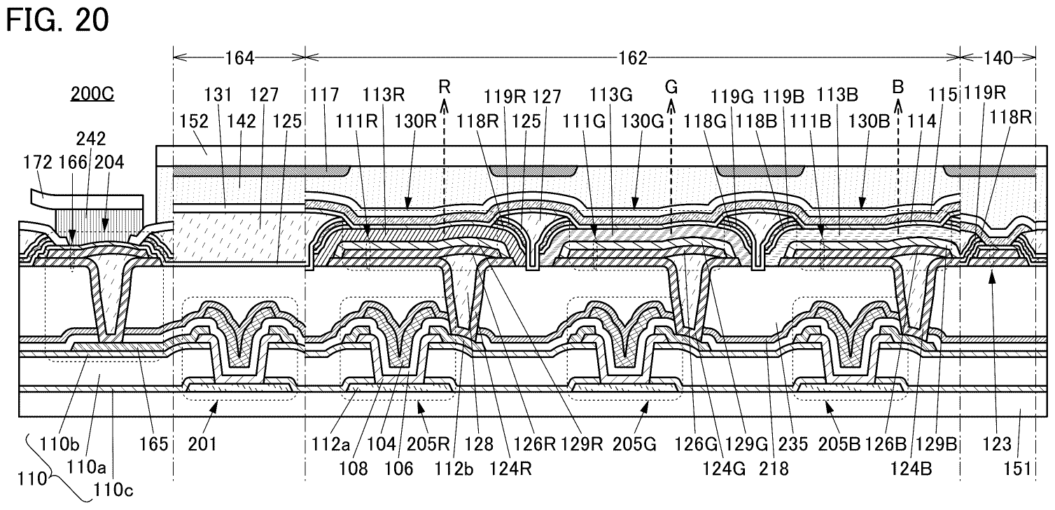

A display apparatus 200C illustrated in FIG. 20 differs from the display apparatus 200A illustrated in FIG. 17 mainly in the structures of the pixel electrode 111R, the pixel electrode 111G, the pixel electrode 111B, the conductive layer 123 and the conductive layer 166 and also in that the insulating layer 237 is not included, the layer 113 covers a top surface and a side surface of the pixel electrode 111, and a common layer 114, an insulating layer 125, and an insulating layer 127 are included.

The light-emitting device 130R includes the pixel electrode 111R over the insulating layer 235, the island-shaped layer 113R over the pixel electrode 111R, the common layer 114 over the island-shaped layer 113R, and the common electrode 115 over the common layer 114. In the light-emitting device 130R, the layer 113R and the common layer 114 can be collectively referred to as an EL layer.

The light-emitting device 130G includes the pixel electrode 111G over the insulating layer 235, the island-shaped layer 113G over the pixel electrode 111G, the common layer 114 over the island-shaped layer 113G, and the common electrode 115 over the common layer 114. In the light-emitting device 130G, the layer 113G and the common layer 114 can be collectively referred to as an EL layer.

The light-emitting device 130B includes the pixel electrode 111B over the insulating layer 235, the island-shaped layer 113B over the pixel electrode 111B, the common layer 114 over the island-shaped layer 113B, and the common electrode 115 over the common layer 114. In the light-emitting device 130B, the layer 113B and the common layer 114 can be collectively referred to as an EL layer.

In this specification and the like, in the EL layers included in the light-emitting devices, the island-shaped layer provided in each light-emitting device is referred to as the layer 113R, the layer 113G, or the layer 113B, and the layer shared by the plurality of light-emitting devices is referred to as the common layer 114. Note that in this specification and the like, only the layer 113R, the layer 113G, and the layer 113B are sometimes referred to as island-shaped EL layers, EL layers formed in an island shape, or the like, in which case the common layer 114 is not included in the EL layers.

For example, the layer 113R, the layer 113G, and the layer 113B may each include a hole-injection layer, a hole-transport layer, a light-emitting layer, and an electron-transport layer in this order. In addition, an electron-blocking layer may be provided between the hole-transport layer and the light-emitting layer. In addition, a hole-blocking layer may be provided between the electron-transport layer and the light-emitting layer. Furthermore, an electron-injection layer may be provided over the electron-transport layer.

The layer 113R, the layer 113G, and the layer 113B may each include an electron-injection layer, an electron-transport layer, a light-emitting layer, and a hole-transport layer in this order, for example. In addition, a hole-blocking layer may be provided between the electron-transport layer and the light-emitting layer. In addition, an electron-blocking layer may be provided between the hole-transport layer and the light-emitting layer. Furthermore, a hole-injection layer may be provided over the hole-transport layer.

Thus, the layer 113R, the layer 113G, and the layer 113B each preferably include the light-emitting layer and a carrier-transport layer (an electron-transport layer or a hole-transport layer) over the light-emitting layer. Alternatively, the layer 113R, the layer 113G, and the layer 113B each preferably include a light-emitting layer and a carrier-blocking layer (a hole-blocking layer or an electron-blocking layer) over the light-emitting layer. Alternatively, the layer 113R, the layer 113G, and the layer 113B each preferably include a light-emitting layer, a carrier-blocking layer over the light-emitting layer, and a carrier-transport layer over the carrier-blocking layer.

The light-emitting device 130R, the light-emitting device 130G, and the light-emitting device 130G may have a tandem structure. In the case of using a tandem structure, preferably, the layer 113R includes a plurality of light-emitting units that emit red light, the layer 113G includes a plurality of light-emitting units that emit green light, and the layer 113B includes a plurality of light-emitting units that emit blue light. A charge-generation layer is preferably provided between the light-emitting units. The layer 113R, the layer 113G, and the layer 113B may include a first light-emitting unit, a charge-generation layer over the first light-emitting unit, and a second light-emitting unit over the charge-generation layer, for example.

The second light-emitting unit preferably includes a light-emitting layer and a carrier-transport layer (an electron-transport layer or a hole-transport layer) over the light-emitting layer. Alternatively, the second light-emitting unit preferably includes a light-emitting layer and a carrier-blocking layer (a hole-blocking layer or an electron-blocking layer) over the light-emitting layer. Alternatively, the second light-emitting unit preferably includes a light-emitting layer, a carrier-blocking layer over the light-emitting layer, and a carrier-transport layer over the carrier-blocking layer. Since the surface of the second light-emitting unit is exposed in the manufacturing process of the display apparatus, providing one or both of the carrier-transport layer and the carrier-blocking layer over the light-emitting layer inhibits the light-emitting layer from being exposed on the outermost surface, so that damage to the light-emitting layer can be reduced. Accordingly, the reliability of the light-emitting device can be increased. Note that in the case where three or more light-emitting units are provided, the uppermost light-emitting unit preferably includes a light-emitting layer and one or both of a carrier-transport layer and a carrier-blocking layer over the light-emitting layer.

The common layer 114 includes, for example, an electron-injection layer or a hole-injection layer. Alternatively, the common layer 114 may be a stack of an electron-transport layer and an electron-injection layer, or may be a stack of a hole-transport layer and a hole-injection layer. The common layer 114 is shared between the light-emitting device 130R, the light-emitting device 130G, and the light-emitting device 130B. The common layer 114 can be formed by an evaporation method (including a vacuum evaporation method), a transfer method, a printing method, an inkjet method, or a coating method, for example.

The common layer 114 is not necessarily provided in the connection portion 140. In the structure illustrated in FIG. 20, the common electrode 115 is provided over the conductive layer 123. The structure in which the common layer 114 is provided over the conductive layer 123, and the conductive layer 123 and the common electrode 115 are electrically connected to each other through the common layer 114 may be employed. For example, by using an area mask, the common layer 114 can be formed in a region different from a region where the common electrode 115 is formed.

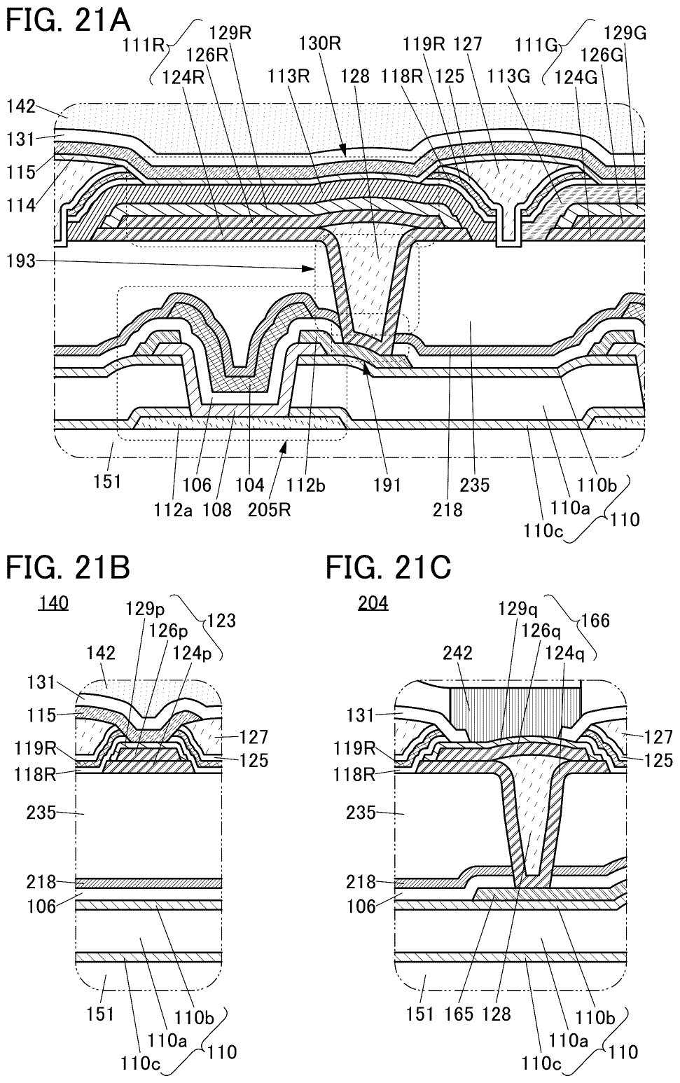

FIG. 21A is an enlarged view of the light-emitting device 130R, the transistor 205R, and the vicinity thereof.

The pixel electrode 111R included in the light-emitting device 130R has a stacked-layer structure including a conductive layer 124R, a conductive layer 126R over the conductive layer 124R, and a conductive layer 129R over the conductive layer 126R.

The conductive layer 124R is electrically connected to the conductive layer 112b included in the transistor 205R through the opening 191 and the opening 193 provided in the insulating layer 106, the insulating layer 218, and the insulating layer 235.

The end portion of the conductive layer 124R is positioned outward from the end portion of the conductive layer 126R. The end portion of the conductive layer 126R is positioned inward from the end portion of the conductive layer 129R. The end portion of the conductive layer 124R is positioned inward from the end portion of the conductive layer 129R. In other words, the end portion of the conductive layer 126R is positioned over the conductive layer 124R. The end portion of the conductive layer 129R is positioned over the conductive layer 124R. A top surface and a side surface of the conductive layer 126R are covered with the conductive layer 129R.

For the conductive layer 124R, no particular limitations are imposed on the properties of transmitting and reflecting visible light. As the conductive layer 124R, a conductive layer having a visible-light-transmitting property or a conductive layer having a visible-light-reflecting property can be used. As a conductive layer having a visible-light-transmitting property, a conductive layer including an oxide conductor (also referred to as an oxide conductive layer) can be used, for example. Specifically, an In—Si—Sn oxide (also referred to as ITSO) can be suitably used as the conductive layer 124R. For a conductive layer having a visible-light-reflecting property, metal such as aluminum, titanium, chromium, nickel, copper, yttrium, zirconium, silver, tin, zinc, platinum, gold, molybdenum, tantalum, or tungsten, or an alloy containing the metal as its main component (e.g., an alloy of silver, palladium, and copper (Ag—Pd—Cu (APC))) can be used, for example. The conductive layer 124R may have a stacked-layer structure of a conductive layer having a visible-light-transmitting property and a conductive layer having a reflecting property over the conductive layer. For the conductive layer 124R, a material with high adhesion to the formation surface of the conductive layer 124R (here, the insulating layer 235) is preferably used. Accordingly, separation of the conductive layer 124R can be inhibited.

A conductive layer having a visible-light-reflecting property can be used as the conductive layer 126R. The conductive layer 126R may have a stacked-layer structure of a conductive layer having a visible-light-transmitting property and a conductive layer having a reflecting property over the conductive layer. For the conductive layer 126R, the material that can be used for the conductive layer 124R can be used. Specifically, a stacked-layer structure of an In—Si—Sn oxide (ITSO) and an alloy of silver, palladium, and copper (APC) over the In—Si—Sn oxide (ITSO) can be suitably used as the conductive layer 126R.

For the conductive layer 129R, the material that can be used for the conductive layer 124R can be used. A conductive layer having a visible-light-transmitting property can be used for the conductive layer 129R, for example. Specifically, an In—Si—Sn oxide (ITSO) can be used for the conductive layer 129R.

When a material that is easily oxidized is used for the conductive layer 126R, a material that is not easily oxidized is used for the conductive layer 129R, and the conductive layer 126R is covered with the conductive layer 129R, whereby oxidation of the conductive layer 126R can be inhibited. In addition, precipitation of a metal component included in the conductive layer 126R can be inhibited. For example, when a material including silver is used for the conductive layer 126R, an In—Si—Sn oxide (ITSO) can be suitably used for the conductive layer 129R. Thus, oxidation of the conductive layer 126R can be inhibited, and precipitation of silver can be inhibited

Detailed description is omitted, regarding the conductive layer 124G, the conductive layer 126G, and the conductive layer 129G in the light-emitting device 130G, and the conductive layer 124B, the conductive layer 126B, and the conductive layer 129B in the light-emitting device 130B, which are similar to the conductive layer 124R, the conductive layer 126R, and the conductive layer 129R in the light-emitting device 130R.

FIG. 21B is an enlarged view of the connection portion 140. The conductive layer 123 can have a stacked-layer structure of a conductive layer 124p, a conductive layer 126p over the conductive layer 124p, and a conductive layer 129p over the conductive layer 126p, for example. The conductive layer 124p can be formed in the same step as the conductive layer 124R, the conductive layer 124G, and the conductive layer 124B. The conductive layer 126p can be formed in the same step as the conductive layer 126R, the conductive layer 126G, and the conductive layer 126B. The conductive layer 129p can be formed in the same step as the conductive layer 129R, the conductive layer 129G, and the conductive layer 129B.

FIG. 21C is an enlarged view of the connection portion 204. The conductive layer 166 can have a stacked-layer structure of a conductive layer 124q, a conductive layer 126q over the conductive layer 124q, and a conductive layer 129q over the conductive layer 126q, for example. The conductive layer 124q can be formed in the same step as the conductive layer 124R, the conductive layer 124G, and the conductive layer 124B. The conductive layer 126q can be formed in the same step as the conductive layer 126R, the conductive layer 126G, and the conductive layer 126B. The conductive layer 129q can be formed in the same step as the conductive layer 129R, the conductive layer 129G, and the conductive layer 129B.

FIG. 20 and the like illustrate a structure in which the thicknesses of the conductive layer 129p and the conductive layer 129q are different from those of the conductive layer 129R, the conductive layer 129G, and the conductive layer 129B. The thicknesses may vary depending on the resistivity of the materials used for the conductive layer 129p, the conductive layer 129q, the conductive layer 129R, the conductive layer 129G, and the conductive layer 129B. In the case where the thicknesses vary, the conductive layer 129p and the conductive layer 129q may be formed in a step different from that of the conductive layer 129R, the conductive layer 129G, and the conductive layer 129B. Alternatively, a step of forming the conductive layer 129p and the conductive layer 129q and a step of forming the conductive layer 129R, the conductive layer 129G, and the conductive layer 129B may be partly shared. The thickness of the conductive layer 129p and the thickness of the conductive layer 129q may be different from each other.

The pixel electrode 111R, the pixel electrode 111G, and the pixel electrode 111B, the conductive layer 123, and the conductive layer 166 illustrated in FIG. 20 and the like can also be used in other structure examples.

The conductive layer 124R, the conductive layer 124G, the conductive layer 124B, and the conductive layer 124q are provided with concave portions to cover openings provided in the insulating layer 106, the insulating layer 218, and the insulating layer 235. A layer 128 is embedded in the concave portions.

The layer 128 has a planarization function for the concave portions of the conductive layer 124R, the conductive layer 124G, the conductive layer 124B, and the conductive layer 124q. The conductive layer 126R, the conductive layer 126G, the conductive layer 126B, and the conductive layer 126q that are respectively electrically connected to the conductive layer 124R, the conductive layer 124G, the conductive layer 124B, and the conductive layer 124q are provided over the conductive layer 124R, the conductive layer 124G, the conductive layer 124B, the conductive layer 124q, and the layer 128. Thus, in the light-emitting devices 130, the regions overlapping with the concave portions of the conductive layer 124R, the conductive layer 124G, and the conductive layer 124B can also function as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. In particular, the layer 128 is preferably formed using an organic material. In particular, a photosensitive organic resin is preferably used as the organic material. For example, a photosensitive resin composition containing an acrylic resin can be preferably used for the layer 128.

When the layer 128 is a conductive layer, the layer 128 can serve as part of a pixel electrode. For the layer 128, for example, an organic resin in which metal particles are dispersed can be used.

The layer 128 illustrated in FIG. 20 and the like can be used in other structure examples.

FIG. 20 and FIG. 21A illustrates an example where the end portion of the layer 113R is positioned outward from the end portion of the pixel electrode 111R. The layer 113R is formed to cover the end portion of the pixel electrode 111R. Such a structure enables the entire top surface of the pixel electrode to be a light-emitting region, and the aperture ratio can be increased as compared with the structure where the end portion of the island-shaped EL layer is positioned inward from the end portion of the pixel electrode. Covering the side surface of the pixel electrode 111 with the EL layer can inhibit a contact between the pixel electrode 111 and the common electrode 115, thereby inhibiting a short-circuit of the light-emitting device 130. Note that although the pixel electrode 111R and the layer 113R are described by way of example, the same applies to the pixel electrode 111G and the layer 113G, and the pixel electrode 111B and the layer 113B.

An insulating layer (the insulating layer 237 in FIG. 17) covering an end portion of the top surface of the pixel electrode 111R is not provided between the pixel electrode 111R and the layer 113R. An insulating layer covering an end portion of the top surface of the pixel electrode 111G is not provided between the pixel electrode 111G and the layer 113G. Thus, the interval between adjacent light-emitting devices can be shortened. Accordingly, the display apparatus can be a high definition display apparatus or a high-resolution display apparatus. In addition, a mask for forming the insulating layer is not needed, which leads to a reduction in manufacturing cost of the display apparatus.

The EL layer can be formed by a photolithography method, for example. Specifically, a film to be the light-emitting layers is formed across a plurality of pixel electrodes that have been formed independently for respective subpixels. Then, the film is processed by a photolithography method so that one island-shaped light-emitting layer is formed for each pixel electrode. Thus, the light-emitting layer can be divided into island-shaped light-emitting layers in respective subpixels. A photolithography method enables a miniaturized EL layer to be formed. When the EL layer is provided in an island shape for each light-emitting device, a leakage current between adjacent light-emitting devices can be inhibited. This can prevent unintended light emission due to crosstalk, so that a display device with extremely high contrast can be obtained. Specifically, a display apparatus having high current efficiency at low luminance can be obtained.

The heat-resistant temperature of the compounds contained in the layer 113R, the layer 113G, and the layer 113B is preferably higher than or equal to 100° C. and lower than or equal to 180° C., further preferably higher than or equal to 120° C. and lower than or equal to 180° C., still further preferably higher than or equal to 140° C. and lower than or equal to 180° C. For example, the glass transition point (Tg) of these compounds is preferably higher than or equal to 100° C. and lower than or equal to 180° C., further preferably higher than or equal to 120° C. and lower than or equal to 180° C., still further preferably higher than or equal to 140° C. and lower than or equal to 180° C. This inhibits a reduction in light emission efficiency and a decrease in lifetime which are due to damage to the layer 113R, the layer 113G, and the layer 113B by heat applied in a manufacturing process.

In a region between adjacent light-emitting devices 130, the insulating layer 125 and the insulating layer 127 over the insulating layer 125 are provided. Although FIG. 20 illustrates cross sections of a plurality of insulating layers 125 and a plurality of insulating layers 127, the insulating layers 125 are connected to each other and the insulating layers 127 are connected to each other when the display apparatus 200C is seen from above. In other words, the display apparatus 200C can have a structure including one insulating layer 125 and one insulating layer 127, for example. Note that the display apparatus 200C may include a plurality of insulating layers 125 that are separated from each other and a plurality of insulating layers 127 that are separated from each other.

The insulating layer 125 is preferably in contact with the side surfaces of the layer 113R, the layer 113G, and the layer 113B. The insulating layer 125 in contact with the layer 113R, the layer 113G, and the layer 113B can prevent separation of the layer 113R, the layer 113G, and the layer 113B. When the insulating layer is in close contact with the layer 113B, the layer 113G, or the layer 113R, adjacent layers 113B and the like can be fixed or bonded to each other by the insulating layer. Accordingly, the reliability of the light-emitting device can be increased. The manufacturing yield of the light-emitting devices can also be improved.

An organic material can be used for the insulating layer 125. For the insulating layer 125, one or more of oxide, oxynitride, nitride oxide, and nitride can be used, for example. The insulating layer 125 may have a single-layer structure or a stacked-layer structure. Examples of the oxide include silicon oxide, aluminum oxide, magnesium oxide, indium-gallium-zinc oxide, gallium oxide, germanium oxide, yttrium oxide, zirconium oxide, lanthanum oxide, neodymium oxide, hafnium oxide, and tantalum oxide. Examples of the nitride include silicon nitride and aluminum nitride. Examples of the oxynitride include silicon oxynitride and aluminum oxynitride. Examples of the nitride oxide include silicon nitride oxide and aluminum nitride oxide. In particular, aluminum oxide is preferably used because it has high selectivity with respect to the EL layer in etching and has a function of protecting the EL layer.

The insulating layer 125 preferably has a function of a barrier insulating film against at least one of water and oxygen. Alternatively, the insulating layer 125 preferably has a function of inhibiting diffusion of at least one of water and oxygen. Alternatively, the insulating layer 125 preferably has a function of capturing or fixing (also referred to as gettering) at least one of water and oxygen. Note that in this specification and the like, a barrier insulating layer refers to an insulating layer having a barrier property. A barrier property in this specification and the like means a function of inhibiting diffusion of a particular substance (also referred to as low permeability).

When the insulating layer 125 has a function of the barrier insulating layer or a gettering function, entry of impurities (typically, at least one of water and oxygen) that would diffuse into the light-emitting devices from the outside can be inhibited. With this structure, a highly reliable light-emitting device and a highly reliable display apparatus can be provided.

The insulating layer 127 is provided over the insulating layer 125 to fill a concave portion formed by the insulating layer 125. The insulating layer 127 can overlap with the side surface and part of the top surface of each of the layer 113R, the layer 113G, and the layer 113B with the insulating layer 125 therebetween. The insulating layer 127 preferably covers at least part of a side surface of the insulating layer 125. The insulating layer 125 and the insulating layer 127 can fill a gap between the adjacent island-shaped layers, whereby unevenness of the formation surface for the layers (e.g., the carrier-injection layer and the common electrode) to be provided over the island-shaped layers can be reduced and the coverage with the layers can be improved. The top surface of the insulating layer 127 preferably has a shape with higher planarity, but may include a convex portion, a convex surface, a concave surface, or a concave portion.

As the insulating layer 127, an insulating layer containing an organic material can be favorably used. As the organic material, a photosensitive organic resin is preferably used, and for example, a photosensitive resin composite containing an acrylic resin is preferably used. Note that in this specification and the like, an acrylic resin refers to not only a polymethacrylic acid ester or a methacrylic resin, but also acrylic polymers in a broad sense in some cases.

The insulating layer 127 may be formed using an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. In addition, the insulating layer 127 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used for the photosensitive resin. As the photosensitive organic resin, either a positive material or a negative material may be used.

The insulating layer 127 may be formed using a material absorbing visible light. When the insulating layer 127 absorbs light emitted from the light-emitting device, leakage of light (stray light) from the light-emitting device to the adjacent light-emitting device through the insulating layer 127 can be inhibited. Thus, the display quality of the display apparatus can be improved. Since no polarizing plate is required to improve the display quality, the weight and thickness of the display apparatus can be reduced.

Examples of the material absorbing visible light include materials containing pigment of black or the like, materials containing dye, light-absorbing resin materials (e.g., polyimide), and resin materials that can be used for color filters (color filter materials). Using the resin material obtained by stacking or mixing color filter materials of two or three or more colors is particularly preferred, in which case the effect of blocking visible light is enhanced. In particular, mixing color filter materials of three or more colors enables the formation of a black or nearly black resin layer.

A mask layer 118R and a mask layer 119R are positioned over the layer 113R included in the light-emitting device 130R, a mask layer 118G and a mask layer 119G are positioned over the layer 113G included in the light-emitting device 130G, and a mask layer 118B and a mask layer 119B are positioned over the layer 113B included in the light-emitting device 130B. The mask layer 118 and the mask layer 119 are provided to surround the light-emitting region. In other words, the mask layer 118 and the mask layer 119 have an opening in a portion overlapping with the light-emitting region. The mask layer 118R and the mask layer 119R are remaining parts of the mask layers provided over the layer 113R at the time of forming the layer 113R. In a similar manner, the mask layer 118G and the mask layer 119G are remaining parts of the mask layers at the time of forming the layer 113G, and the mask layer 118B and the mask layer 119B are remaining parts of the mask layers provided at the time of forming the layer 113B. Thus, the mask layer used to protect the EL layer in manufacture of the display apparatus may partly remain in the display apparatus of one embodiment of the present invention.

The common layer 114 and the common electrode 115 are provided over the layer 113R, the layer 113G, and the layer 113B, the mask layer 118 and the mask layer 119, and the insulating layer 125 and the insulating layer 127. Before the insulating layer 125 and the insulating 127 are provided, a step difference is generated due to a difference between a region where the pixel electrode and the island-shaped EL layer are provided and a region where neither the pixel electrode nor the island-shaped EL layer is provided (region between the light-emitting devices). In the display apparatus of one embodiment of the present invention, the step difference can be reduced by the presence of the insulating layer 125 and the insulating 127, and the coverage with the common layer 114 and the common electrode 115 can be improved. Consequently, a defective connection due to step disconnection can be inhibited. In addition, an increase in the electric resistance, which is caused by local thinning of the common electrode 115 due to the step difference, can be inhibited.

The insulating layer 127 may cover at least parts of the side surface of the insulating layer 125 and the side surface of the mask layer 118R, the side surface of the mask layer 119R, the side surface of the mask layer 118G, the side surface of the mask layer 119G, the side surface of the mask layer 118B, and the side surface of the mask layer 119B. The insulating layer 127 may include regions in contact with the layer 113R, the layer 113G, and the layer 113B.

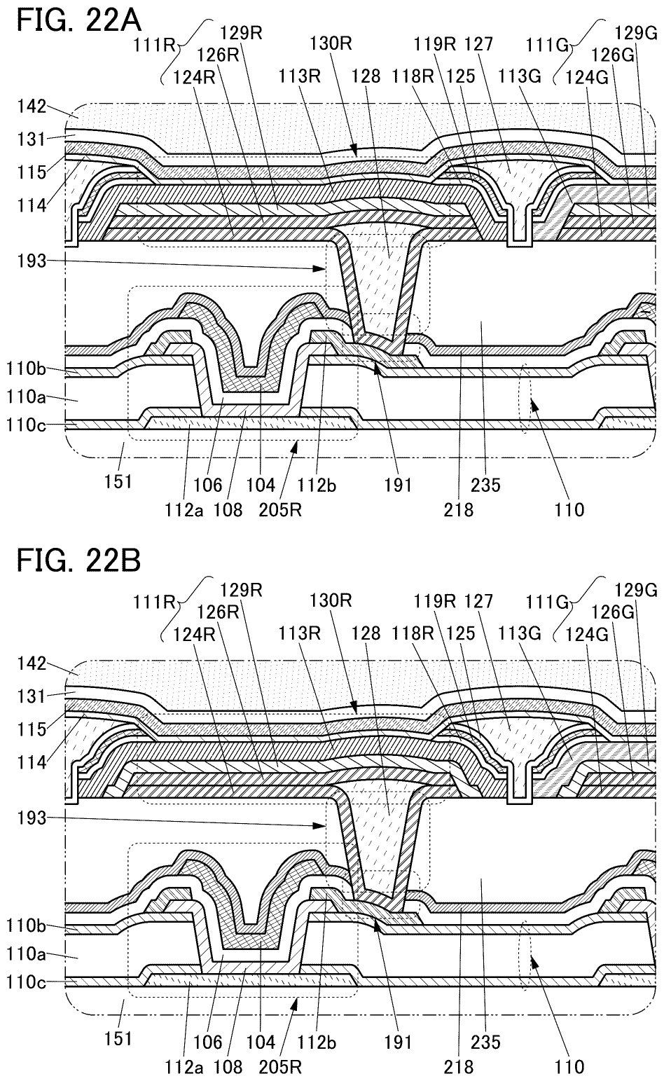

FIG. 22A and FIG. 22B illustrate structure examples different from that of the pixel electrode 111R illustrated in FIG. 21A and the like.

In the pixel electrode 111R illustrated in FIG. 22A, end portions of the conductive layer 129R, the conductive layer 126R, and the conductive layer 124R are aligned or substantially aligned with each other. The layer 113R is in contact with the side surface of the conductive layer 129R, the side surface of the conductive layer 126R, and the side surface of the conductive layer 124R.

For example, a first conductive film to be the conductive layer 124R, the layer 128, a second conductive film to be the conductive layer 126R, and a third conductive film to be the conductive layer 129R are formed, a resist mask is formed over the third conductive film, and the first conductive film, the second conductive film, and the third conductive film are processed using the resist mask, whereby the conductive layer 124R, the conductive layer 126R, and the conductive layer 129R can be formed. The first conductive film, the second conductive film, and the third conductive film are processed in the same step to form the conductive layer 124R, the conductive layer 126R, and the conductive layer 129R, whereby the process can be simplified.

In the pixel electrode 111R illustrated in FIG. 22B, the side surface of the conductive layer 124R and the top surface and the side surface of the conductive layer 126R are covered with the conductive layer 129R. The end portion of the conductive layer 124R and the end portion of the conductive layer 126R are aligned or substantially aligned with each other. The layer 113R is in contact with the top surface and the side surface of the conductive layer 129R.

For example, after the first conductive film to be the conductive layer 124R, the layer 128, and the second conductive film to be the conductive layer 126R are formed, a resist mask is formed over the second conductive film, and the first conductive film and the second conductive film are processed using the resist mask, whereby the conductive layer 124R and the conductive layer 126R are formed. After that, the third conductive film to be the conductive layer 129R is formed to cover the conductive layer 124R and the conductive layer 126R, and the third conductive film is processed to form the conductive layer 129R. The first conductive film and the second conductive film are processed in the same step to form the conductive layer 124R and the conductive layer 126R, whereby the process can be simplified. Even when a material that is easily diffused, such as silver, is used for the conductive layer 124R or the conductive layer 126R, the top and side surfaces of the conductive layer 124R and the conductive layer 126R are covered with the conductive layer 129R, whereby diffusion can be inhibited.

Although FIG. 22A and the like illustrate a structure in which the top surface of the layer 128 has a shape in which the center and the vicinity thereof bulge, i.e., a shape including a convex surface, in a cross-sectional view, the shape of the layer 128 is not particularly limited. The top surface of the layer 128 can have a shape in which the center and the vicinity thereof are recessed, i.e., a shape including a concave surface, in a cross-sectional view. The top surface of the layer 128 may include one or both of a convex surface and a concave surface. The number of convex surfaces and the number of concave surfaces included in the top surface of the layer 128 are not limited and can each be one or more.

The level of the top surface of the layer 128 and the level of the top surface of the conductive layer 124R may be match or substantially match with each other, or may be different from each other. For example, the level of the top surface of the layer 128 may be lower or higher than the level of the top surface of the conductive layer 124R.

Note that the pixel electrode 111 illustrated in FIG. 21A, FIG. 22A, and FIG. 22B can also be used in other structure examples.

### <Display Apparatus 200D>

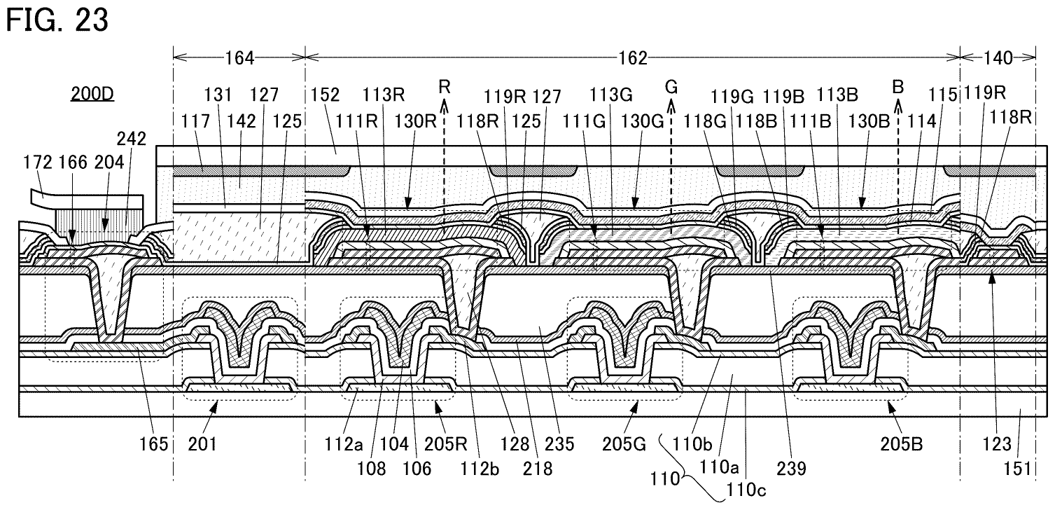

A display apparatus 200D illustrated in FIG. 23 differs from the display apparatus 200C illustrated in FIG. 20 mainly in including an insulating layer 239.

The insulating layer 239 is provided over the insulating layer 235 and includes an opening in a region overlapping with the opening in the insulating layer 235. The pixel electrode 111 is provided to cover the opening provided in the insulating layer 239, the insulating layer 235, the insulating layer 218, and the insulating layer 106.

The insulating layer 239 can function as an etching protective film at the time of formation of the layer 113. The insulating layer 239 can prevent generation of unevenness in the insulating layer 235 caused by etching of part of the insulating layer 235 at the time of formation of the layer 113. Thus, a step difference in the formation surface of the insulating layer 125 become small, whereby the coverage with the insulating layer 125 can be increased. Consequently, the side surface of the layer 113 is covered with the insulating layer 125, which can prevent separation of the layer 113.

The insulating layer 239 can be an insulating layer including an inorganic material. For the insulating layer 239, one or more of oxide, nitride, oxynitride, and nitride oxide can be used, for example. The insulating layer 239 may have a single-layer structure or a stacked-layer structure. Examples of the oxide include silicon oxide, aluminum oxide, magnesium oxide, indium-gallium-zinc oxide, gallium oxide, germanium oxide, yttrium oxide, zirconium oxide, lanthanum oxide, neodymium oxide, hafnium oxide, and tantalum oxide. Examples of the nitride include silicon nitride and aluminum nitride. Examples of the oxynitride include silicon oxynitride and aluminum oxynitride. Examples of the nitride oxide include silicon nitride oxide and aluminum nitride oxide. Silicon oxide or silicon oxynitride can be suitably used as the insulating layer 239, for example.

The insulating layer 239 preferably includes a material having a high etching rate (selectivity) with respect to film to be the layer 113 in etching of the film.

The low planarity of the formation surface of the light-emitting device 130 might cause a connection defect due to step disconnection of the common electrode 115 or an increase in electric resistance due to local thinning of the common electrode 115, for example. In addition, the processing accuracy of the layer to be formed on the formation surface might be lowered.

In the display apparatus of one embodiment of the present invention, the formation surface of the light-emitting devices 130 can be planarized by the insulating layer 239. Accordingly, the processing accuracy of the light-emitting devices 130 and the like provided over the insulating layer 239 is increased, whereby the display apparatus can have high definition. Furthermore, since defective connection due to step disconnection of the common electrode 115 and an increase in electric resistance due to local thinning of the common electrode 115 can be prevented, the display apparatus can have high display quality.

Although the insulating layer 239 has a single-layer structure in FIG. 23, one embodiment of the present invention is not limited to this example. The insulating layer 239 may have a stacked-layer structure.

In the region overlapping with none of the layer 113R, the layer 113G, and the layer 113B, part of the insulating layer 239 may be removed. The thickness of the insulating layer 239 in the region overlapping with none of the layer 113R, the layer 113G, and the layer 113B may be smaller than the thickness of the insulating layer 239 in the region overlapping with the layer 113R, the layer 113G, or the layer 113B.

The insulating layer 239 can be used in other structure examples.

### <Display Apparatus 200E>

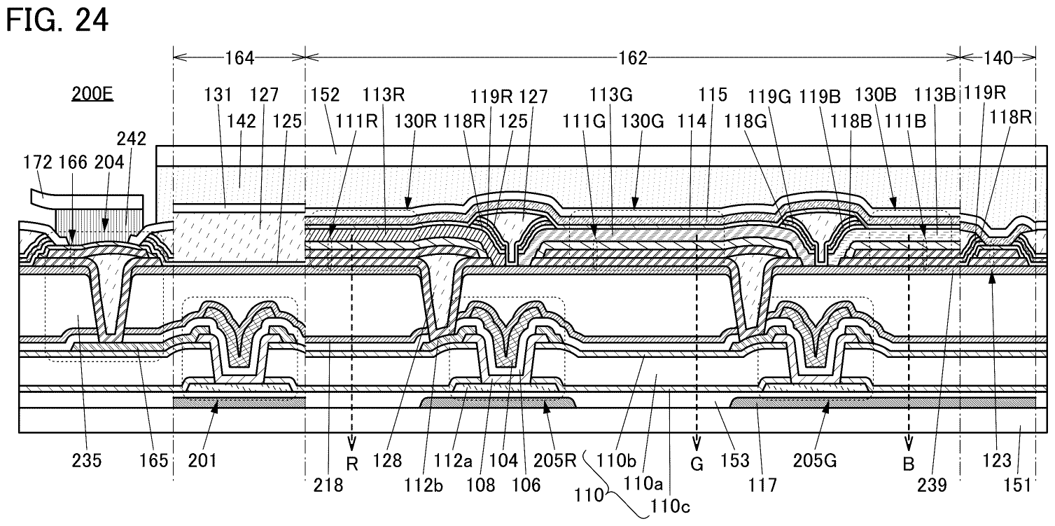

The display apparatus 200E illustrated in FIG. 24 differs from the display apparatus 200D illustrated in FIG. 23 mainly in having a bottom-emission structure.

Light emitted from the light-emitting devices is emitted through the substrate 151. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor 201 and between the substrate 151 and the transistor 205. FIG. 24 illustrates an example in which the light-blocking layer 117 is provided over the substrate 151, an insulating layer 153 is provided over the light-blocking layer 117, and the transistor 201, the transistor 205R, and the transistor 205G are provided over the insulating layer 153.

A material having a high visible-light-transmitting property is used for each of the pixel electrode 111R, the pixel electrode 111G, and the pixel electrode 111B. A material that reflects visible light is preferably used for the common electrode 115.

### <Display Apparatus 200F>

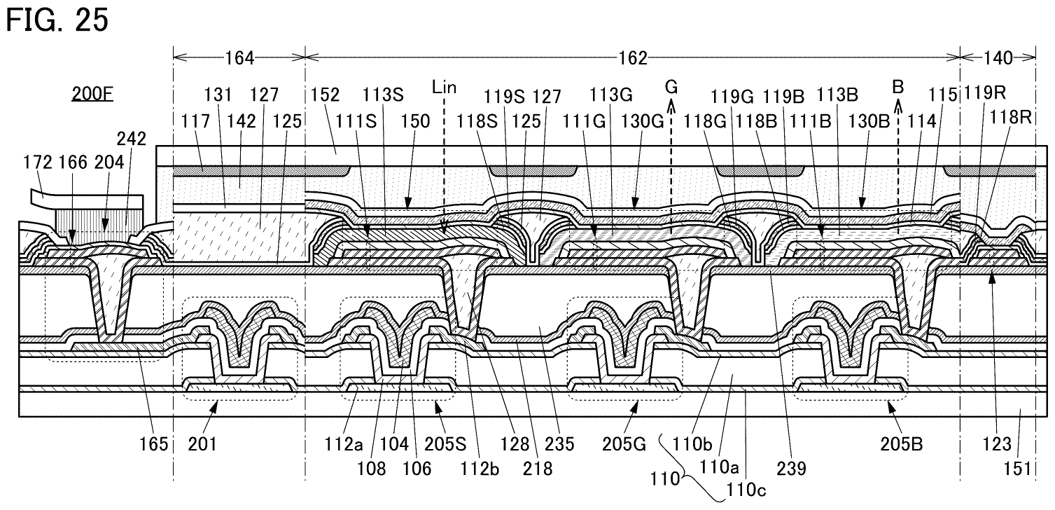

A display apparatus 200F illustrated in FIG. 25 differs from the display apparatus 200D illustrated in FIG. 23 mainly in including a light-receiving device 150.

As the light-receiving device 150, a PN photodiode or a PIN photodiode can be used, for example. The light-receiving device 150 functions as a photoelectric conversion device (also referred to as a photoelectric conversion element) that detects light entering the light-receiving device 150 to generate electric charge. The amount of electric charge generated by the light-receiving device 150 depends on the amount of light entering the light-receiving device 150.

The light-receiving device 150 can detect one or both of visible light and infrared light. In the case of detecting visible light, for example, one or more of blue light, violet light, bluish violet light, green light, yellowish green light, yellow light, orange light, red light, and the like can be detected. The infrared light is preferably detected, in which case an object can be detected even in a dark environment.

It is particularly preferable to use an organic photodiode including a layer including an organic compound as the light-receiving device 150. An organic photodiode, which is easily made thin, lightweight, and large in area and has a high degree of freedom for shape and design, can be used in a variety of display apparatuses.

In one embodiment of the present invention, an organic EL device is used as the light-emitting device 130, and an organic photodiode is used as the light-receiving device 150. The organic EL device and the organic photodiode can be formed over one substrate. Thus, the organic photodiode can be incorporated into the display apparatus including the organic EL device.

The light-receiving device 150 is driven by application of reverse bias between the pixel electrode and the common electrode, whereby light entering the light-receiving device can be detected and electric charge can be generated and extracted as a current.

In FIG. 25, the light G and the light B, which are emitted toward the substrate 152 from the light-emitting device 130G and light-emitting device 130B, and light Lin, which enters the light-receiving device 150 through the substrate 152, are indicated by the respective dashed arrows.

A manufacturing method similar to that of the light-emitting device 130 can be employed for the light-receiving device 150. An island-shaped active layer (also referred to as a photoelectric conversion layer) included in the light-receiving device can be formed with a fine metal mask, for example. The active layer can also be formed by a photolithography method instead of the method using a fine metal mask. In the photolithography method, a film that is to be the active layer is formed entirely and processed to form the active layer, and accordingly the island-shaped active layer with a uniform thickness can be formed. Moreover, providing the mask layer over the active layer can reduce damage to the active layer in the manufacturing process of the display apparatus, resulting in an improvement in reliability of the light-receiving device. A structure in which the active layer is formed by the photolithography method is described by way of example.

The light-receiving device 150 includes a pixel electrode 111S, a layer 113S, the common layer 114, and the common electrode 115. The layer 113S includes at least an active layer. The pixel electrode 111S can be formed in the same step as the pixel electrode 111R (not illustrated), the pixel electrode 111G, and the pixel electrode 111B.

The pixel electrode 111S is electrically connected to the conductive layer 112b included in a transistor 205S. A transistor 205S can be fabricated in the same step as the transistor 205R, the transistor 205G, and the transistor 205B. The insulating layer 235, the insulating layer 218, and the insulating layer 106 include an opening in a region overlapping with the conductive layer 112b included in the transistor 205S. The pixel electrode 111S of the light-receiving device 150 is provided to cover the opening. The conductive layer 112b included in the transistor 205S is electrically connected to the pixel electrode 111S through the opening. The layer 113S is provided over the pixel electrode 111S. The common layer 114 is provided over the layer 113S, and the common electrode 115 is provided over the common layer 114. The common layer 114 is a continuous film shared between the light-receiving device 150 and the light-emitting device 130.

Here, the layer 113S includes at least an active layer, preferably includes a plurality of functional layers. Examples of the functional layer include carrier-transport layers (a hole-transport layer and an electron-transport layer) and carrier-blocking layers (a hole-blocking layer and an electron-blocking layer). In addition, one or more layers are preferably formed over the active layer. A layer between the active layer and the mask layer can inhibit the active layer from being exposed on the outermost surface during the manufacturing process of the display apparatus and can reduce damage to the active layer. Accordingly, the reliability of the light-receiving device 150 can be increased. Thus, the layer 113S preferably includes an active layer and a carrier-blocking layer (a hole-blocking layer or an electron-blocking layer) or a carrier-transport layer (an electron-transport layer or a hole-transport layer) over the active layer.

The layer 113S is provided in the light-receiving device 150, not in the light-emitting devices. Note that the functional layer other than the active layer in the layer 113S may include the same material as the functional layer other than the light-emitting layer in the layer 113B to the layer 113R. Meanwhile, the common layer 114 is a continuous layer shared by the light-emitting device and the light-receiving device.

Here, a layer shared by the light-receiving device and the light-emitting device may have a different function depending on which device the layer is in. In this specification, the name of a component is based on its function in the light-emitting device in some cases. For example, a hole-injection layer functions as a hole-injection layer in the light-emitting device and functions as a hole-transport layer in the light-receiving device. Similarly, an electron-injection layer functions as an electron-injection layer in the light-emitting device and functions as an electron-transport layer in the light-receiving device. A layer shared by the light-receiving device and the light-emitting device may have the same function in both the light-receiving device and the light-emitting device. For example, the hole-transport layer functions as a hole-transport layer in both the light-emitting device and the light-receiving device, and the electron-transport layer functions as an electron-transport layer in both the light-emitting device and the light-receiving device.

The insulating layer 125 and the insulating layer 127 over the insulating layer 125 are provided in a region between the light-emitting device 130 and the light-receiving device 150 adjacent to each other.

The mask layer 118R and the mask layer 119R are positioned between the layer 113R and the insulating layer 125, and a mask layer 118S and a mask layer 119S are positioned between the layer 113S and the insulating layer 125. The mask layer 118R and the mask layer 119R are remaining parts of the mask layers provided over the layer 113R at the time of processing the layer 113R. The mask layer 118S and the mask layer 119S are remaining parts of the mask layers provided in contact with the top surface of the layer 113S at the time of processing the layer 113S, which is a layer including the active layer. The mask layer 118B and the mask layer 118S may include the same material or different materials. The mask layer 119B and the mask layer 119S may include the same material or different materials.

This embodiment can be combined with any of the other embodiments as appropriate.

### Embodiment 3

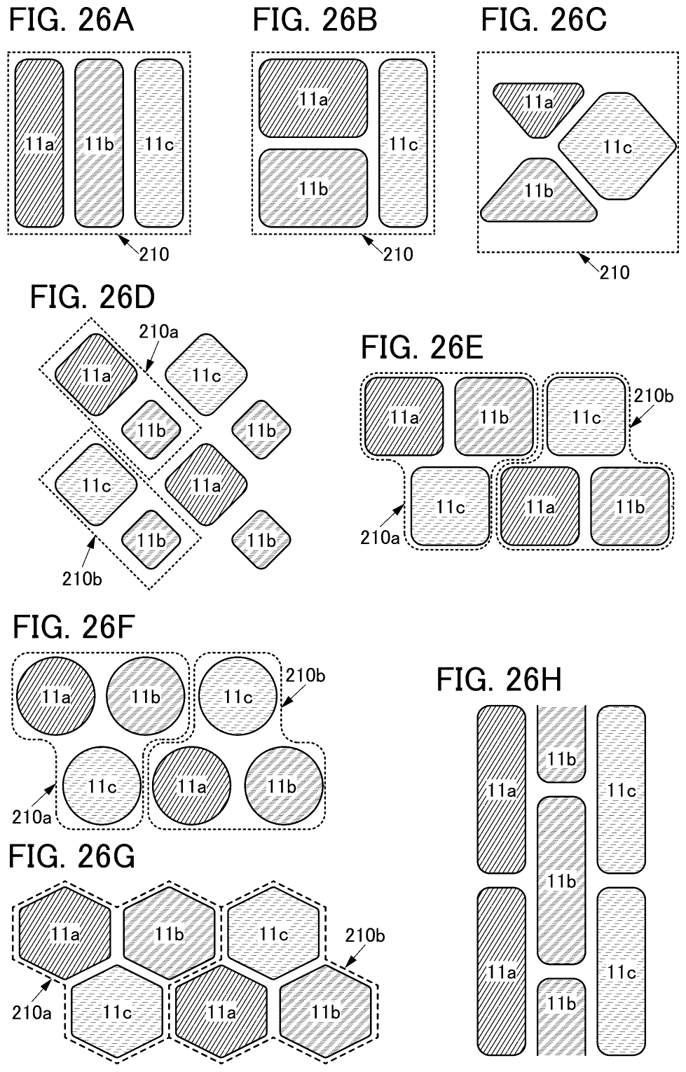

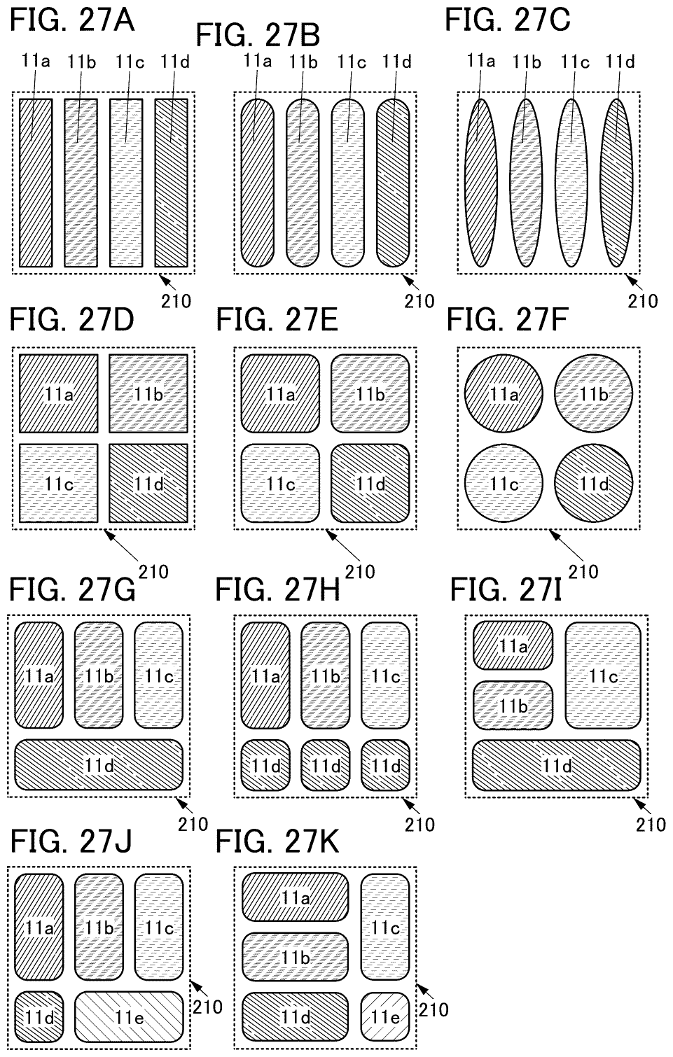

In this embodiment, display apparatuses of embodiments of the present invention are described with reference to FIG. 26 and FIG. 27.

A pixel layout is described. There is no particular limitation on the arrangement of subpixels, and a variety of methods can be employed. Examples of the arrangement of subpixels include stripe arrangement, S stripe arrangement, matrix arrangement, delta arrangement, Bayer arrangement, and PenTile arrangement.

Examples of a top surface shape of the subpixel include polygons such as a triangle, a tetragon (including a rectangle and a square), and a pentagon; polygons with rounded corners; an ellipse; and a circle. A top surface shape of the subpixel corresponds to a top surface shape of a light-emitting region of a light-emitting device and a top surface shape of a light-receiving region of a light-receiving device.

The pixel 210 illustrated in FIG. 26A employs stripe arrangement. The pixel 210 includes three types of a subpixel 11a, a subpixel 11b, and a subpixel 11c. The subpixel 11a, the subpixel 11b, and the subpixel 11c emit light of different colors from each other. The subpixel 11a, the subpixel 11b, and the subpixel 11c can be of three colors of red (R), green (G), and blue (B) or of three colors of yellow (Y), cyan (C), and magenta (M), for example. The number of types of subpixels is not limited to three, and four or more types of subpixels may be used. Examples of four subpixels include subpixels emitting light of four colors of R, G, B, and white (W), subpixels emitting light of four colors of R, G, B, and Y, and four subpixels emitting light of R, G, and B and infrared light (IR).

The subpixels each include a pixel circuit that controls the light-emitting device. The pixel circuit is not necessarily placed within the dimensions of the subpixel illustrated in FIG. 26A and may be placed outside the subpixel. For example, transistors included in the pixel circuit of a subpixel 11a may be positioned within the dimension of a subpixel 11a illustrated in FIG. 26A, or some or all of the transistors may be positioned outside the dimension of the subpixel 11a.

Although the subpixel 11a, the subpixel 11b, and the subpixel 11c have the same or substantially the same aperture ratio (also referred to as that the light-emitting regions have the same or substantially the size) in FIG. 26A, one embodiment of the present invention is not limited thereto. Note that the aperture ratio of each of the subpixel 11a, the subpixel 11b, and the subpixel 11c can be determined as appropriate. The subpixel 11a, the subpixel 11b, and the subpixel 11c may have different aperture ratios, or two or more of the subpixel 11a, the subpixel 11b, and the subpixel 11c may have the same or substantially the same aperture ratio.

The pixel 210 in FIG. 26B employs S-stripe arrangement. In FIG. 26B, the three subpixels of the subpixel 11a, the subpixel 11b, and the subpixel 11c make up the pixel 210 where two subpixels (the subpixel 11a and the subpixel 11b) are in the left column (first column) and one subpixel (the subpixel 11c) is in the right column (second column).

The pixel 210 illustrated in FIG. 26C includes the subpixel 11a whose top surface shape is a rough trapezoidal shape with rounded corners, the subpixel 11b whose top surface shape is a rough triangle shape with rounded corners, and the subpixel 11c whose top surface shape is a rough tetragonal or rough hexagonal shape with rounded corners. The subpixel 11b has a larger light-emitting area than the subpixel 11a. In this manner, the shapes and sizes of the subpixels can be determined independently. For example, the size of a subpixel including a light-emitting device with higher reliability can be smaller.

A pixel 210a and a pixel 210b illustrated in FIG. 26D employ PenTile arrangement. FIG. 26D illustrates an example where the pixels 210a including the subpixel 11a and the subpixel 11b and the pixels 210b including the subpixel 11b and the subpixel 11c are alternately arranged.

The pixel 210a and the pixel 210b illustrated in FIG. 26E to 26G employ delta arrangement. The pixel 210a includes two subpixels (the subpixel 11a and the subpixel 11b) in the upper row (first row) and one subpixel (the subpixel 11c) in the lower row (second row). The pixel 210b includes one subpixel (the subpixel 11c) in the upper row (first row) and two subpixels (the subpixel 11a and the subpixel 11b) in the lower row (second row).

FIG. 26E illustrates an example where the top surface shape of each subpixel is a rough square shape with rounded corners, FIG. 26F illustrates an example where the top surface shape of each subpixel is a circular shape, and FIG. 26G illustrates an example where the top surface shape of each subpixel is a rough hexagonal shape with rounded corners.

In FIG. 26G, a subpixel is provided in each of the hexagonal regions that are arranged densely. Focusing on one of the subpixels, the subpixel is placed so as to be surrounded by six subpixels. In addition, the subpixels are arranged such that subpixels exhibiting the same color are not adjacent to each other. For example, focusing on the subpixel 11a, three subpixels 11b and three subpixels 11c are alternately provided so as to surround the subpixel 11a.

FIG. 26H illustrates an example where subpixels of different colors are arranged in a zigzag manner. Specifically, the positions of the top sides of two subpixels arranged in the row direction (e.g., the subpixel 11a and the subpixel 11b or the subpixel 11b and the subpixel 11c) are not aligned in the top view.

For example, in each pixel in FIG. 26A to 26H, it is preferable that the subpixel 11a be a subpixel R emitting red light, the subpixel 11b be a subpixel G emitting green light, and the subpixel 11c be a subpixel B emitting blue light. Note that the structures of the subpixels are not limited to this, and the colors and arrangement order of the subpixels can be determined as appropriate. For example, the subpixel 11b may be the subpixel R emitting red light and the subpixel 11a may be the subpixel G emitting green light.

In a photolithography method, as a pattern to be formed by processing becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface shape of a subpixel may be a polygonal shape with rounded corners, an elliptical shape, a circular shape, or the like.

To obtain a desired top surface shape of the subpixel, a technique of correcting a mask pattern in advance so that a transferred pattern matches with a design pattern (an optical proximity correction (OPC) technique) may be used. Specifically, with the OPC technique, a pattern for correction is added to a corner portion or the like of a figure on a mask pattern.

As illustrated in FIG. 27A to FIG. 27I, the pixel can include four types of subpixels.

The pixel 210 illustrated in FIG. 27A to FIG. 27C employs stripe arrangement.

FIG. 27A illustrates an example where each subpixel has a rectangular top surface shape, FIG. 27B illustrates an example where each subpixel has a top surface shape formed by combining two half circles and a rectangle, and FIG. 27C illustrates an example where each subpixel has an elliptical top surface shape.

The pixel 210 illustrated in FIG. 27D to FIG. 27F employs matrix arrangement.

FIG. 27D illustrates an example where the top surface of each subpixel has a square shape, FIG. 27E illustrates an example where the top surface of each subpixel has a rough square shape with rounded corners, and FIG. 27F illustrates an example where the top surface of each subpixel has a circular shape.

FIG. 27G and FIG. 27H each illustrate an example where one pixel 210 is composed of two rows and three columns.

The pixel 210 illustrated in FIG. 27G includes three subpixels (the subpixel 11a, the subpixel 11b, and the subpixel 11c) in the upper row (first row) and one subpixel (subpixel 11d) in the lower row (second row). In other words, the pixel 210 includes the subpixel 11a in the left column (first column), the subpixel 11b in the center column (second column), the subpixel 11c in the right column (third column), and the subpixel 11d across these three columns.

The pixel 210 illustrated in FIG. 27H includes three subpixels (the subpixel 11a, the subpixel 11b, and the subpixel 11c) in the upper row (first row) and three subpixels 11d in the lower row (second row). In other words, the pixel 210 includes the subpixel 11a and the subpixel 11d in the left column (first column), the subpixel 11b and another subpixel 11d in the center column (second column), and the subpixel 11c and another subpixel 11d in the right column (third column). Matching the positions of the subpixels in the upper row and the lower row as illustrated in FIG. 27H enables dust and the like that would be produced in the manufacturing process to be removed efficiently. Thus, a display apparatus having high display quality can be provided.

FIG. 27I illustrates an example where one pixel 210 is composed of three rows and two columns.

The pixel 210 illustrated in FIG. 27I includes the subpixel 11a in the upper row (first row), the subpixel 11b in the center row (second row), the subpixel 11c across the first and second rows, and one subpixel (the subpixel 11d) in the lower row (third row). In other words, the pixel 210 includes the subpixel 11a and the subpixel 11b in the left column (first column), the subpixel 11c in the right column (second column), and the subpixel 11d across these two columns.

The pixel 210 illustrated in FIG. 27A to FIG. 27I includes four subpixels of the subpixel 11a, the subpixel 11b, the subpixel 11c, and the subpixel 11d.

The subpixel 11a, the subpixel 11b, the subpixel 11c, and the subpixel 11d include light-emitting devices of different emission colors. The subpixel 11a, the subpixel 11b, the subpixel 11c, and the subpixel 11d can be of four colors of R, G, B, and white (W), of four colors of R, G, B, and Y, or of R, G, B and infrared (IR) light, for example.

In the pixel 210 illustrated in FIG. 27A to FIG. 27I, it is preferable that the subpixel 11a be the subpixel R emitting red light, the subpixel 11b be the subpixel G emitting green light, the subpixel 11c be the subpixel B emitting blue light, and the subpixel 11d be any of a subpixel W emitting white light, a subpixel Y emitting yellow light, and a subpixel IR emitting near-infrared light, for example. In the case of such a structure, stripe arrangement is employed as the layout of R, G, and B in the pixel 210 illustrated in FIG. 27G and FIG. 27H, leading to an increase in the display quality. In the pixel 210 illustrated in FIG. 27I, what is called S stripe arrangement is employed as the layout of R, G, and B, leading to higher display quality.

The pixel 210 may include a subpixel including a light-receiving device.

In the pixel 210 illustrated in FIG. 27A to FIG. 27I, any one of the subpixel 11a to the subpixel 11d may be a subpixel including a light-receiving device.

In the pixel 210 illustrated in FIG. 27A to FIG. 27I, for example, it is preferable that the subpixel 11a be the subpixel R emitting red light, the subpixel 11b be the subpixel G emitting green light, the subpixel 11c be the subpixel B emitting blue light, and the subpixel 11d be a subpixel S including a light-receiving device. In the case of such a structure, stripe arrangement is employed as the layout of R, G, and B in the pixel 210 illustrated in FIG. 27G and FIG. 27H, leading to higher display quality. In addition, what is called S stripe arrangement is employed as the layout of R, G, and B in the pixel 210 illustrated in FIG. 27I, leading to higher display quality.

There is no particular limitation on the wavelength of light detected by the subpixel S including a light-receiving device. The subpixel S can have a structure in which one or both of visible light and infrared light can be detected.

As illustrated in FIG. 27J and FIG. 27K, the pixel can include five types of subpixels.

FIG. 27J illustrates an example where one pixel 210 is composed of two rows and three columns.

The pixel 210 illustrated in FIG. 27J includes three subpixels (the subpixel 11a, the subpixel 11b, and the subpixel 11c) in the upper row (first row) and two subpixels (the subpixel 11d and a subpixel 11e) in the lower row (second row). In other words, the pixel 210 includes the subpixels 11a and the subpixel 11d in the left column (first column), the subpixel 11b in the center column (second column), the subpixel 11c in the right column (third column), and the subpixel 11e across the second and third columns.

FIG. 27K illustrates an example where one pixel 210 is composed of three rows and two columns.

The pixel 210 illustrated in FIG. 27K includes the subpixel 11a in the upper row (first row), the subpixel 11b in the center row (second row), the subpixel 11c across the first row and the second row, and two subpixels (the subpixel 11d and the subpixel 11e) in the lower row (third row). In other words, the pixel 210 includes the subpixel 11a, the subpixel 11b, and the subpixel 11d in the left column (first column), and the subpixel 11c and the subpixel 11e in the right column (second column).

In the pixel 210 illustrated in FIG. 27J and FIG. 27K, for example, it is preferable that the subpixel 11a be the subpixel R emitting red light, the subpixel 11b be the subpixel G emitting green light, and the subpixel 11c be the subpixel B emitting blue light. In the case of such a structure, stripe arrangement is employed as the layout of R, G, and B in the pixel 210 illustrated in FIG. 27J, leading to higher display quality. In addition, what is called S stripe arrangement is employed as the layout of R, G, and B in the pixel 210 illustrated in FIG. 27K, leading to higher display quality.

In the pixel 210 illustrated in FIG. 27J and FIG. 27K, for example, it is preferable to use the subpixel S including a light-receiving device as at least one of the subpixel 11d and the subpixel 11e. In the case where light-receiving devices are used in both the subpixel 11d and the subpixel 11e, the light-receiving devices may have different structures. For example, the wavelength ranges of detected light may be different at least partly. Specifically, one of the subpixel 11d and the subpixel 11e may include a light-receiving device mainly detecting visible light and the other may include a light-receiving device mainly detecting infrared light.

In the pixel 210 illustrated in FIG. 27J and FIG. 27K, for example, it is preferable that the subpixel S including a light-receiving device be used as one of the subpixel 11d and the subpixel 11e and a subpixel including a light-emitting device that can be used as a light source be used as the other. For example, it is preferable that one of the subpixel 11d and the subpixel 11e be the subpixel IR emitting infrared light and the other be the subpixel S including a light-receiving device detecting infrared light.

In the pixel including the subpixels R, G, B, IR, and S, while displaying an image using the subpixels R, G, and B, the subpixel S can detect reflected light of infrared light emitted from the subpixel IR that is used as a light source.

As described above, the pixel composed of the subpixels each including the light-emitting device can employ any of a variety of layouts in the display apparatus of one embodiment of the present invention. The display apparatus of one embodiment of the present invention can have a structure in which the pixel includes both a light-emitting device and a light-receiving device. In this case, any of a variety of layouts can be employed.

This embodiment can be combined with any of the other embodiments as appropriate.

### Embodiment 4

In this embodiment, light-emitting devices that can be used for the display apparatus of one embodiment of the present invention will be described.

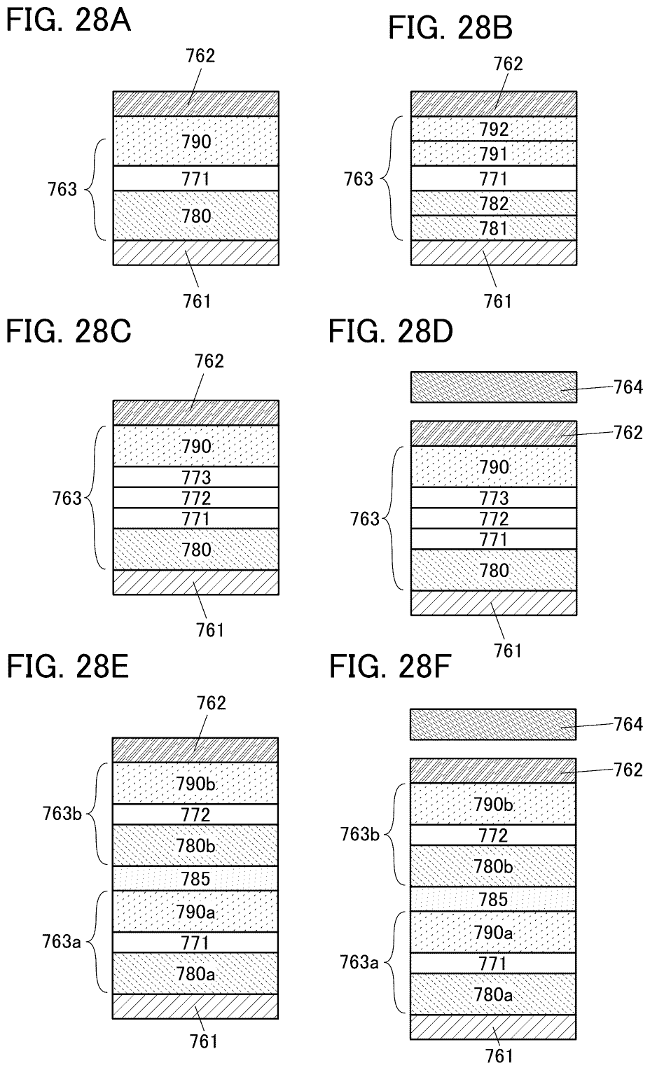

As illustrated in FIG. 28A, the light-emitting device includes an EL layer 763 between a pair of electrodes (a lower electrode 761 and an upper electrode 762). The EL layer 763 can be formed of a plurality of layers such as a layer 780, a light-emitting layer 771, and a layer 790.

The light-emitting layer 771 contains at least a light-emitting substance (also referred to as a light-emitting material).

In the case where the lower electrode 761 is an anode and the upper electrode 762 is a cathode, the layer 780 includes one or more of a layer containing a material having a high hole-injection property (a hole-injection layer), a layer containing a material having a high hole-transport property (a hole-transport layer), and a layer containing a material having a high electron-blocking property (an electron-blocking layer). Furthermore, the layer 790 includes one or more of a layer containing a material having a high electron-injection property (an electron-injection layer), a layer containing a material having a high electron-transport property (an electron-transport layer), and a layer containing a material having a high hole-blocking property (a hole-blocking layer). In the case where the lower electrode 761 is a cathode and the upper electrode 762 is an anode, the structures of the layer 780 and the layer 790 are replaced with each other.

The structure including the layer 780, the light-emitting layer 771, and the layer 790, which is provided between the pair of electrodes, can function as a single light-emitting unit, and the structure in FIG. 28A is referred to as a single structure in this specification.

FIG. 28B is a variation example of the EL layer 763 included in the light-emitting device illustrated in FIG. 28A. Specifically, the light-emitting device illustrated in FIG. 28B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layered structure, carriers can be efficiently injected to the light-emitting layer 771, and the efficiency of the recombination of carriers in the light-emitting layer 771 can be enhanced.

Note that structures in which a plurality of light-emitting layers (the light-emitting layers 771, 772, and 773) are provided between the layer 780 and the layer 790 as illustrated in FIG. 28C and FIG. 28D are other variations of the single structure. Although FIG. 28C and FIG. 28D illustrate the examples where three light-emitting layers are included, the light-emitting layer in the light-emitting device with a single structure may include two or four or more light-emitting layers. In addition, the light-emitting device with a single structure may include a buffer layer between two light-emitting layers. A carrier-transport layer (a hole-transport layer or an electron-transport layer) can be used as the buffer layer, for example.

A structure where a plurality of light-emitting units (a light-emitting unit 763a and a light-emitting unit 763b) are connected in series with a charge-generation layer 785 (also referred to as an intermediate layer) therebetween as illustrated in FIG. 28E and FIG. 28F is referred to as a tandem structure in this specification. Note that a tandem structure may be referred to as a stack structure. The tandem structure enables a light-emitting device capable of high-luminance light emission. Furthermore, the tandem structure can reduce the amount of current needed for obtaining the same luminance as compared with a single structure, and thus can improve the reliability.

Note that FIG. 28D and FIG. 28F illustrate examples where the display apparatus includes a layer 764 overlapping with the light-emitting device. FIG. 28D illustrates an example where the layer 764 overlaps with the light-emitting device illustrated in FIG. 28C, and FIG. 28F illustrates an example where the layer 764 overlaps with the light-emitting device illustrated in FIG. 28E. In FIG. 28D and FIG. 28F, a conductive film transmitting visible light is used for the upper electrode 762 to extract light to the upper electrode 762 side.

One or both of a color conversion layer and a color filter (a coloring layer) can be used as the layer 764.

In FIG. 28C and FIG. 28D, light-emitting substances that emit light of the same color, or moreover, the same light-emitting substance may be used for the light-emitting layer 771, the light-emitting layer 772, and the light-emitting layer 773. For example, a light-emitting substance that emits blue light may be used for the light-emitting layer 771, the light-emitting layer 772, and the light-emitting layer 773. In a subpixel that emits blue light, blue light emitted from the light-emitting device can be extracted. In a subpixel that emits red light and a subpixel that emits green light, by providing a color conversion layer as the layer 764 illustrated in FIG. 28D, blue light emitted from the light-emitting device can be converted into light with a longer wavelength, and red light or green light can be extracted. As the layer 764, both a color conversion layer and a coloring layer are preferably used. In some cases, part of light emitted from the light-emitting device is transmitted through the color conversion layer without being converted. When light transmitted through the color conversion layer is extracted through the coloring layer, light other than light of the desired color can be absorbed by the coloring layer, and color purity of light emitted from a subpixel can be improved.

In FIG. 28C and FIG. 28D, light-emitting substances that emit light of different colors may be used for the light-emitting layer 771, the light-emitting layer 772, and the light-emitting layer 773. White light emission can be obtained by mixing of light emitted from the light-emitting layer 771, the light-emitting layer 772, and the light-emitting layer 773. The light-emitting device with a single structure preferably includes a light-emitting layer containing a light-emitting substance emitting blue light and a light-emitting layer containing a light-emitting substance emitting visible light with a longer wavelength than blue light, for example.

A color filter may be provided as the layer 764 illustrated in FIG. 28D. When white light passes through the color filter, light of a desired color can be obtained.

In the case where the light-emitting device with a single structure includes three light-emitting layers, for example, a light-emitting layer containing a light-emitting substance emitting red (R) light, a light-emitting layer containing a light-emitting substance emitting green (G) light, and a light-emitting layer containing a light-emitting substance emitting blue (B) light are preferably included. The stacking order of the light-emitting layers can be RGB from an anode side or RBG from an anode side, for example. In that case, a buffer layer may be provided between R and G or between R and B.

For example, in the case where the light-emitting device with a single structure includes two light-emitting layers, the light-emitting device preferably includes a light-emitting layer containing a light-emitting substance that emits blue (B) light and a light-emitting layer containing a light-emitting substance that emits yellow (Y) light. Such a structure may be referred to as a BY single structure.

The light-emitting device that emits white light preferably contains two or more kinds of light-emitting substances. Light-emitting substances are selected such that their emission colors are mixed to make white color. For example, when an emission color of a first light-emitting layer and an emission color of a second light-emitting layer are complementary colors, the light-emitting device can be configured to emit white light as a whole. The same applied to in the case of a light-emitting device including three or more light-emitting layers.

Also in FIG. 28C and FIG. 28D, the layer 780 and the layer 790 may each independently have a stacked-layer structure of two or more layers as illustrated in FIG. 28B.

In FIG. 28E and FIG. 28F, light-emitting substances that emit light of the same color, or moreover, the same light-emitting substance may be used for the light-emitting layer 771 and the light-emitting layer 772. For example, in light-emitting devices included in subpixels emitting light of different colors, a light-emitting substance that emits blue light may be used for each of the light-emitting layer 771 and the light-emitting layer 772. In a subpixel that emits blue light, blue light emitted from the light-emitting device can be extracted. In the subpixel that emits red light and the subpixel that emits green light, by providing a color conversion layer as the layer 764 illustrated in FIG. 28F, blue light emitted from the light-emitting device can be converted into light with a longer wavelength, and red light or green light can be extracted. As the layer 764, both a color conversion layer and a coloring layer are preferably used.

In the case where the light-emitting device having the structure illustrated in FIG. 28E or FIG. 28F is used for the subpixels emitting different colors, the subpixels may use different light-emitting substances. Specifically, in the light-emitting device included in the subpixel that emits red light, a light-emitting substance that emits red light may be used for each of the light-emitting layer 771 and the light-emitting layer 772. Similarly, in the light-emitting device included in the subpixel that emits green light, a light-emitting substance that emits green light may be used for each of the light-emitting layer 771 and the light-emitting layer 772. In the light-emitting device included in the subpixel that emits blue light, a light-emitting substance that emits blue light may be used for each of the light-emitting layer 771 and the light-emitting layer 772. A display apparatus with such a structure includes a light-emitting device with a tandem structure and can be regarded to have an SBS structure. Thus, the display apparatus can have both the advantage of a tandem structure and the advantage of an SBS structure. Accordingly, a light-emitting device capable of light emission at high luminance and having high reliability can be achieved.

In FIG. 28E and FIG. 28F, light-emitting substances of different emission colors may be used for the light-emitting layer 771 and the light-emitting layer 772. White light emission can be obtained when light emitted from the light-emitting layer 771 and light emitted from the light-emitting layer 772 have complementary colors. A color filter may be provided as the layer 764 illustrated in FIG. 28F. When white light passes through the color filter, light of a desired color can be obtained.

Although FIG. 28E and FIG. 28F illustrate examples where the light-emitting unit 763a includes one light-emitting layer 771 and the light-emitting unit 763b includes one light-emitting layer 772, one embodiment of the present invention is not limited thereto. Each of the light-emitting unit 763a and the light-emitting unit 763b may include two or more light-emitting layers.

Although FIG. 28E and FIG. 28F illustrate the light-emitting device including two light-emitting units, one embodiment of the present invention is not limited thereto. The light-emitting device may include three or more light-emitting units. Note that a structure including two light-emitting units and a structure including three light-emitting units may be referred to as a two-unit tandem structure and a three-unit tandem structure, respectively.

In FIG. 28E and FIG. 28F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layer 780a and the layer 780b each include one or more of a hole-injection layer, a hole-transport layer, and an electron-blocking layer. The layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are replaced with each other, and the structures of the layer 780b and the layer 790b are also replaced with each other.

In the case where the lower electrode 761 is an anode and the upper electrode 762 is a cathode, for example, the layer 780a includes a hole-injection layer and a hole-transport layer over the hole-injection layer, and may further include an electron-blocking layer over the hole-transport layer. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, for example, the layer 780a includes an electron-injection layer and an electron-transport layer over the electron-injection layer, and may further include a hole-blocking layer over the electron-transport layer. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of manufacturing a light-emitting device with a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes into the other when voltage is applied between the pair of electrodes.

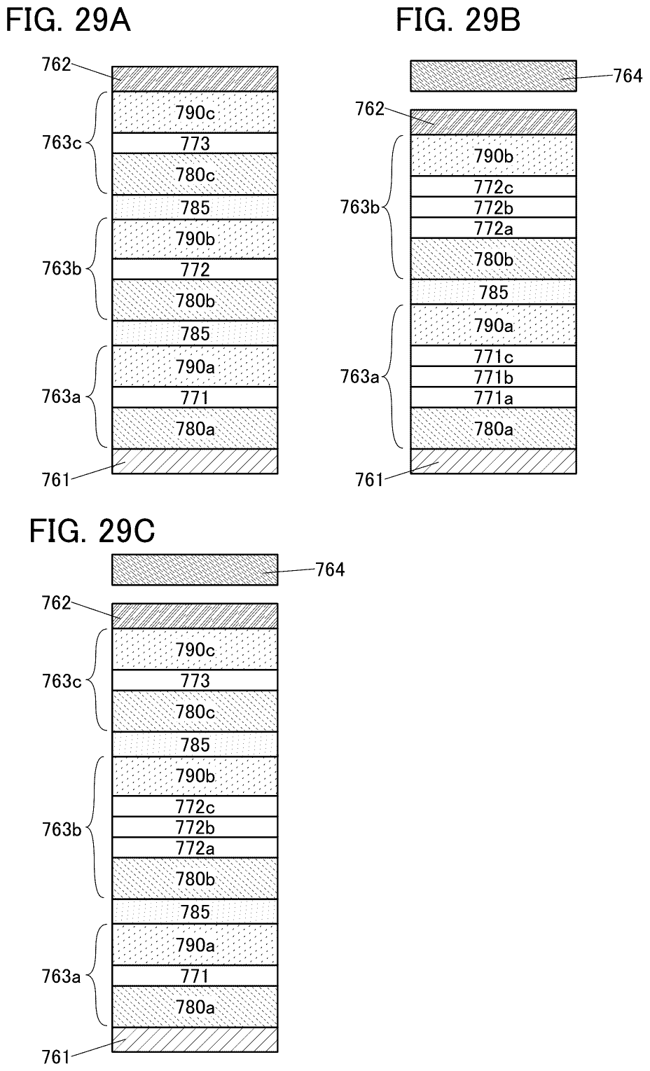

Structures illustrated in FIG. 29A to FIG. 29C can be given as examples of the light-emitting device with a tandem structure.

FIG. 29A illustrates a structure including three light-emitting units. In FIG. 29A, a plurality of light-emitting units (the light-emitting unit 763a, the light-emitting unit 763b, and a light-emitting unit 763c) are each connected in series through the charge-generation layers 785. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure usable in the layer 780a and the layer 780b, and the layer 790c can have a structure usable in the layer 790a and the layer 790b.

In FIG. 29A, the light-emitting layer 771, the light-emitting layer 772, and the light-emitting layer 773 preferably contain light-emitting substances that emit light of the same color. Specifically, the light-emitting layer 771, the light-emitting layer 772, and the light-emitting layer 773 can each contain a red (R) light-emitting substance (a so-called three-unit tandem structure of R\R\R); the light-emitting layer 771, the light-emitting layer 772, and the light-emitting layer 773 can each contain a green (G) light-emitting substance (a so-called three-unit tandem structure of G\G\G); or the light-emitting layer 771, the light-emitting layer 772, and the light-emitting layer 773 can each contain a blue (B) light-emitting substance (a so-called three-unit tandem structure of B\B\B). Note that “a\b” means that a light-emitting unit containing a light-emitting substance that emits light of b is provided over a light-emitting unit containing a light-emitting substance that emits light of a with a charge-generation layer therebetween, where a and b represent colors.

In FIG. 29A, light-emitting substances with different emission colors may be used for some or all of the light-emitting layer 771, the light-emitting layer 772, and the light-emitting layer 773. Examples of a combination of emission colors for the light-emitting layer 771, the light-emitting layer 772, and the light-emitting layer 773 include blue (B) for two of them and yellow (Y) for the other; and red (R) for one of them, green (G) for another, and blue (B) for the other.

Note that the structures of the light-emitting substances that emit light of the same color are not limited to the above structures. For example, a light-emitting device with a tandem structure may be employed in which light-emitting units each including a plurality of light-emitting layers are stacked as illustrated in FIG. 29B. FIG. 29B illustrates a structure in which two light-emitting units (the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 29B, the light-emitting substances can be selected such that the light-emitting unit 763a emits white light (W) by mixing light emitted from the light-emitting layer 771a, the light-emitting layer 771b, and the light-emitting layer 771c. In addition, the light-emitting substances can be selected such that the light-emitting unit 763b emits white light (W) by mixing light emitted from the light-emitting layer 772a, the light-emitting layer 772b, and the light-emitting layer 772c. That is, the structure illustrated in FIG. 29B is a two-unit tandem structure of WWW. Note that there is no particular limitation on the stacking order of the light-emitting substances for white emission (W). The practitioner can select the optimal stacking order as appropriate. Although not illustrated, a three-unit tandem structure of W\W\W or a tandem structure with four or more units may be employed.

In the case of a light-emitting device with a tandem structure, any of the following structure may be employed, for example: a two-unit tandem structure of B\Y or Y\B including a light-emitting unit that emits yellow (Y) light and a light-emitting unit that emits blue (B) light; a two-unit tandem structure of R·G\B or B\R·G including a light-emitting unit that emits red (R) and green (G) light and a light-emitting unit that emits blue (B) light; a three-unit tandem structure of B\Y\B including a light-emitting unit that emits blue (B) light, a light-emitting unit that emits yellow (Y) light, and a light-emitting unit that emits blue (B) light in this order; a three-unit tandem structure of B\YG\B including a light-emitting unit that emits blue (B) light, a light-emitting unit that emits yellow-green (YG) light, and a light-emitting unit that emits blue (B) light in this order; and a three-unit tandem structure of B\G\B including a light-emitting unit that emits blue (B) light, a light-emitting unit that emits green (G) light, and a light-emitting unit that emits blue (B) light in this order. Note that “a·b” means that one light-emitting unit contains a light-emitting substance that emits light of a and a light-emitting substance that emits light of b.

As illustrated in FIG. 29C, a light-emitting unit including one light-emitting layer and a light-emitting unit including a plurality of light-emitting layers may be used in combination.

Specifically, in the structure illustrated in FIG. 29C, a plurality of light-emitting units (the light-emitting unit 763a, the light-emitting unit 763b, and the light-emitting unit 763c) are each connected in series through the charge-generation layers 785. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

As the structure illustrated in FIG. 29C, for example, a three-unit tandem structure of B\R·G·YG\B in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light can be employed.

Examples of the number of stacked light-emitting units and the order of colors from the anode side include a two-unit structure of B and Y, a two-unit structure of B and a light-emitting unit X, a three-unit structure of B, Y, and B, and a three-unit structure of B, X, and B. Examples of the number of light-emitting layers stacked in the light-emitting unit X and the order of colors from an anode side include a two-layer structure of R and Y, a two-layer structure of R and G, a two-layer structure of G and R, a three-layer structure of G, R, and G, and a three-layer structure of R, G, and R. Another layer may be provided between two light-emitting layers.

Next, materials that can be used for the light-emitting device will be described.

A conductive film transmitting visible light is used for the electrode through which light is extracted, which is either the lower electrode 761 or the upper electrode 762. A conductive film reflecting visible light is preferably used for the electrode through which light is not extracted. In the case where a display apparatus includes a light-emitting device emitting infrared light, it is preferable that a conductive film transmitting visible light and infrared light be used for the electrode through which light is extracted and that a conductive film reflecting visible light and infrared light be used for the electrode through which light is not extracted.

A conductive film transmitting visible light may be used also for an electrode through which no light is extracted. In this case, this electrode is preferably provided between the reflective layer and the EL layer 763. In other words, light emitted from the EL layer 763 may be reflected by the reflective layer to be extracted from the display apparatus.

As a material that forms the pair of electrodes of the light-emitting device, a metal, an alloy, an electrically conductive compound, a mixture thereof, and the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (APC). Other example of the material include elements belonging to Group 1 and Group 2 of the periodic table, which are not exemplified above (e.g., lithium, cesium, calcium, and strontium), rare earth metals such as europium and ytterbium, an alloy containing any of these metals in appropriate combination, and graphene.

The light-emitting device preferably employs a microcavity structure. Therefore, one of the pair of electrodes of the light-emitting device is preferably an electrode having properties of transmitting and reflecting visible light (transflective electrode), and the other is preferably an electrode having a property of reflecting visible light (reflective electrode). When the light-emitting device has a microcavity structure, light obtained from the light-emitting layer can be resonated between the electrodes, whereby light emitted from the light-emitting device can be intensified.

The transparent electrode has a light transmittance higher than or equal to 40%. For example, an electrode having a visible light (light with a wavelength longer than or equal to 400 nm and shorter than 750 nm) transmittance higher than or equal to 40% is preferably used as the transparent electrode of the light-emitting device. The visible light reflectance of the transflective electrode is higher than or equal to 10% and lower than or equal to 95%, preferably higher than or equal to 30% and lower than or equal to 80%. The visible light reflectance of the reflective electrode is higher than or equal to 40% and lower than or equal to 100%, preferably higher than or equal to 70% and lower than or equal to 100%. These electrodes preferably have a resistivity of 1×10⁻² Ωcm or lower.

The light-emitting device includes at least the light-emitting layer. In addition, the light-emitting device may further include, as a layer other than the light-emitting layer, a layer containing a material with a high hole-injection property, a material with a high hole-transport property, a hole-blocking material, a material with a high electron-transport property, an electron-blocking material, a material with a high electron-injection property, a material with a bipolar property (a material with a high electron-transport property and a high hole-transport property), or the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used for the light-emitting device, and an inorganic compound may also be included. Each layer included in the light-emitting device can be formed by a method such as an evaporation method (including a vacuum evaporation method), a transfer method, a printing method, an inkjet method, or a coating method.

The light-emitting layer contains one or more kinds of light-emitting substances. As the light-emitting substance, a material whose emission color is blue, violet, bluish violet, green, yellowish green, yellow, orange, red, or the like is appropriately used. Alternatively, a material that emits near-infrared light can be used as the light-emitting substance.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material or an assist material) in addition to the light-emitting substance (a guest material). As one or more kinds of organic compounds, one or both of a material with a high hole-transport property (a hole-transport material) and a material with a high electron-transport property (an electron-transport material) can be used. As the hole-transport material, it is possible to use a material with a high hole-transport property which can be used for the hole-transport layer and will be described later. As the electron-transport material, it is possible to use a material having a high electron-transport property usable for the electron-transport layer described later. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination of materials is selected to form an exciplex that exhibits light emission whose wavelength overlaps with the wavelength of the lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

The hole-injection layer is a layer injecting holes from an anode to a hole-transport layer and containing a material with a high hole-injection property. Examples of the material with a high hole-injection property include an aromatic amine compound and a composite material containing a hole-transport material and an acceptor material (electron-accepting material).

As the hole-transport material, it is possible to use a material with a high hole-transport property usable for the hole-transport layer described later.

As the acceptor material, an oxide of a metal belonging to any of Group 4 to Group 8 of the periodic table can be used, for example. Specifically, molybdenum oxide, vanadium oxide, niobium oxide, tantalum oxide, chromium oxide, tungsten oxide, manganese oxide, and rhenium oxide are given. Among these, molybdenum oxide is particularly preferable since it is stable in the air, has a low hygroscopic property, and is easy to handle. Alternatively, an organic acceptor material containing fluorine can be used. Alternatively, an organic acceptor material such as a quinodimethane derivative, a chloranil derivative, or a hexaazatriphenylene derivative can be used.

As the material having a high hole-injection property, a material that contains a hole-transport material and the above-described oxide of a metal belonging to Group 4 to Group 8 of the periodic table (typically, molybdenum oxide) may be used, for example.

The hole-transport layer is a layer transporting holes, which are injected from the anode by the hole-injection layer, to the light-emitting layer. The hole-transport layer is a layer containing a hole-transport material. As the hole-transport material, a material having a hole mobility greater than or equal to 1×10⁻⁶ cm²/Vs is preferable. Note that other substances can also be used as long as they have a property of transporting more holes than electrons. As the hole-transport material, a material with a high hole-transport property such as a n-electron rich heteroaromatic compound (e.g., a carbazole derivative, a thiophene derivative, or a furan derivative) or an aromatic amine (a compound having an aromatic amine skeleton) is preferable.

The electron-blocking layer is provided in contact with the light-emitting layer. The electron-blocking layer is a layer having a hole-transport property and containing a material capable of blocking electrons. Any of the materials having an electron-blocking property among the above hole-transport materials can be used for the electron-blocking layer.

The electron-blocking layer has a hole-transport property, and thus can also be referred to as a hole-transport layer. A layer having an electron-blocking property among the hole-transport layers can also be referred to as an electron-blocking layer.

The electron-transport layer is a layer transporting electrons, which are injected from the cathode by the electron-injection layer, to the light-emitting layer. The electron-transport layer is a layer that contains an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, it is possible to use a material with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a T-electron deficient heteroaromatic compound including a nitrogen-containing heteroaromatic compound.

The hole-blocking layer is provided in contact with the light-emitting layer. The hole-blocking layer is a layer having an electron-transport property and containing a material that can block holes. Any of the materials having a hole-blocking property among the above electron-transport materials can be used for the hole-blocking layer.

The hole-blocking layer has an electron-transport property, and thus can also be referred to as an electron-transport layer. A layer having a hole-blocking property among the electron-transport layers can also be referred to as a hole-blocking layer.

The electron-injection layer is a layer injecting electrons from the cathode to the electron-transport layer and containing a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used.

The difference between the lowest unoccupied molecular orbital (LUMO) level of the material with a high electron-injection property and the work function value of the material used for the cathode is preferably small (specifically, less than or equal to 0.5 eV).

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato) lithium (abbreviation: Liq), 2-(2-pyridyl) phenolatolithium (abbreviation: LiPP), 2-(2-pyridyl)-3-pyridinolato lithium (abbreviation: LiPPy), 4-phenyl-2-(2-pyridyl) phenolatolithium (abbreviation: LiPPP), lithium oxide (LiOₓ), or cesium carbonate, for example. The electron-injection layer may have a stacked-layer structure of two or more layers. In the stacked-layer structure, for example, lithium fluoride can be used for the first layer and ytterbium can be used for the second layer.

The electron-injection layer may contain an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, and a pyridazine ring), and a triazine ring.

Note that the LUMO level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl) biphenyl-3-yl]-1,3,5-triazine (abbreviation: TmPPPyTz), or the like can be used as the organic compound having an unshared electron pair. Note that NBPhen has a higher glass transition point (Tg) than BPhen and thus has high heat resistance.

As described above, the charge-generation layer includes at least a charge-generation region. The charge-generation region preferably contains an acceptor material, and for example, preferably contains a hole-transport material and an acceptor material usable for the above-described hole-injection layer.

The charge-generation layer preferably includes a layer containing a material with a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered; thus, electrons generated in the charge-generation region can be easily injected into the electron-transport layer.

The electron-injection buffer layer preferably contains an alkali metal or an alkaline earth metal, and for example, can be configured to contain an alkali metal compound or an alkaline earth metal compound. Specifically, the electron-injection buffer layer preferably contains an inorganic compound containing an alkali metal and oxygen or an inorganic compound containing an alkaline earth metal and oxygen, further preferably contains an inorganic compound containing lithium and oxygen (e.g., lithium oxide (Li₂O)). Alternatively, a material usable for the electron-injection layer can be suitably used for the electron-injection buffer layer.

The charge-generation layer preferably includes a layer containing a material with a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper (II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from one another in some cases on the basis of the cross-sectional shapes, properties, or the like.

Note that the charge-generation layer may contain a donor material instead of an acceptor material. For example, the charge-generation layer may include a layer containing an electron-transport material and a donor material, which is usable for the electron-injection layer.

When the light-emitting units are stacked, provision of a charge-generation layer between two light-emitting units can inhibit an increase in drive voltage.

This embodiment can be combined with any of the other embodiments as appropriate.

### Embodiment 5

In this embodiment, a light-receiving device that can be used for the display apparatus of one embodiment of the present invention and a display apparatus having a light-emitting and light-receiving function will be described.

### [Light-Receiving Device]

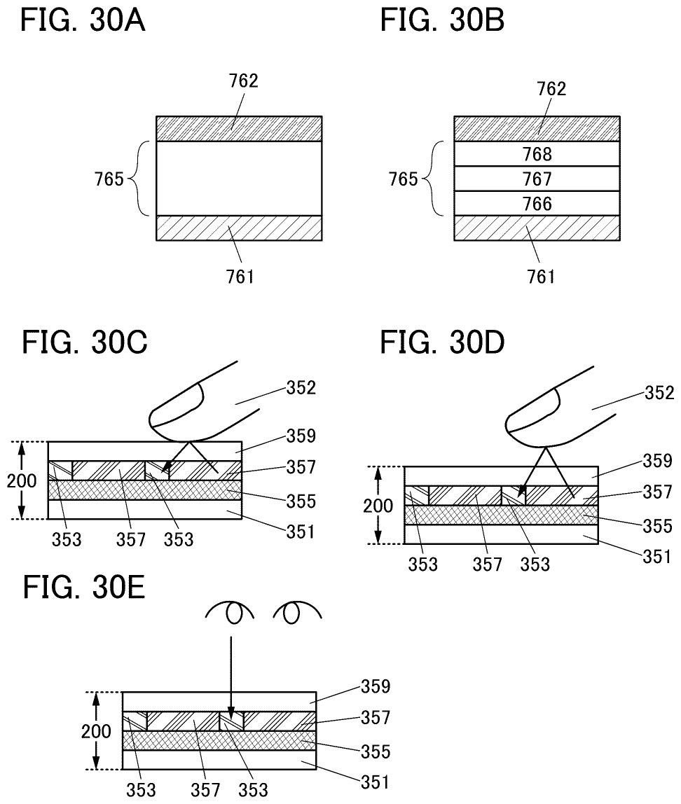

As illustrated in FIG. 30A, the light-receiving device includes a layer 765 between a pair of electrodes (the lower electrode 761 and the upper electrode 762). The layer 765 includes at least one active layer, and may further include another layer.

FIG. 30B is a variation example of the layer 765 included in the light-receiving device illustrated in FIG. 30A. Specifically, the light-receiving device illustrated in FIG. 30B includes a layer 766 over the lower electrode 761, an active layer 767 over the layer 766, a layer 768 over the active layer 767, and the upper electrode 762 over the layer 768.

The active layer 767 functions as a photoelectric conversion layer.

In the case where the lower electrode 761 is an anode and the upper electrode 762 is a cathode, the layer 766 includes one or both of a hole-transport layer and an electron-blocking layer. The layer 768 includes one or both of an electron-transport layer and a hole-blocking layer. In the case where the lower electrode 761 is a cathode and the upper electrode 762 is an anode, the structures of the layer 766 and the layer 768 are replaced with each other.

Next, materials that can be used for the light-receiving device will be described.

Either a low molecular compound or a high molecular compound can be used for the light-receiving device, and an inorganic compound may also be included. Each layer included in the light-receiving device can be formed by a method such as an evaporation method (including a vacuum evaporation method), a transfer method, a printing method, an inkjet method, or a coating method.

The active layer included in the light-receiving device includes a semiconductor. Examples of the semiconductor include an inorganic semiconductor such as silicon and an organic semiconductor including an organic compound. This embodiment describes an example in which an organic semiconductor is used as the semiconductor included in the active layer. The use of an organic semiconductor is preferable because the light-emitting layer and the active layer can be formed by the same method (e.g., a vacuum evaporation method) and thus the same manufacturing apparatus can be used.

Examples of an n-type semiconductor material included in the active layer include electron-accepting organic semiconductor materials such as fullerene (e.g., C₆₀ and C₇₀) and fullerene derivatives. Examples of the fullerene derivative include [6,6]-phenyl-C₇₁-butyric acid methyl ester (abbreviation: PC70BM), [6,6]-phenyl-C₆₁-butyric acid methyl ester (abbreviation: PC60BM), and 1′,1″,4′,4″-tetrahydro-di[1,4]methanonaphthaleno[1,2:2′,3′,56,60:2″,3″][5,6]fullerene-C₆₀ (abbreviation: ICBA).

Other examples of an n-type semiconductor material include perylenetetracarboxylic acid derivatives such as N,N′-dimethyl-3,4,9,10-perylenetetracarboxylic diimide (abbreviation: Me-PTCDI) and 2,2′-(5,5′-(thieno[3,2-b]thiophene-2,5-diyl)bis(thiophene-5,2-diyl))bis(methan-1-yl-1-ylidene)dimalononitrile (abbreviation: FT2TDMN).

Other examples of an n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the active layer include electron-donating organic semiconductor materials such as copper (II) phthalocyanine (CuPc), tetraphenyldibenzoperiflanthene (DBP), zinc phthalocyanine (ZnPc), tin phthalocyanine (SnPc), quinacridone, and rubrene.

Other examples of a p-type semiconductor material include a carbazole derivative, a thiophene derivative, a furan derivative, and a compound having an aromatic amine skeleton. Other examples of a p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a rubrene derivative, a tetracene derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of similar kinds, which have molecular orbital energy levels close to each other, can increase the carrier-transport property.

For the active layer, a high molecular compound such as poly[[4,8-bis[5-(2-ethylhexyl)-2-thienyl]benzo[1,2-b:4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]] polymer (abbreviation: PBDB-T) or a PBDB-T derivative, which functions as a donor, can be used. For example, a method in which an acceptor material is dispersed to PBDB-T or a PBDB-T derivative can be used.

For example, the active layer is preferably formed by co-evaporation of an n-type semiconductor and a p-type semiconductor. Alternatively, the active layer may be formed by stacking an n-type semiconductor and a p-type semiconductor.

Three or more kinds of materials may be mixed for the active layer. For example, a third material may be mixed in addition to an n-type semiconductor material and a p-type semiconductor material in order to extend the absorption wavelength range. The third material may be a low molecular compound or a high molecular compound.

In addition to the active layer, the light-receiving device may further include a layer containing a material with a high hole-transport property, a material with a high electron-transport property, a material with a bipolar property (a material with a high electron-transport property and a high hole-transport property), or the like. Without limitation to the above, the light-receiving device may further include a layer containing a material with a high hole-injection property, a hole-blocking material, a material with a high electron-injection property, an electron-blocking material, or the like. Layers other than the active layer included in the light-receiving device can be formed using a material that can be used for the light-emitting device.

As the hole-transport material or the electron-blocking material, a high molecular compound such as poly(3,4-ethylenedioxythiophene)/polystyrenesulfonic acid (abbreviation: PEDOT/PSS), or an inorganic compound such as molybdenum oxide or copper iodide (CuI) can be used, for example. As the electron-transport material or the hole-blocking material, an inorganic compound such as zinc oxide (ZnO), or an organic compound such as polyethylenimine ethoxylate (PEIE) can be used. The light-receiving device may include a mixed film of PEIE and ZnO, for example.

### [Display Apparatus Having Light Detection Function]

In the display apparatus of one embodiment of the present invention, the light-emitting devices are arranged in a matrix in a display portion, and an image can be displayed on the display portion. Furthermore, the light-receiving devices are arranged in a matrix in the display portion, and the display portion has one or both of an image capturing function and a sensing function in addition to an image displaying function. The display portion can be used as an image sensor or a touch sensor. That is, by detecting light with the display portion, an image can be captured or the approach or contact of a target (e.g., a finger, a hand, or a pen) can be detected.

Furthermore, in the display apparatus of one embodiment of the present invention, the light-emitting devices can be used as a light source of the sensor. In the display apparatus of one embodiment of the present invention, when an object reflects (or scatters) light emitted by the light-emitting device included in the display portion, the light-receiving device can detect reflected light (or scattered light); thus, image capturing or touch detection is possible even in a dark place.

Accordingly, a light-receiving portion and a light source do not need to be provided separately from the display apparatus; hence, the number of components of an electronic device can be reduced. For example, there is no need to separately provide a biometric authentication device provided in the electronic device, a capacitive touch panel for scroll operation, or the like. Thus, with the use of the display apparatus of one embodiment of the present invention, the electronic device can be provided with reduced manufacturing cost.

Specifically, the display apparatus of one embodiment of the present invention includes a light-emitting device and a light-receiving device in a pixel. In the display apparatus of one embodiment of the present invention, an organic EL device is used as the light-emitting device, and an organic photodiode is used as the light-receiving device. The organic EL device and the organic photodiode can be formed over the same substrate. Thus, the organic photodiode can be incorporated in the display apparatus that includes the organic EL device.

In the display apparatus including light-emitting devices and a light-receiving device in each pixel, the pixel has a light-receiving function; thus, the display apparatus can detect a contact or approach of an object while displaying an image. For example, all the subpixels included in the display apparatus can display an image in some cases, or some of the subpixels can emit light as a light source, others of the subpixels can detect light, and the others of the subpixels can display an image in other cases.

In the case where the light-receiving device is used as an image sensor, the display apparatus can capture an image with the use of the light-receiving device. For example, the display apparatus of this embodiment can be used as a scanner.

For example, image capturing for personal authentication with the use of a fingerprint, a palm print, the iris, the shape of a blood vessel (including the shape of a vein and the shape of an artery), a face, or the like can be performed using the image sensor.

For example, an image of the periphery, surface, or inside (e.g., fundus) of an eye of a user of a wearable device can be captured using the image sensor. Therefore, the wearable device can have a function of detecting one or more selected from blinking, movement of an iris, and movement of an eyelid of the user.

The light-receiving device can be used for a touch sensor (also referred to as a direct touch sensor), a near touch sensor (also referred to as a hover sensor, a hover touch sensor, a contactless sensor, or a touchless sensor), or the like.

Here, the touch sensor or the near touch sensor can detect the approach or contact of an object (e.g., a finger, a hand, or a pen).

The touch sensor can detect an object when the display apparatus and the object come in direct contact with each other. The near touch sensor can detect an object even when the object is not in contact with the display apparatus. For example, the display apparatus is preferably capable of detecting an object when the distance between the display apparatus and the object is greater than or equal to 0.1 mm and less than or equal to 300 mm, preferably greater than or equal to 3 mm and less than or equal to 50 mm. With this structure, the display apparatus can be operated without direct contact of an object. In other words, the display apparatus can be operated in a contactless (touchless) manner. With the above structure, the display apparatus can have a reduced risk of being dirty or damaged, or can be operated without the object directly touching a dirt (e.g., dust or a virus) attached to the display apparatus.

The refresh rate can be variable in the display apparatus of one embodiment of the present invention. For example, the refresh rate is adjusted (adjusted in the range from 1 Hz to 240 Hz, for example) in accordance with contents displayed on the display apparatus, whereby power consumption can be reduced. The driving frequency of the touch sensor or the near touch sensor may be changed in accordance with the refresh rate. For example, when the refresh rate of the display apparatus is 120 Hz, the driving frequency of the touch sensor or the near touch sensor can be higher than 120 Hz (typically 240 Hz). With this structure, low power consumption can be achieved, and the response speed of the touch sensor or the near touch sensor can be increased.

The display apparatus 200 illustrated in FIG. 30C to FIG. 30E includes a layer 353 including a light-receiving device, a functional layer 355, and a layer 357 including a light-emitting device, between a substrate 351 and a substrate 359.

The functional layer 355 includes a circuit for driving a light-receiving device and a circuit for driving a light-emitting device. One or more of a switch, a transistor, a capacitor, a resistor, a wiring, a terminal, and the like can be provided in the functional layer 355. Note that in the case where the light-emitting device and the light-receiving device are driven by a passive-matrix method, a structure including neither a switch nor a transistor may be employed. The transistor described in Embodiment 1 can be suitably used as the transistor provided in the functional layer 355.

For example, when light emitted by the light-emitting device in the layer 357 including the light-emitting device is reflected by a finger 352 in contact with the display apparatus 200 as illustrated in FIG. 30C, the light-receiving device in the layer 353 including the light-receiving device detects the reflected light. Thus, the contact of the finger 352 with the display apparatus 200 can be detected.

Alternatively, the display apparatus may have a function of detecting an object that is approaching (not in contact with) the display apparatus as illustrated in FIG. 30D and FIG. 30E or capturing an image of such an object. FIG. 30D illustrates an example in which a human finger is detected, and FIG. 30E illustrates an example in which information on the periphery, surface, or inside of the human eye (e.g., the number of blinks, movement of an eyeball, and movement of an eyelid) is detected.

This embodiment can be combined with any of the other embodiments as appropriate.

### Embodiment 6

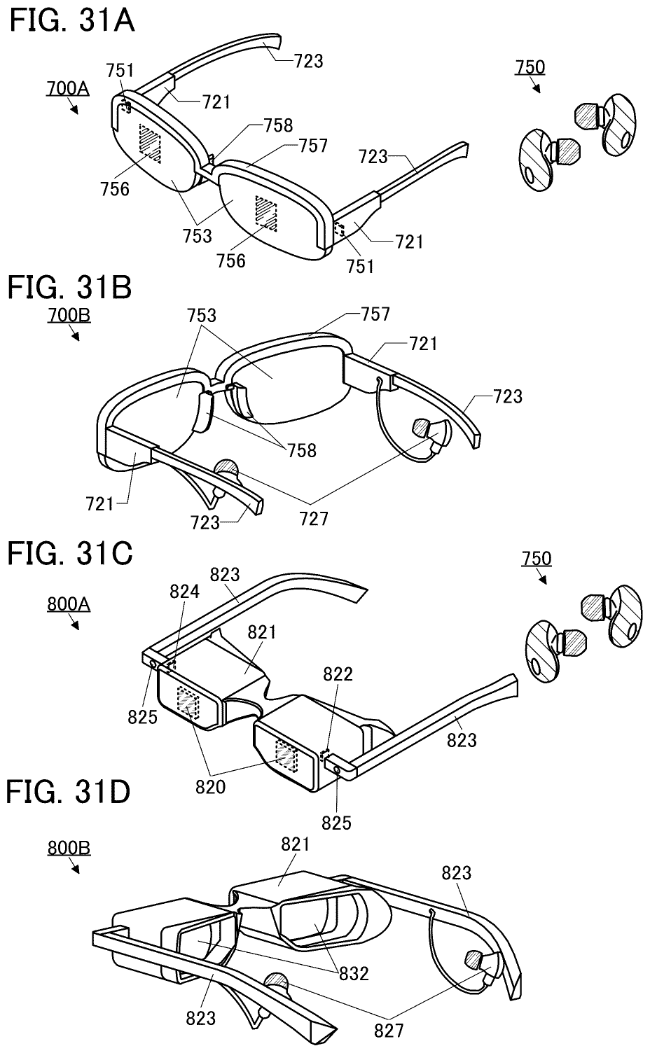

In this embodiment, electronic devices of embodiments of the present invention will be described with reference to FIG. 31 to FIG. 33.

Electronic devices of this embodiment each include the display apparatus of one embodiment of the present invention in a display portion. The display apparatus of one embodiment of the present invention can be easily increased in definition and resolution. Thus, the display apparatus of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or notebook personal computer, a monitor of a computer or the like, digital signage, and a large game machine such as a pachinko machine.

In particular, the display apparatus of one embodiment of the present invention can have high definition, and thus can be suitably used for an electronic device including a relatively small display portion. Examples of such an electronic device include watch-type and bracelet-type information terminals (wearable devices) and wearable devices capable of being worn on a head, such as a VR device like a head-mounted display, a glasses-type AR device, and an MR device.

The resolution of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the resolution is preferably 4K, 8K, or higher. The pixel density (definition) of the display apparatus of one embodiment of the present invention is preferably higher than or equal to 100 ppi, further preferably higher than or equal to 300 ppi, still further preferably higher than or equal to 500 ppi, yet still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. The use of such a display apparatus with high resolution and/or high definition can improve realistic sensation, sense of depth, and the like. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of a wearable device capable of being worn on a head are described with reference to FIG. 31A to FIG. 31D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables a user to feel a higher sense of immersion.

An electronic device 700A illustrated in FIG. 31A and an electronic device 700B illustrated in FIG. 31B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, the electronic device can perform display with extremely high definition.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In each of the electronic device 700A and the electronic device 700B, a camera capable of capturing an image of what lies in front thereof may be provided as the image capturing portion. Furthermore, when the electronic device 700A and the electronic device 700B are each provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Note that instead of the wireless communication device or in addition to the wireless communication device, a connector to which a cable for supplying a video signal and a power supply potential can be connected may be provided.

The electronic device 700A and the electronic device 700B are each provided with a battery so that they can be charged wirelessly and/or by wire.

A touch sensor module may be provided in the housing 721. The touch sensor module has a function of detecting touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast forward and fast rewind can be executed by a slide operation. The touch sensor module is provided in each of the two housings 721, whereby the range of the operation can be increased.

A variety of touch sensors can be used for the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion device (also referred to as a photoelectric conversion element) can be used as a light-receiving device. One or both of an inorganic semiconductor and an organic semiconductor can be used for an active layer of the photoelectric conversion device.

An electronic device 800A illustrated in FIG. 31C and an electronic device 800B illustrated in FIG. 31D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used for the display portions 820. Thus, the electronic device can perform display with extremely high definition. This enables a user to feel high sense of immersion.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B each preferably include a mechanism for adjusting the positions of the lenses 832 and the display portions 820 laterally so that the lenses 832 and the display portions 820 are positioned optimally in accordance with the positions of the user's eyes. Moreover, the electronic device 800A and the electronic device 800B each preferably include a mechanism for adjusting focus by changing the distance between the lenses 832 and the display portions 820.

The electronic device 800A or the electronic device 800B can be mounted on the user's head with the wearing portion 823. FIG. 31C and the like illustrate examples where the wearing portion 823 has a shape like a temple of glasses; however, one embodiment of the present invention is not limited to the shape. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example of including the image capturing portion 825 is described here, a range sensor (hereinafter, also referred to as a sensing portion) that is capable of measuring a distance to an object may be provided. That is, the image capturing portion 825 is one embodiment of the sensing portion. As the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be employed for any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, or the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 31A has a function of transmitting information to the earphones 750 with the wireless communication function. As another example, the electronic device 800A illustrated in FIG. 31C has a function of transmitting information to the earphones 750 with the wireless communication function.

The electronic device may include earphone portions. The electronic device 700B illustrated in FIG. 31B includes earphone portions 727. For example, the earphone portions 727 and the control portion can be connected to each other by wire. Part of a wiring that connects the earphone portions 727 and the control portion may be positioned inside the housing 721 or the wearing portions 723.

Similarly, the electronic device 800B illustrated in FIG. 31D includes earphone portions 827. For example, the earphone portion 827 and the control portion 824 can be connected to each other by wire. Part of a wiring that connects the earphone portion 827 and the control portion 824 may be positioned inside the housing 821 or the wearing portions 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

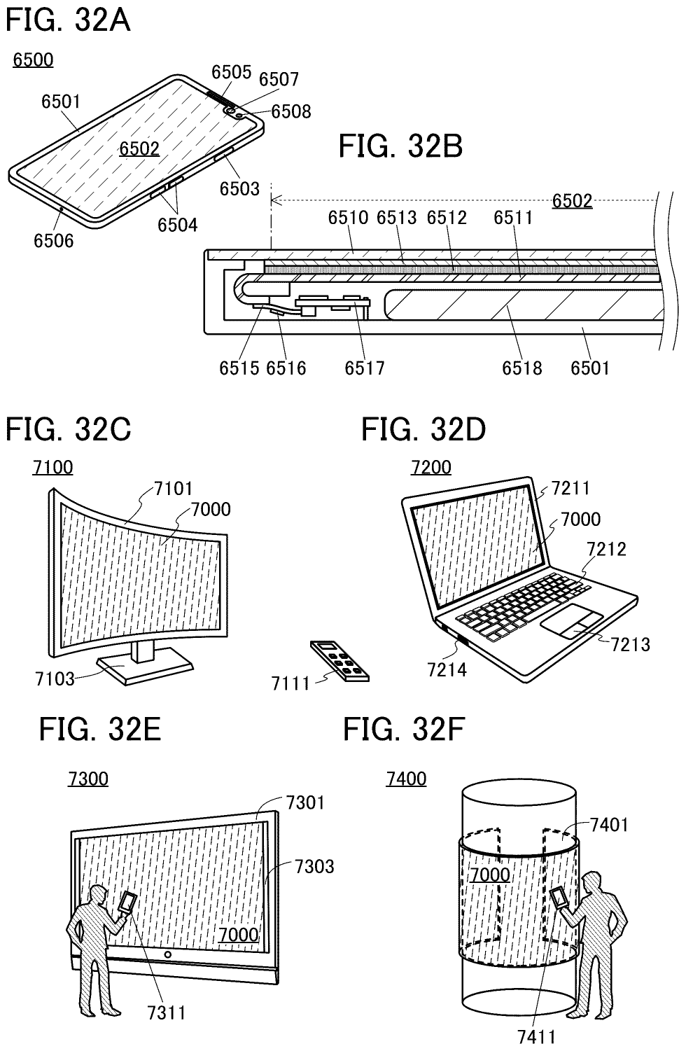

An electronic device 6500 illustrated in FIG. 32A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used for the display portion 6502.

FIG. 32B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be obtained. Since the display panel 6511 is extremely thin, the battery 6518 with high capacity can be mounted while the thickness of the electronic device is reduced. Moreover, part of the display panel 6511 is folded back so that a connection portion with the FPC 6515 is provided on the back side of the pixel portion, whereby an electronic device with a narrow bezel can be obtained.

FIG. 32C illustrates an example of a television device. In a television device 7100, a display portion 7000 is incorporated in a housing 7101. Here, a structure in which the housing 7101 is supported by a stand 7103 is illustrated.

The display apparatus of one embodiment of the present invention can be used for the display portion 7000.

Operation of the television device 7100 illustrated in FIG. 32C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and videos displayed on the display portion 7000 can be controlled.

Note that the television device 7100 has a structure in which a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 32D illustrates an example of a notebook personal computer. A notebook personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used for the display portion 7000.

FIG. 32E and FIG. 32F illustrate examples of digital signage.

Digital signage 7300 illustrated in FIG. 32E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 32F is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 in each of FIG. 32E and FIG. 32F.

A larger area of the display portion 7000 can increase the amount of information that can be provided at a time. The larger the display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 32E and FIG. 32F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operating the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

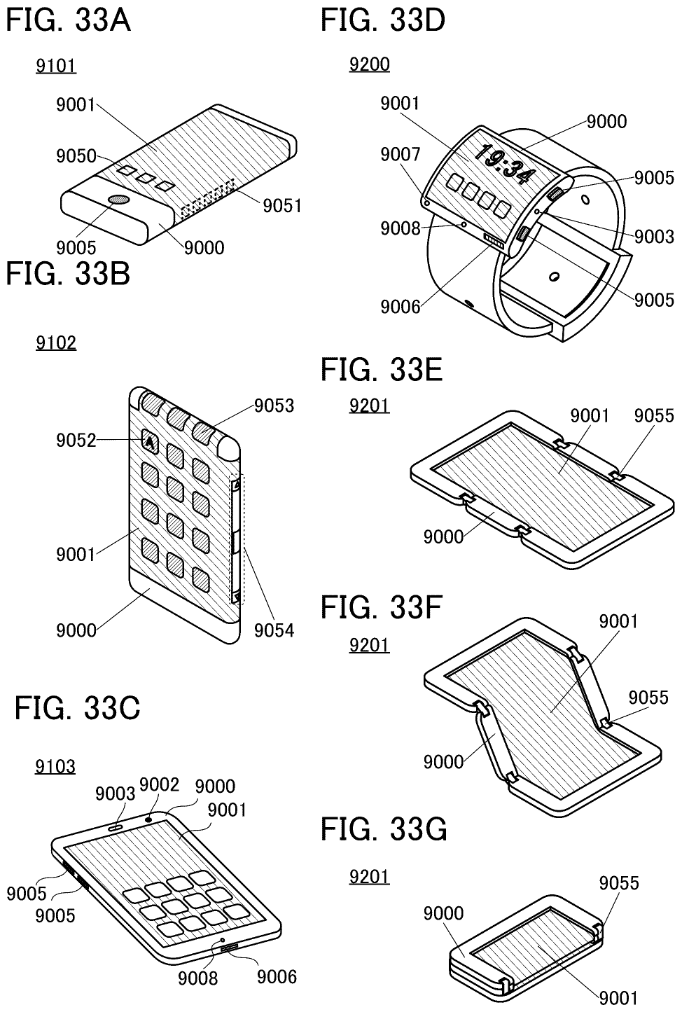

Electronic devices illustrated in FIG. 33A to FIG. 33G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like. The display device described in the above embodiment can be suitably used for the display portion 9001.

The electronic devices illustrated in FIG. 33A to FIG. 33G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, a function of reading out and processing a program or data stored in a recording medium, and the like. Note that the functions of the electronic devices are not limited to the above, and the electronic devices can have a variety of functions. The electronic devices may each include a plurality of display portions. The electronic devices may each be provided with a camera or the like and have a function of taking a still image or a moving image and storing the taken image in a storage medium (an external storage medium or a storage medium incorporated in the camera), a function of displaying the taken image on the display portion, and the like.

The electronic devices illustrated in FIG. 33A to FIG. 33G are described in detail below.

FIG. 33A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display characters and image information on its plurality of surfaces. FIG. 33A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, date, time, remaining battery, and a radio field intensity. Alternatively, the icon 9050 or the like may be displayed at the position where the information 9051 is displayed.

FIG. 33B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is illustrated. For example, a user can check the information 9053 displayed so as to be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 33C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 33D is a perspective view illustrating a watch-type portable information terminal 9200. For example, the portable information terminal 9200 can be used as a Smartwatch (registered trademark). The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 33E to FIG. 33G are perspective views illustrating a foldable portable information terminal 9201. FIG. 33E is a perspective view of an opened state of the portable information terminal 9201, FIG. 33G is a perspective view of a folded state thereof, and FIG. 33F is a perspective view of a state in the middle of change from one of FIG. 33E and FIG. 33G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with any of the other embodiments as appropriate.

### REFERENCE NUMERALS

11a: subpixel, 11b: subpixel, 11c: subpixel, 11d: subpixel, 11e: subpixel, 100A: transistor, 100B: transistor, 100C: transistor, 100D: transistor, 100: transistor, 102: substrate, 104: conductive layer, 106: insulating layer, 108f: metal oxide film, 108: semiconductor layer, 110a: insulating layer, 110a_1: insulating layer, 110a_2: insulating layer, 110af: insulating film, 110b: insulating layer, 110bf: insulating film, 110c: insulating layer, 110cf: insulating film, 110f: insulating film, 110: insulating layer, 111B: pixel electrode, 111G: pixel electrode, 111R: pixel electrode, 111S: pixel electrode, 111: pixel electrode, 112a: conductive layer, 112b: conductive layer, 112f: conductive film, 113B: layer, 113G: layer, 113R: layer, 113S: layer, 113W: layer, 113: layer, 114: common layer, 115: common electrode, 117: light-blocking layer, 118B: mask layer, 118G: mask layer, 118R: mask layer, 118S: mask layer, 118: mask layer, 119B: mask layer, 119G: mask layer, 119R: mask layer, 119S: mask layer, 119: mask layer, 123: conductive layer, 124B: conductive layer, 124G: conductive layer, 124p: conductive layer, 124q: conductive layer, 124R: conductive layer, 125: insulating layer, 126B: conductive layer, 126G: conductive layer, 126p: conductive layer, 126q: conductive layer, 126R: conductive layer, 127: insulating layer, 128: layer, 129B: conductive layer, 129G: conductive layer, 129p: conductive layer, 129q: conductive layer, 129R: conductive layer, 130B: light-emitting device, 130G: light-emitting device, 130R: light-emitting device, 130: light-emitting device, 131: protective layer, 132B: coloring layer, 132G: coloring layer, 132R: coloring layer, 140: connection portion, 141: opening, 142: adhesive layer, 143: opening, 149: metal oxide layer, 150: light-receiving device, 151: substrate, 152: substrate, 153: insulating layer, 162: display portion, 164: circuit, 165: wiring, 166: conductive layer, 172: FPC, 173: IC, 191: opening, 193: opening, 200A: display apparatus, 200B: display apparatus, 200C: display apparatus, 200D: display apparatus, 200E: display apparatus, 200F: display apparatus, 200: display apparatus, 201: transistor, 204: connection portion, 205B: transistor, 205G: transistor, 205R: transistor, 205S: transistor, 210a: pixel, 210b: pixel, 210: pixel, 218: insulating layer, 235: insulating layer, 237: insulating layer, 239: insulating layer, 242: connection layer, 351: substrate, 352: finger, 353: layer, 355: functional layer, 357: layer, 359: substrate, 700A: electronic device, 700B: electronic device, 721: housing, 723: wearing portion, 727: earphone portion, 750: earphone, 751: display panel, 753: optical member, 756: display region, 757: frame, 758: nose pad, 761: lower electrode, 762: upper electrode, 763a: light-emitting unit, 763b: light-emitting unit, 763c: light-emitting unit, 763: EL layer, 764: layer, 765: layer, 766: layer, 767: active layer, 768: layer, 771a: light-emitting layer, 771b: light-emitting layer, 771c: light-emitting layer, 771: light-emitting layer, 772a: light-emitting layer, 772b: light-emitting layer, 772c: light-emitting layer, 772: light-emitting layer, 773: light-emitting layer, 780a: layer, 780b: layer, 780c: layer, 780: layer, 781: layer, 782: layer, 785: charge-generation layer, 790a: layer, 790b: layer, 790c: layer, 790: layer, 791: layer, 792: layer, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: notebook personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A semiconductor device comprising:
a semiconductor layer, a first conductive layer, a second conductive layer, a third conductive layer, a first insulating layer, and a second insulating layer,
wherein the first insulating layer is provided over the first conductive layer,
wherein the first insulating layer has a first opening reaching the first conductive layer,
wherein the semiconductor layer is in contact with a top surface and a side surface of the first insulating layer and a top surface of the first conductive layer,
wherein the second conductive layer is provided over the semiconductor layer,
wherein the second conductive layer has a second opening in a region overlapping with the first opening,
wherein the second insulating layer is provided over the semiconductor layer and the second conductive layer,
wherein the third conductive layer is provided over the second insulating layer, and
wherein the first insulating layer has a stacked-layer structure of a third insulating layer and a fourth insulating layer over the third insulating layer.

2. The semiconductor device according to claim 1,
wherein the first insulating layer comprises a fifth insulating layer,
wherein the fifth insulating layer is positioned between the third insulating layer and the first conductive layer, and
wherein the fifth insulating layer comprises a region having a film density higher than a film density of the third insulating layer.

3. The semiconductor device according to claim 1,
wherein the first insulating layer comprises a fifth insulating layer,
wherein the fifth insulating layer is positioned between the third insulating layer and the first conductive layer, and
wherein the fifth insulating layer comprises a region having a content of nitrogen higher than a content of nitrogen of the third insulating layer.

4.-6. (canceled)

7. The semiconductor device according to claim 1,
wherein a thickness of the first insulating layer is greater than or equal to 0.01 μm and less than 3 μm.

8. The semiconductor device according to claim 1,
wherein the first conductive layer comprises an oxide conductor.

9. The semiconductor device according to claim 1,
wherein the second conductive layer comprises an oxide conductor.

10. The semiconductor device according to claim 8,
wherein the second conductive layer comprises an oxide conductor.

11. A method for manufacturing a semiconductor device, comprising:
forming a first conductive film;
processing the first conductive film to form a first conductive layer;
forming a first insulating film over the first conductive layer;
processing the first insulating film to form a first insulating layer having a first opening reaching the first conductive layer;
forming a semiconductor layer in contact with a top surface of the first conductive layer and a top surface and a side surface of the first insulating layer;
forming a second conductive film over the semiconductor layer;
processing the second conductive film to form a second conductive layer having a second opening in a region overlapping with the first opening;
forming a second insulating layer over the semiconductor layer and the second conductive layer; and
forming a third conductive layer over the second insulating layer, and
wherein the first insulating layer has a stacked-layer structure of a third insulating layer and a fourth insulating layer over the third insulating layer.

12. (canceled)

13. The semiconductor device according to claim 1,
wherein the fourth insulating layer comprises a region having a film density higher than a film density of the third insulating layer.

14. The semiconductor device according to claim 1,
wherein the fourth insulating layer comprises a region having a content of nitrogen higher than a content of nitrogen of the third insulating layer.

15. The method for manufacturing a semiconductor device according to claim 11,
wherein the fourth insulating layer comprises a region having a film density higher than a film density of the third insulating layer.

16. The method for manufacturing a semiconductor device according to claim 11,
wherein the fourth insulating layer comprises a region having a content of nitrogen higher than a content of nitrogen of the third insulating layer.
